(19) United States
(12) Patent Application Publication
(10) Pub. No.: US 2026/0281581 A1
(43) Pub. Date: Sep. 17, 2026

(54) PHOTODETECTION DEVICE AND ELECTRONIC APPARATUS

(71) Applicant: SONY SEMICONDUCTOR SOLUTIONS CORPORATION, Kanagawa (JP)

(72) Inventors: Ryoto YOSHITA, Kanagawa (JP); Takashi MACHIDA, Tokyo (JP)

(73) Assignee: SONY SEMICONDUCTOR SOLUTIONS CORPORATION, Kanagawa (JP)

(21) Appl. No.: 19/471,611

(22) PCT Filed: Mar. 25, 2024
(86) PCT No.: PCT/JP2024/011578

§ 371 Date: Oct. 1, 2025

(30) Foreign Application Priority Data
Apr. 13, 2023 (JP) 2023-065949

(51) Int. Cl. H04N 25/771

(52) U.S. Cl. CPC H04N 25/771

(57) ABSTRACT

A photodetection device that includes a plurality of pixels that performs exposure at the same timing. Each of the plurality of pixels includes: a photoelectric conversion element that stores charge corresponding to a light amount of incident light; a first retention unit that retains the charge stored in the photoelectric conversion element; a charge-voltage conversion unit that converts the charge retained in the first retention unit into a voltage; a second retention unit that retains charge overflowing from the photoelectric conversion element; a first transfer path that transfers charge from the photoelectric conversion element to the first retention unit; a second transfer path that transfers charge from the photoelectric conversion element to the second retention unit; and a first transistor that switches whether or not to supply the charge retained in the second retention unit to the charge-voltage conversion unit together with the charge retained in the first retention unit.

### TECHNICAL FIELD

The present disclosure relates to a photodetection device and an electronic apparatus.

### BACKGROUND ART

A global shutter imaging device that starts exposure at the same timing for all pixels and performs charge readout is known. The global shutter method has an advantage that no distortion occurs in the captured image as compared with the rolling shutter method in which exposure is performed for each pixel row. Furthermore, an imaging device has been proposed in which a first charge storage unit is provided to perform a global shutter operation, and a second charge storage unit that retains charge overflowing from a photoelectric conversion element is provided to expand the dynamic range (see Patent Document 1).

### CITATION LIST

### Patent Document

Patent Document 1: Japanese Patent Application Laid-Open No. 2011-199816

### SUMMARY OF THE INVENTION

### Problems to be Solved by the Invention

However, in the imaging device of Patent Document 1, charge equal to or less than the saturation charge amount of the first charge storage unit is stored in the first charge storage unit, and charge exceeding the saturation charge amount of the first charge storage unit is stored in the second charge storage unit. A transistor for switching whether or not to store charge in the second charge storage unit is provided, and it is necessary to control on or off of the transistor by determining whether or not the saturation charge amount of the first charge storage unit is exceeded, which complicates control.

Furthermore, in the imaging device of Patent Document 1, the first charge storage unit and a photodiode are arranged on the same surface. Therefore, when the area of the first charge storage unit is increased, the area of the photodiode is reduced, which becomes an obstacle to increase the number of pixels. As a result, the charge storage amount of the first charge storage unit also cannot be increased.

Against this background, the present disclosure provides a photodetection device and an electronic apparatus capable of achieving both expansion of the dynamic range and high resolution without complicating control in a case where the global shutter method is adopted.

### Solutions to Problems

In order to solve the above problem, according to the present disclosure, there is provided
a photodetection device including a plurality of pixels that performs exposure at the same timing, each of the plurality of pixels including:
a photoelectric conversion element that stores charge corresponding to a light amount of incident light;
a first retention unit that retains the charge stored in the photoelectric conversion element;
a charge-voltage conversion unit that converts the charge retained in the first retention unit into a voltage;
a second retention unit that retains charge overflowing from the photoelectric conversion element;
a first transfer path that transfers charge from the photoelectric conversion element to the first retention unit;
a second transfer path that transfers charge from the photoelectric conversion element to the second retention unit; and
a first transistor that switches whether or not to supply the charge retained in the second retention unit to the charge-voltage conversion unit together with the charge retained in the first retention unit.

The first transistor may be switched so as to read the charge retained in the second retention unit when the incident light amount is equal to or greater than a first light amount, and not to read the charge retained in the second retention unit when the incident light amount is less than the first light amount.

A semiconductor region in which the plurality of pixels is arranged may further be provided, and
the photoelectric conversion element and the first retention unit may be arranged at different depth positions in the semiconductor region.

The second transfer path may include a first diffusion region in which an impurity concentration changes continuously or stepwise in a depth direction of the semiconductor region from the photoelectric conversion element.

A charge capturing portion arranged between the photoelectric conversion element and the first retention unit on the semiconductor region may further be provided, the charge capturing portion capturing charge from the photoelectric conversion element and guiding the charge to the second transfer path.

The charge capturing portion may be arranged so as to cover the entire region of the first retention unit in plan view of the semiconductor region.

The charge capturing portion may include a second diffusion region in which an impurity concentration changes continuously or stepwise from the photoelectric conversion element to the first retention unit.

The second transfer path may include a second transistor extending in a depth direction of the semiconductor region from the photoelectric conversion element to the second retention unit, and
a gate of the second transistor may be set to a predetermined potential.

A third transistor that switches whether or not to discard the charge stored in the photoelectric conversion element may further be provided, and
the second transfer path may transfer the charge stored in the photoelectric conversion element to the second retention unit without passing through the third transistor.

A third transistor that switches whether or not to discard the charge stored in the photoelectric conversion element may further be provided, and
the second transfer path may transfer the charge overflowing from the photoelectric conversion element to the second retention unit through the third transistor.

A first substrate on which the photoelectric conversion element, the first retention unit, and the second retention unit are arranged, and
a second substrate laminated on the first substrate and provided with a pixel circuit that generates a pixel signal on the basis of charge retained in the first retention unit and the second retention unit may further be provided.

A first substrate on which the photoelectric conversion element and the first retention unit are arranged, and
a second substrate laminated on the first substrate and provided with the second retention unit and a pixel circuit that generates a pixel signal on the basis of charge retained in the first retention unit and the second retention unit may further be provided.

Each of the plurality of pixels may include
a third retention unit that retains the charge stored in the photoelectric conversion element, and
a fourth transistor that switches whether or not to read the charge retained in the third retention unit.

A capacitance of the third retention unit may be smaller than a capacitance of the second retention unit.

The first transistor and the fourth transistor may be,
when the amount of incident light on the photoelectric conversion element is equal to or less than a second light amount, switched such that the charge retained in the first retention unit is supplied to the charge-voltage conversion unit without using the second retention unit and the third retention unit,
when the amount of incident light on the photoelectric conversion element is greater than the second light amount and equal to or less than a third light amount, switched such that a pixel signal is generated on the basis of the charge retained in the first retention unit and the third retention unit without using the second retention unit, and
when the amount of incident light on the photoelectric conversion element is greater than the third light amount, switched such that the charge retained in the first retention unit, the second retention unit, and the third retention unit is supplied to the charge-voltage conversion unit.

The second retention unit may include a diffusion layer and a wiring layer.

The second retention unit may be configured using a diffusion layer, a wiring layer, and a metal-oxide semiconductor (MOS) capacitor.

The second retention unit may be configured using a diffusion layer, a wiring layer, and a metal-insulator-metal (MIM) capacitor.

A semiconductor layer arranged on a semiconductor region in which the plurality of pixels is arranged, the semiconductor layer having an impurity concentration changing in a depth direction of the semiconductor region, and
a light shielding member partially arranged inside the semiconductor layer may further be provided, and
the photoelectric conversion element included in each of the plurality of pixels may be arranged in the semiconductor layer, and the first retention unit may be arranged so as to at least partially overlap the light shielding member in plan view of the semiconductor region.

Furthermore, according to the present disclosure, there is provided an electronic apparatus including
a photodetection device, and
a processing unit that processes image data output from the photodetection device, in which
the photodetection device includes a plurality of pixels that performs exposure at the same timing, and
each of the plurality of pixels includes:
a photoelectric conversion element that stores charge corresponding to a light amount of incident light;
a first retention unit that retains the charge stored in the photoelectric conversion element;
a charge-voltage conversion unit that converts the charge retained in the first retention unit into a voltage;
a second retention unit that retains charge overflowing from the photoelectric conversion element;
a first transfer path that transfers charge from the photoelectric conversion element to the first retention unit;
a second transfer path that transfers charge from the photoelectric conversion element to the second retention unit; and
a first transistor that switches whether or not to supply the charge retained in the second retention unit to the charge-voltage conversion unit together with the charge retained in the first retention unit.

### BRIEF DESCRIPTION OF DRAWINGS

FIG. 1 is a block diagram of an electronic apparatus according to a first embodiment of the present disclosure.

FIG. 2 is a block diagram of a photodetection device according to the first embodiment of the present disclosure.

FIG. 3 is a diagram illustrating a laminated structure of the photodetection device according to the first embodiment of the present disclosure.

FIG. 4 is a circuit diagram of a pixel and a pixel circuit according to the first embodiment of the present disclosure.

FIG. 5 is a potential diagram of a photoelectric conversion element and a buffer unit.

FIG. 6 is a cross-sectional view of a photodetection device according to the first embodiment of the present disclosure.

FIG. 7 is a plan layout diagram of a first pixel chip according to the first embodiment of the present disclosure.

FIG. 8 is a plan layout diagram of a second pixel chip according to the first embodiment of the present disclosure.

FIG. 9 is a circuit diagram of a pixel and a pixel circuit according to a modification of the first embodiment of the present disclosure.

FIG. 10 is a cross-sectional view of a photodetection device according to the modification of the first embodiment of the present disclosure.

FIG. 11 is a plan layout diagram of a first pixel chip according to the modification of the first embodiment of the present disclosure.

FIG. 12 is a circuit diagram of a pixel according to a first comparative example.

FIG. 13 is a cross-sectional view of a pixel and a pixel circuit according to the first comparative example.

FIG. 14 is a plan layout diagram of a first pixel chip according to the first comparative example.

FIG. 15 is a block diagram illustrating a cross-sectional configuration of a pixel according to a second comparative example.

FIG. 16 is a circuit diagram of the pixel according to the second comparative example.

FIG. 17 is a cross-sectional view of a photodetection device according to a second embodiment of the present disclosure.

FIG. 18 is a cross-sectional view of a photodetection device according to a third embodiment of the present disclosure.

FIG. 19 is a circuit diagram of a pixel and a pixel circuit according to a fourth embodiment of the present disclosure.

FIG. 20 is a cross-sectional view of a photodetection device according to the fourth embodiment of the present disclosure.

FIG. 21 is a plan layout diagram of a first pixel chip according to the fourth embodiment of the present disclosure.

FIG. 22 is a plan layout diagram of a second pixel chip according to the fourth embodiment of the present disclosure.

FIG. 23 is a circuit diagram of a pixel and a pixel circuit according to a fifth embodiment of the present disclosure.

FIG. 24 is a graph illustrating signal characteristics of a first pixel signal, a second pixel signal, and a third pixel signal.

FIG. 25 is a plan layout diagram of the second pixel chip according to the fifth embodiment of the present disclosure.

FIG. 26A is a cross-sectional view of a first example of a pixel according to a sixth embodiment of the present disclosure.

FIG. 26B is a cross-sectional view of a second example of the pixel according to the sixth embodiment of the present disclosure.

FIG. 26C is a cross-sectional view of a third example of the pixel according to the sixth embodiment of the present disclosure.

FIG. 27 is a block diagram illustrating an example of a functional configuration of an imaging device according to a first application example of the present disclosure.

FIG. 28 is a schematic plan view illustrating a schematic configuration of the imaging device illustrated in FIG. 27.

FIG. 29 is a schematic diagram illustrating a cross-sectional configuration taken along line III-III′ illustrated in FIG. 28.

FIG. 30 is an equivalent circuit diagram of a pixel sharing unit illustrated in FIG. 27.

FIG. 31 is a diagram illustrating an example of a connection mode between a plurality of pixel sharing units and a plurality of vertical signal lines.

FIG. 32 is a schematic cross-sectional view illustrating an example of a specific configuration of the imaging device illustrated in FIG. 29.

FIG. 33A is a schematic diagram illustrating an example of a planar configuration of a main part of a first substrate illustrated in FIG. 32.

FIG. 33B is a schematic diagram illustrating a planar configuration of pad portions together with the main part of the first substrate illustrated in FIG. 33A.

FIG. 34 is a schematic diagram illustrating an example of a planar configuration of a second substrate (semiconductor layer) illustrated in FIG. 32.

FIG. 35 is a schematic diagram illustrating an example of a planar configuration of main parts of a pixel circuit and the first substrate together with a first wiring layer illustrated in FIG. 32.

FIG. 36 is a schematic diagram illustrating an example of a planar configuration of the first wiring layer and a second wiring layer illustrated in FIG. 32.

FIG. 37 is a schematic diagram illustrating an example of a planar configuration of the second wiring layer and a third wiring layer illustrated in FIG. 32.

FIG. 38 is a schematic diagram illustrating an example of a planar configuration of the third wiring layer and a fourth wiring layer illustrated in FIG. 32.

FIG. 39 is a schematic diagram for describing paths of input signals to the imaging device illustrated in FIG. 29.

FIG. 40 is a schematic diagram for describing signal paths of pixel signals of the imaging device illustrated in FIG. 29.

FIG. 41 is a schematic diagram illustrating a modification of the planar configuration of the second substrate (semiconductor layer) illustrated in FIG. 34.

FIG. 42 is a schematic diagram illustrating a planar configuration of main parts of a first wiring layer and a first substrate together with a pixel circuit illustrated in FIG. 41.

FIG. 43 is a schematic diagram illustrating an example of a planar configuration of a second wiring layer together with the first wiring layer illustrated in FIG. 42.

FIG. 44 is a schematic diagram illustrating an example of a planar configuration of a third wiring layer together with the second wiring layer illustrated in FIG. 43.

FIG. 45 is a schematic diagram illustrating an example of a planar configuration of a fourth wiring layer together with the third wiring layer illustrated in FIG. 44.

FIG. 46 is a schematic diagram illustrating a modification of the planar configuration of the first substrate illustrated in FIG. 33a.

FIG. 47 is a schematic diagram illustrating an example of a planar configuration of a second substrate (semiconductor layer) laminated on the first substrate illustrated in FIG. 46.

FIG. 48 is a schematic diagram illustrating an example of a planar configuration of a first wiring layer together with a pixel circuit illustrated in FIG. 47.

FIG. 49 is a schematic diagram illustrating an example of a planar configuration of a second wiring layer together with the first wiring layer illustrated in FIG. 48.

FIG. 50 is a schematic diagram illustrating an example of a planar configuration of a third wiring layer together with the second wiring layer illustrated in FIG. 49.

FIG. 51 is a schematic diagram illustrating an example of a planar configuration of a fourth wiring layer together with the third wiring layer illustrated in FIG. 50.

FIG. 52 is a schematic diagram illustrating another example of the planar configuration of the first substrate illustrated in FIG. 46.

FIG. 53 is a schematic diagram illustrating an example of a planar configuration of a second substrate (semiconductor layer) laminated on the first substrate illustrated in FIG. 52.

FIG. 54 is a schematic diagram illustrating an example of a planar configuration of a first wiring layer together with a pixel circuit illustrated in FIG. 53.

FIG. 55 is a schematic diagram illustrating an example of a planar configuration of a second wiring layer together with the first wiring layer illustrated in FIG. 54.

FIG. 56 is a schematic diagram illustrating an example of a planar configuration of a third wiring layer together with the second wiring layer illustrated in FIG. 55.

FIG. 57 is a schematic diagram illustrating an example of a planar configuration of a fourth wiring layer together with the third wiring layer illustrated in FIG. 56.

FIG. 58 is a schematic cross-sectional view illustrating another example of the imaging device illustrated in FIG. 29.

FIG. 59 is a schematic diagram for describing paths of input signals to the imaging device illustrated in FIG. 58.

FIG. 60 is a schematic diagram for describing signal paths of pixel signals of the imaging device illustrated in FIG. 58.

FIG. 61 is a schematic cross-sectional view illustrating another example of the imaging device illustrated in FIG. 32.

FIG. 62 is a diagram illustrating another example of an equivalent circuit illustrated in FIG. 30.

FIG. 63 is a schematic plan view illustrating another example of a pixel isolation portion illustrated in FIG. 33A and the like.

FIG. 64 is a diagram illustrating an example of a schematic configuration of an imaging system including the imaging device according to one of the above embodiments and the modifications thereof.

FIG. 65 is a diagram illustrating an example of an imaging procedure of the imaging system illustrated in FIG. 64.

FIG. 66 is a block diagram illustrating an example of a schematic configuration of a vehicle control system.

FIG. 67 is an explanatory view illustrating exemplary installation positions of an outside-vehicle information detecting section and an imaging section.

FIG. 68 is a diagram illustrating an example of a schematic configuration of an endoscopic surgery system.

FIG. 69 is a block diagram illustrating an example of a functional configuration of a camera head and a CCU.

### MODE FOR CARRYING OUT THE INVENTION

Hereinafter, embodiments of a photodetection device and an electronic apparatus will be described with reference to the drawings. Hereinafter, main components of the photodetection device and the electronic apparatus will be mainly described, but the photodetection device and the electronic apparatus may have components and functions that are not illustrated or described. The following description is not intended to exclude components and functions that are not illustrated or described.

### First Embodiment

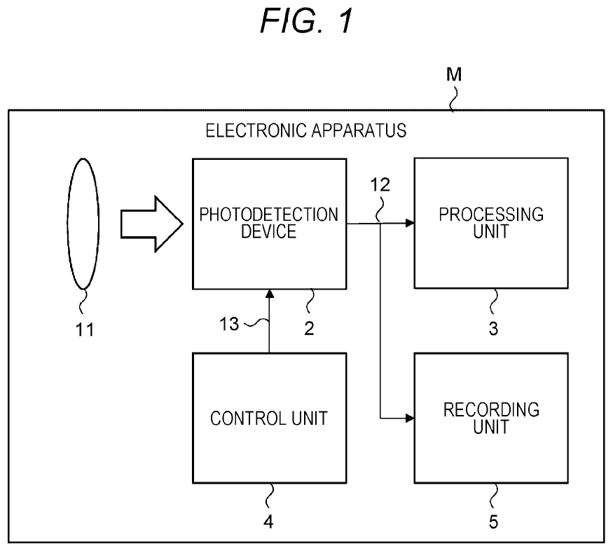

FIG. 1 is a block diagram of an electronic apparatus M according to a first embodiment of the present disclosure. The electronic apparatus M captures image data, and includes an imaging lens 11, the photodetection device 2, a processing unit 3, and a control unit 4. For example, while a camera mounted on an industrial robot, a vehicle-mounted camera, or the like is assumed as the electronic apparatus M, the electronic apparatus M has any specific application and configuration.

The imaging lens 11 condenses and guides incident light to the photodetection device 2. The photodetection device 2 is, for example, a complementary metal-oxide-semiconductor (CMOS) image sensor, and photoelectrically converts incident light to capture image data. The image data output from the photodetection device 2 is input to the processing unit 3 via a transmission line 12. The processing unit 3 performs predetermined image processing on the image data output from the photodetection device 2.

The electronic apparatus M may include a recording unit 5. The recording unit 5 records image data from the photodetection device 2. The recording unit 5 may be arranged in a server or the like connected via a network.

The control unit 4 controls the imaging timing of the photodetection device 2 and the like via a control line 13. For example, the control unit 4 controls start and end of imaging of the photodetection device 2 according to an operation of a shutter operation member (not illustrated).

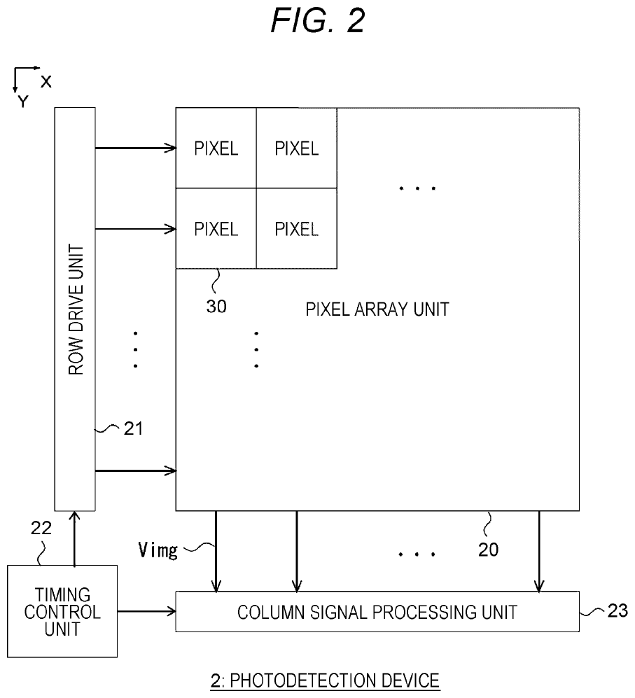

FIG. 2 is a block diagram of the photodetection device 2 according to the first embodiment of the present disclosure. The photodetection device 2 includes a pixel array unit 20, a row drive unit 21, a timing control unit 22, and a column signal processing unit 23.

The pixel array unit 20 includes a plurality of pixels 30 arranged in a first direction X and a second direction Y. In the present specification, the left-right (horizontal) direction in FIG. 2 is referred to as the first direction X, and the top-down (vertical) direction in FIG. 2 is referred to as the second direction Y. Furthermore, a group of pixels 30 arranged along the first direction X is referred to as a pixel row, and a group of pixels 30 arranged along the second direction Y is referred to as a pixel column.

Each of the pixels 30 includes a photoelectric conversion element that generates charge according to the amount of incident light. A pixel circuit (not illustrated in FIG. 1) connected to the pixel 30 generates a pixel signal Vimg on the basis of the charge of the photoelectric conversion element.

The row drive unit 21 includes a shift register, an address decoder, and the like. The row drive unit 21 drives each pixel 30 of the pixel array unit 20 at the same time for all pixels or in units of pixel rows. The row drive unit 21 sweeps charge and reads signals for each pixel 30 and the pixel circuit.

In the sweeping of charge, unnecessary charge is swept (reset) from the photoelectric conversion element of the pixel 30. As a result, the photoelectric conversion element in the pixel 30 can start new exposure. The operation of discarding the charge of the photoelectric conversion element and newly starting exposure (starting to store charge) is also called an electronic shutter operation.

The photodetection device 2 performs a global shutter operation of simultaneously starting exposure in all the pixels. The global shutter operation has a feature that since the exposure timing is not shifted for each pixel, distortion due to the shift of the exposure timing does not occur in the captured image.

In the reading of the signal, the pixel signal Vimg based on the charge stored in the photoelectric conversion element in the pixel 30 is read from the pixel circuit. The period from the electronic shutter operation to the reading of the signal is also referred to as an exposure period. The pixel signal Vimg is a signal corresponding to the amount of light incident on the pixel 30 within the exposure period.

The timing control unit 22 includes a timing generator that generates various timing signals and the like. The timing control unit 22 controls the reading and sweeping timings of the row drive unit 21, the driving of the column signal processing unit 23, and the like on the basis of various timing signals.

The pixel signal Vimg output from each pixel 30 and the pixel circuit in the pixel array unit 20 is supplied to the column signal processing unit 23 via a vertical signal line. The column signal processing unit 23 performs predetermined signal processing on the pixel signal Vimg. For the predetermined signal processing, for example, analog-to-digital conversion of the pixel signal Vimg is performed. Furthermore, the column signal processing unit 23 performs correlated double sampling (CDS) in some cases.

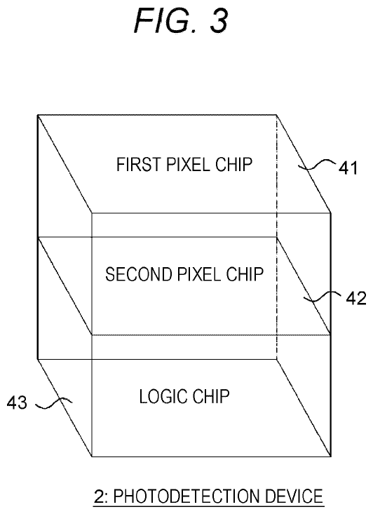

The photodetection device 2 is configured by laminating, for example, three chips (semiconductor substrates). FIG. 3 is a diagram illustrating a laminated structure of the photodetection device 2 according to the first embodiment of the present disclosure. The photodetection device 2 is configured by laminating a first pixel chip 41, a second pixel chip 42, and a logic chip 43 in this order. These chips are joined by vias or the like. Note that these chips may be bonded by Cu—Cu bonding or bumps in addition to vias. In the present specification, the first pixel chip 41 may be referred to as a first substrate, the second pixel chip 42 may be referred to as a second substrate, and the logic chip 43 may be referred to as a third substrate.

In the first pixel chip 41, for example, a plurality of pixels 30 in the pixel array unit 20 is arranged. In the second pixel chip 42, a plurality of pixel circuits each connected to a plurality of or one pixel 30 is arranged. Detailed configurations of the first pixel chip 41 and the second pixel chip 42 will be described later. In the logic chip 43, for example, logic circuits that mainly perform digital signal processing such as the row drive unit 21, the timing control unit 22, and the column signal processing unit 23 are arranged.

Note that although FIG. 3 illustrates an example in which three chips are laminated, the number of laminated chips is arbitrary, and a circuit or the like arranged on each chip can be changed according to the number of laminated chips. For example, a plurality of pixels 30 and a plurality of pixel circuits may be arranged on one pixel chip. In addition, the above-described logic circuits may be dispersedly arranged on two or more logic chips.

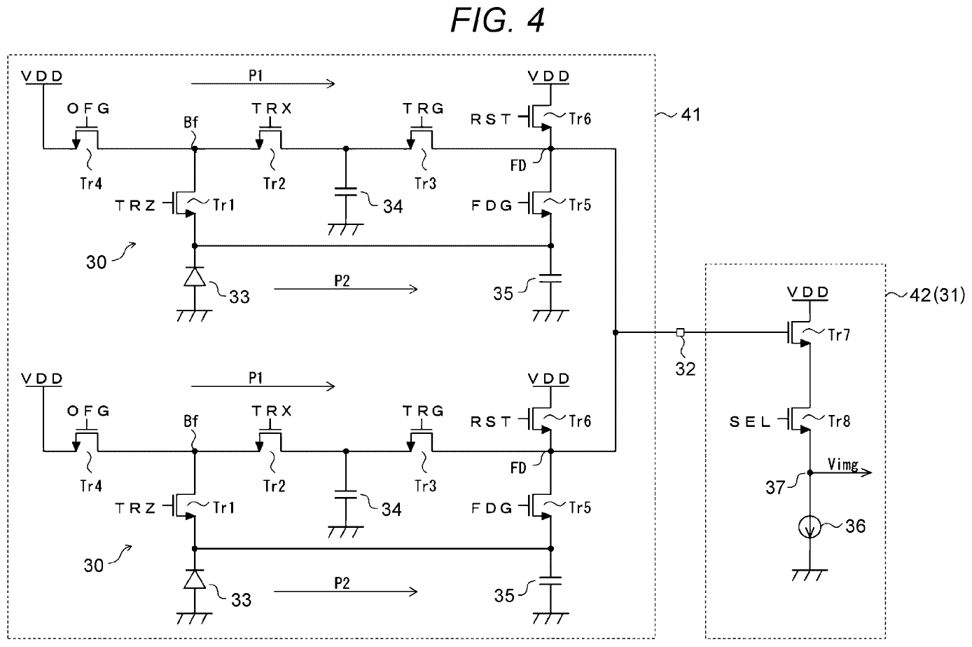

FIG. 4 is a circuit diagram of the pixel 30 and a pixel circuit 31 according to the first embodiment of the present disclosure. In the example of FIG. 4, two pixels 30 share one pixel circuit 31, but this is merely an example. One pixel circuit 31 may be arranged for each pixel 30, or three or more pixels 30 may share one pixel circuit 31. Note that in the present specification, a pixel region arranged in the first pixel chip 41 is referred to as the pixel 30, and a pixel region arranged in the second pixel chip 42 is referred to as the pixel circuit 31. In addition, all the pixel regions of the first pixel chip 41 and the second pixel chip 42 are collectively referred to as the pixel array unit 20. The first pixel chip 41 and the second pixel chip 42 are bonded at a bonding portion 32. The bonding portion 32 is formed of a via, a bump, a contact, wiring, Cu—Cu bonding, or the like.

Each of the two pixels 30 includes a photoelectric conversion element 33, transfer transistors Tr1, Tr2, and Tr3, a transfer transistor (third transistor) Tr4, a conversion efficiency transistor (first transistor) Tr5, a reset transistor Tr6, a global shutter (GS) memory (first retention unit) 34, and an overflow (OF) memory (second retention unit) 35. A buffer unit Bf is arranged between the transfer transistors Tr1, Tr2, and Tr4. A floating diffusion FD is arranged between the transfer transistor Tr3, the conversion efficiency transistor Tr5, and the reset transistor Tr6. The transistors included in the pixel 30 are also collectively referred to as a pixel transistor.

The pixel circuit 31 includes an amplification transistor Tr7, a selection transistor Tr8, and a current source 36.

In the present specification, an example in which all the transistors of the pixel 30 and the pixel circuit 31 are constituted by, for example, N channel metal-oxide-semiconductor (NMOS) transistors will be described. Note, however, that at least some of the above-described transistors may be configured by, for example, P channel metal-oxide-semiconductor (PMOS) transistors.

The photoelectric conversion element 33 is, for example, a photodiode, and generates and stores charge corresponding to the amount of incident light. The photoelectric conversion element 33 includes an anode and a cathode. One of the anode or the cathode (for example, the cathode) of the photoelectric conversion element 33 is connected to the transfer transistor Tr1, and the other (for example, the anode) is connected to a predetermined reference voltage node such as a ground voltage.

The transfer transistor Tr1 is arranged between the photoelectric conversion element 33 and the buffer unit Bf. The transfer transistor Tr1 switches whether or not to transfer the charge of the photoelectric conversion element 33 to the buffer unit Bf on the basis of a transfer signal TRZ supplied at a predetermined timing. The transfer transistor Tr1 includes, for example, a vertical transistor.

The buffer unit Bf includes, for example, an n-type semiconductor region. The buffer unit Bf provides a potential well between the photoelectric conversion element 33 and the GS memory 34. As a result, the buffer unit Bf prevents leakage (blooming) of charge from the photoelectric conversion element 33 to the GS memory 34.

The transfer transistor Tr2 is arranged between the buffer unit Bf and the GS memory 34. The transfer transistor Tr2 switches whether or not to transfer the charge retained in the buffer unit Bf to the GS memory 34 on the basis of a transfer signal TRX supplied at a predetermined timing.

The GS memory 34 temporarily retains the charge of the photoelectric conversion element 33 in order to implement a global shutter of the photodetection device 2. The charge of the photoelectric conversion element 33 is simultaneously transferred to the GS memory 34 in all the pixels 30 in the pixel array unit 20 in accordance with the end of the exposure period. The charge retained by the GS memory 34 is sequentially read by the pixels 30 in the pixel array unit 20.

The pixel 30 has a first transfer path P1 for transferring charge from the photoelectric conversion element 33 to the GS memory 34. The first transfer path P1 includes the transfer transistor Tr1, the buffer unit Bf, and the transfer transistor Tr2.

The transfer transistor Tr3 is arranged between the GS memory 34 and the floating diffusion FD. The transfer transistor Tr3 switches whether or not to transfer the charge retained by the GS memory 34 to the floating diffusion FD on the basis of a transfer signal TRG supplied at the signal read timing for each pixel 30.

The transfer transistor Tr4 is arranged between a predetermined high-voltage side power supply voltage node VDD and the buffer unit Bf. The transfer transistor Tr4 is used to discard the charge overflowing from the photoelectric conversion element 33 (and the OF memory 35). A transfer signal OFG is supplied to the transfer transistor Tr4.

The OF memory 35 retains the charge overflowing from the photoelectric conversion element 33 during the exposure period. The OF memory 35 is, for example, a lateral overflow storage capacitor (lateral overflow integration capacitor; LOFIC). One end of the OF memory 35 is connected to the cathode of the photoelectric conversion element 33 and the conversion efficiency transistor Tr5. The other end of the OF memory 35 is connected to a predetermined reference voltage node such as a ground voltage. The OF memory 35 includes, for example, an inter-wiring capacitance, a diffusion layer, or the like.

The pixel 30 has a second transfer path P2 for transferring charge from the photoelectric conversion element 33 to the OF memory 35. The second transfer path P2 includes, for example, an impurity diffusion region (first diffusion region). Details of the first diffusion region will be described later.

The conversion efficiency transistor Tr5 is arranged between the OF memory 35 and the floating diffusion FD. The conversion efficiency transistor Tr5 switches whether or not to transfer the charge retained by the OF memory 35 to the floating diffusion FD on the basis of a conversion efficiency signal FDG supplied at the signal read timing for each pixel 30.

When the incident light on the pixel 30 has low illuminance, almost all of the charge stored in the photoelectric conversion element 33 is transferred to and retained in the GS memory 34 via the transfer transistors Tr1 and Tr2. In a case where the amount of incident light is equal to or greater than a predetermined light amount (first light amount), a part of the charge stored in the photoelectric conversion element 33 is also transferred to and retained in the OF memory 35. Therefore, in a case where the amount of incident light is equal to or greater than a predetermined light amount (first light amount), the retained charge of the OF memory 35 is transferred to the floating diffusion FD via the transfer transistor Tr5.

The floating diffusion FD is also referred to as a charge-voltage conversion unit because it converts the charge transferred from the photoelectric conversion element 33 via the transfer transistors Tr1, Tr2, and Tr3 into a voltage signal. Charge is transferred from the GS memory 34 to the floating diffusion FD in a signal read period. In addition, in a case where the amount of incident light is equal to or greater than the first light amount, charge is transferred from the OF memory 35 to the floating diffusion FD. As a result, the floating diffusion FD can convert the charge stored in the photoelectric conversion element 33 into a voltage faithfully reflecting the charge even in a case where the amount of incident light is large. The voltage of the floating diffusion FD is supplied to the gate of the amplification transistor Tr7 of the pixel circuit 31.

The reset transistor Tr6 controls sweeping of the charge of the pixel 30. The reset transistor Tr6 is arranged between the floating diffusion FD and the high-voltage side power supply voltage node VDD. The reset transistor Tr6 switches whether or not to discharge the charge retained by the floating diffusion FD to the high-voltage side power supply voltage node VDD on the basis of a reset signal RST supplied at the timing of sweeping the charge of the pixel 30.

When the charge of the floating diffusion FD is discharged to the high-voltage side power supply voltage node VDD, the floating diffusion FD is reset. By resetting the floating diffusion FD, the pixel 30 can expose the next frame.

The amplification transistor Tr7 in the pixel circuit 31 is used as an input unit of the source follower circuit. The amplification transistor Tr7 has one end connected to the selection transistor Tr8 and the other end connected to the high-voltage side power supply voltage node VDD. Furthermore, the voltage of the floating diffusion FD is supplied to the amplification transistor Tr7. The amplification transistor Tr7 supplies a voltage signal (pixel signal) based on the voltage of the floating diffusion FD to the selection transistor Tr8.

The selection transistor Tr8 controls reading of the pixel signal output from the pixel 30. The selection transistor Tr8 outputs the pixel signal Vimg from an output node 37 on the basis of a selection signal SEL supplied at the signal read timing of the pixel 30. The voltage level of the pixel signal Vimg output from the output node 37 is a voltage level corresponding to the voltage of the floating diffusion FD.

As illustrated in FIG. 4, the pixel 30 retains the charge overflowing from the photoelectric conversion element 33 at the time of exposure in the OF memory 35. As a result, the pixel 30 and the pixel circuit 31 can generate the pixel signal Vimg on the basis of charge equal to or greater than the saturation charge amount of the photoelectric conversion element 33, and the dynamic range of the pixel signal Vimg can be expanded.

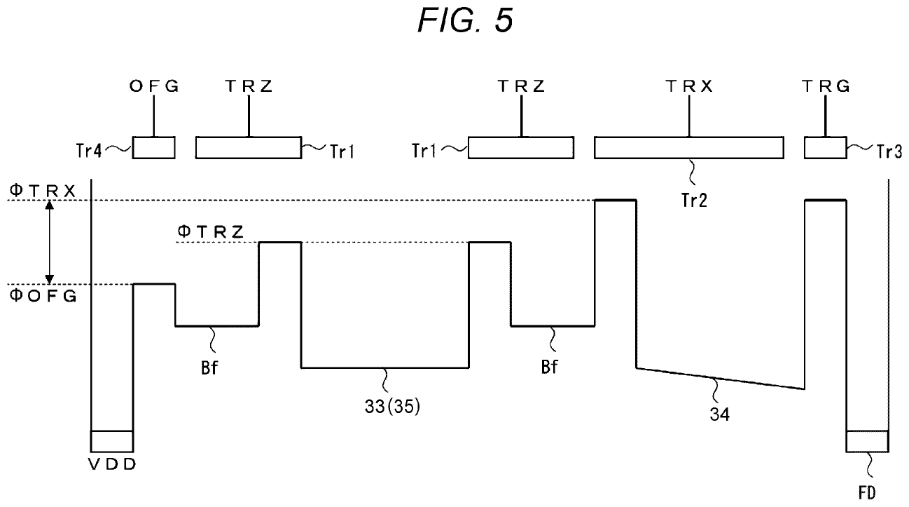

FIG. 5 is a diagram illustrating potentials of the pixel 30 and the pixel circuit 31, and illustrates an example in which the potential is lower toward the upper side in the vertical direction and the potential is higher toward the lower side. As illustrated in FIG. 4, the photoelectric conversion element 33 is connected to the GS memory 34 or the high-voltage side power supply voltage node VDD via the buffer unit Bf. A potential barrier ΦTRZ between the photoelectric conversion element 33 and the buffer unit Bf is controlled by the transfer signal TRZ. A potential barrier ΦTRX between the buffer unit Bf and the GS memory 34 is controlled by the transfer signal TRX. A potential barrier ΦOFG between the buffer unit Bf and the high-voltage side power supply voltage node VDD is controlled by the transfer signal OFG.

The charge exceeding the saturation charge amount of the photoelectric conversion element 33 and exceeding the potential barrier ΦTRZ is accumulated in the potential well of the buffer unit Bf. The charge accumulated in the potential well of the buffer unit Bf can be transferred to either the GS memory 34 or the high-voltage side power supply voltage node VDD. Here, by making the potential barrier ΦOFG sufficiently lower than the potential barrier ΦTRX, the charge accumulated in the potential well of the buffer unit Bf is discharged to the high-voltage side power supply voltage node VDD. As a result, there is no possibility that charge is transferred to the GS memory 34 in a period other than the exposure period.

The potential design illustrated in FIG. 5 improves blooming characteristics in which charge leaks from the photoelectric conversion element 33 to the GS memory 34 in a period other than the exposure period. In addition, a backflow afterimage characteristic in which charge flows back from the GS memory 34 to the photoelectric conversion element 33 is improved.

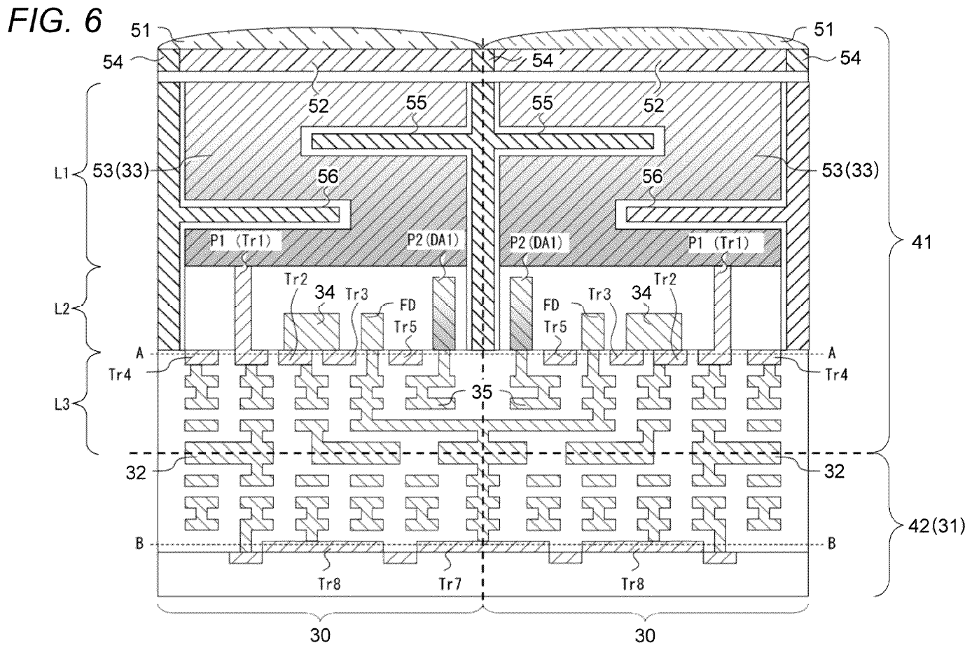

FIG. 6 is a cross-sectional view of the photodetection device 2 according to the first embodiment of the present disclosure. The photodetection device 2 of FIG. 6 is a back-illuminated type. The first pixel chip 41 in FIG. 6 includes a first region L1, a second region L2, and a third region L3 in this order from the back surface side. In the present specification, the first region L1 and the second region L2 are referred to as semiconductor regions. A plurality of pixels 30 is arranged in the semiconductor region. A lens portion 51 and a color filter 52 are arranged for each pixel 30 on the back surface side of the first region L1. Note that in the pixel 30 in FIG. 6, a part of the pixel circuit 31 such as the reset transistor Tr6 and the buffer unit Bf are omitted.

In the first region L1, a semiconductor layer 53 is arranged. In the second region L2, a part of the transfer transistor Tr1, the GS memory 34, the floating diffusion FD, and a first diffusion region DA1 are arranged. In the third region L3, pixel transistors and the like are arranged. Specifically, the remaining part of the transfer transistor Tr1, the transfer transistors Tr2 to Tr5, the conversion efficiency transistor Tr5, the OF memory 35, and the wiring layer are arranged in the third region L3.

The lens portion 51, the color filter 52, and the semiconductor layer 53 are laminated in this order. The lens portion 51 condenses incident light on the pixel 30. The color filter 52 separates the incident light for each wavelength. A light shielding portion 54 is provided between the adjacent pixels 30. The light shielding portion 54 prevents incident light on one pixel 30 from leaking and mixing to another adjacent pixel 30.

The semiconductor layer 53 is a layer whose impurity concentration changes in the depth direction of the semiconductor region, and includes the photoelectric conversion element 33. Light shielding portions 55 and 56 are partially arranged inside the semiconductor layer 53. The light shielding portions 55 and 56 are provided to prevent leakage and mixture of incident light into the GS memory 34. The GS memory 34 is arranged so as to at least partially overlap the light shielding portions 55 and 56 in plan view of the semiconductor region. FIG. 6 illustrates an example in which two light shielding portions are provided inside the semiconductor layer 53, but the present invention is not limited thereto. Furthermore, the cross-sectional shapes and sizes of the light shielding portions 55 and 56 are not limited to those illustrated in FIG. 6.

The photoelectric conversion element 33 transfers charge to the third region L3 via the first transfer path P1 and the second transfer path P2. The first transfer path P1 includes the transfer transistor Tr1 that is a vertical transistor extending from the second region L2 to the third region L3. The second transfer path P2 in FIG. 6 includes the first diffusion region DA1. The first diffusion region DA1 is a region where the impurity concentration changes continuously or stepwise in the depth direction of the semiconductor region from the photoelectric conversion element 33. The first diffusion region DA1 is formed by, for example, implanting impurities into first pixel chip 41 and thermally diffusing the impurities.

At the time of exposure, the potential barrier formed by the voltage applied to the first diffusion region DA1 connected to the OF memory 35 is made higher than the potential barrier formed by the voltage applied to a transfer gate TRX of the transfer transistor Tr2. As a result, the stored charge of the photoelectric conversion element 33 is first retained in the GS memory 34 through the transfer transistors Tr1 and Tr2. When the retained charge of the GS memory 34 reaches the saturation charge amount, the stored charge of the photoelectric conversion element 33 passes through the first diffusion region DA1 and is retained in the OF memory 35.

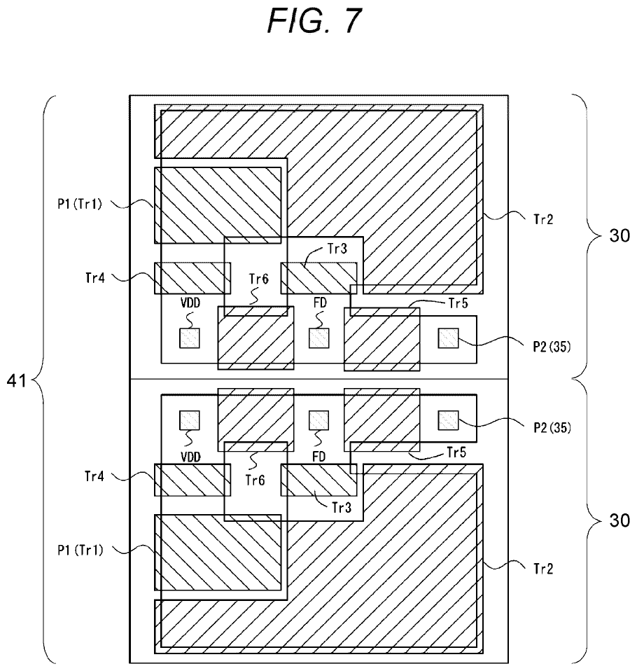

FIG. 7 is a plan layout diagram of the first pixel chip 41 according to the first embodiment of the present disclosure. FIG. 7 illustrates a planar layout taken along line A-A in FIG. 6. The two pixels 30 sharing the pixel circuit 31 are in contact with each other on one side. Along this side, a connection portion with the high-voltage side power supply voltage node VDD, the reset transistor Tr6, a connection portion with the floating diffusion FD, the conversion efficiency transistor Tr5, and a connection portion with the OF memory 35 (second transfer path P2) are arranged in this order from the left side of FIG. 7.

The transfer transistor Tr2 is arranged along a side opposite to the side with which the two pixels 30 are in contact. A connection portion with the high-voltage side power supply voltage node VDD, the transfer transistor Tr4, the transfer transistor Tr1, and the transfer transistor Tr2 are arranged in this order along one of the remaining two sides of the pixel 30. A connection portion with the OF memory 35 and the transfer transistor Tr2 are arranged in this order along a side opposite to this side. The transfer transistor Tr3 is arranged substantially at the center of the pixel 30.

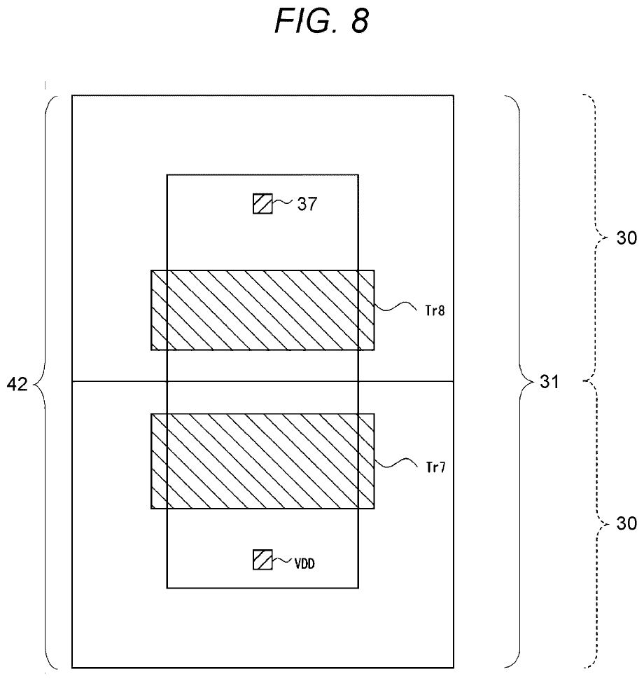

FIG. 8 is a plan layout diagram of the second pixel chip 42 according to the first embodiment of the present disclosure. FIG. 8 illustrates a planar layout taken along line B-B in FIG. 6. The pixel circuit 31 in FIG. 8 is shared by the two pixels 30 in FIG. 7. In the pixel circuit 31, the output node 37, the selection transistor Tr8, the amplification transistor Tr7, and a connection portion with the high-voltage side power supply voltage node VDD are arranged in this order from the upper side of FIG. 8 in the direction in which the two pixels 30 of FIG. 7 are adjacent to each other.

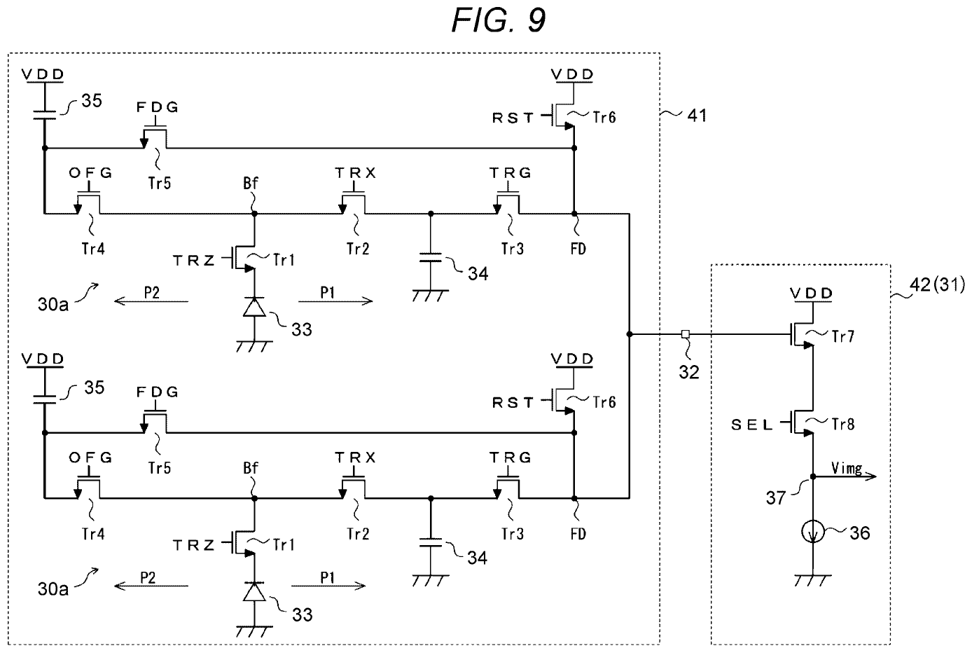

As illustrated in FIG. 4, the OF memory 35 of the first embodiment is connected to the photoelectric conversion element 33 through a transfer path (second transfer path P2) different from the transfer transistor Tr4 and the high-voltage side power supply voltage node VDD. The OF memory 35 may be arranged between the transfer transistor Tr4 and the high-voltage side power supply voltage node VDD. FIG. 9 is a circuit diagram of a pixel 30a and a pixel circuit 31 according to a modification of the first embodiment of the present disclosure.

FIG. 9 is different from FIG. 4 in the connection portion of an OF memory 35. The OF memory 35 of FIG. 9 is arranged between a transfer transistor Tr4 and a high-voltage side power supply voltage node VDD. The charge overflowing from a photoelectric conversion element 33 is transferred to the OF memory 35 through a second transfer path P2. The second transfer path P2 includes a transfer transistor Tr1, a buffer unit Bf, and the transfer transistor Tr4.

As described with reference to FIG. 5, since the potential barrier of the transfer transistor Tr4 is sufficiently lower than the potential barrier of a transfer transistor Tr2, the charge overflowing from the photoelectric conversion element 33 is preferentially transferred to the OF memory 35 rather than a GS memory 34.

A conversion efficiency transistor Tr5 of FIG. 9 has one end connected to the OF memory 35 and the transfer transistor Tr4 and the other end connected to a reset transistor Tr6 and a floating diffusion FD.

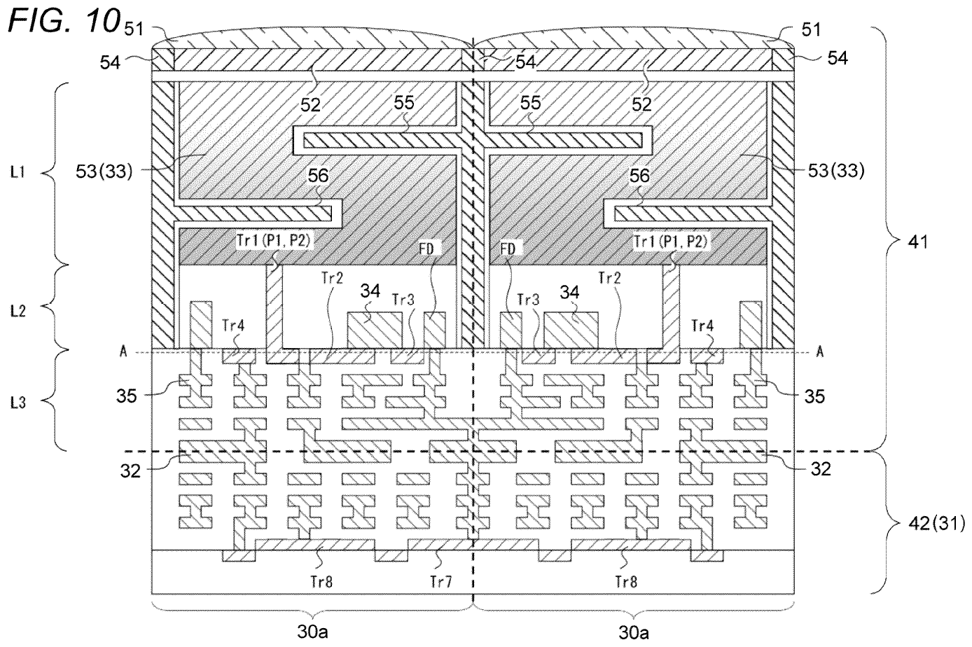

FIG. 10 is a cross-sectional view of a photodetection device 2 according to the modification of the first embodiment of the present disclosure. A pixel 30a illustrated in FIG. 10 is different from the pixel 30 illustrated in FIG. 6 in that the first diffusion region DA1 is not provided. A first transfer path P1 and the second transfer path P2 in FIG. 10 share the transfer transistor Tr1. Note that the conversion efficiency transistor Tr5 is omitted in FIG. 10.

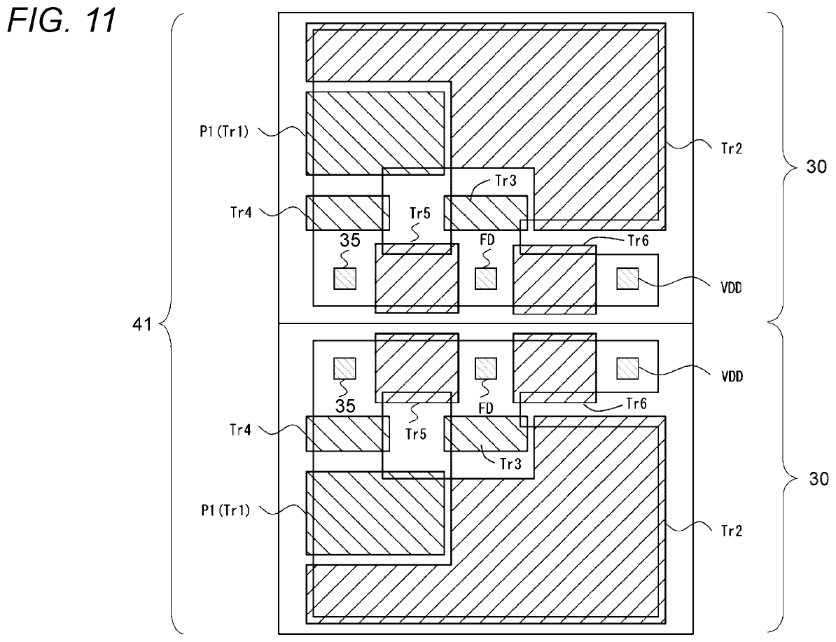

FIG. 11 is a plan layout diagram of a first pixel chip 41 according to the modification of the first embodiment of the present disclosure. The pixel 30a in FIG. 11 is different from the pixel 30 in FIG. 7 in the locations where the connection portion with the OF memory 35, the conversion efficiency transistor Tr5, the reset transistor Tr6, and a connection portion with the high-voltage side power supply voltage node VDD are arranged.

In FIG. 11, the connection portion with the OF memory 35, the conversion efficiency transistor Tr5, the connection portion with the floating diffusion FD, the reset transistor Tr6, and the connection portion with the high-voltage side power supply voltage node VDD are arranged in this order from the left side of FIG. 11 along the side with which the two pixels 30a sharing the pixel circuit 31 are in contact. A connection portion with the OF memory 35 is arranged instead of the connection portion with the high-voltage side power supply voltage node VDD in FIG. 7 on the side where the transfer transistor Tr1 and the transfer transistor Tr2 are arranged. Furthermore, on a side opposite to this side, a connection portion with the high-voltage side power supply voltage node VDD is arranged instead of the connection portion with the OF memory 35 in FIG. 7.

Note that the planar layout of a second pixel chip 42 according to the modification of the first embodiment is the same as that illustrated in FIG. 8.

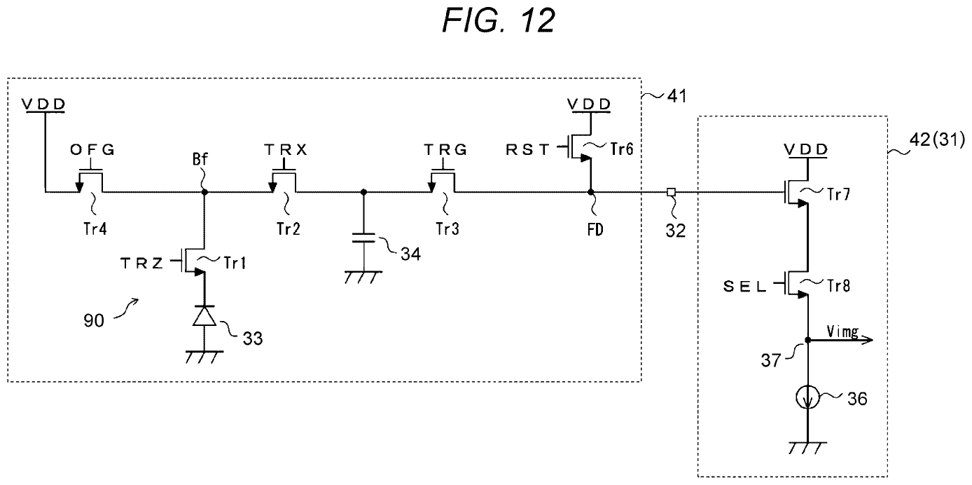

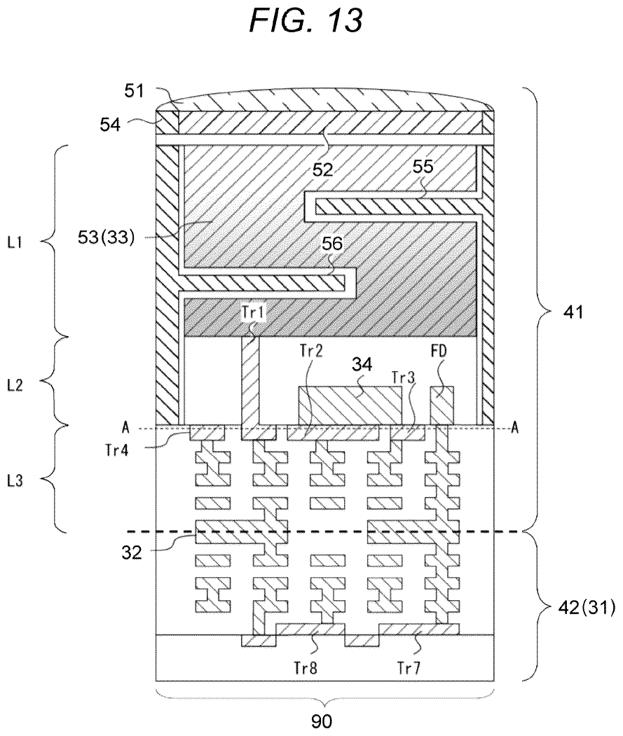

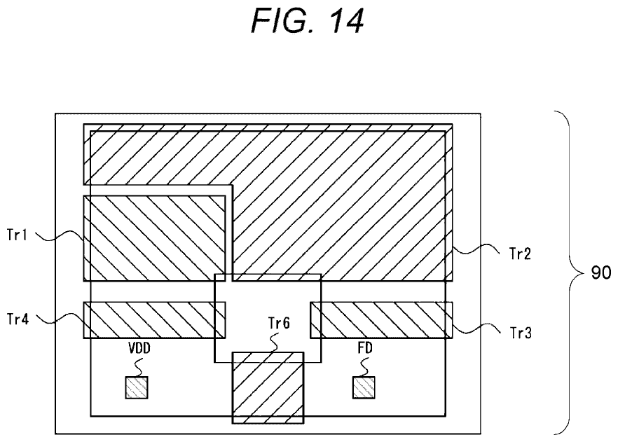

FIG. 12 is a circuit diagram of a pixel 90 according to a first comparative example. FIG. 13 is a cross-sectional view of the pixel 90 and a pixel circuit 31 according to the first comparative example. FIG. 14 is a plan layout diagram of a first pixel chip 41 according to the first comparative example. The pixel 90 of the first comparative example is different from the pixel 30 of the first embodiment of the present disclosure in not including the OF memory 35, the conversion efficiency transistor Tr5, and the first diffusion region DA1.

Since the pixel 90 according to the first comparative example does not have the OF memory 35, the charge overflowing from a photoelectric conversion element 33 is discharged to a high-voltage side power supply voltage node VDD via a transfer transistor Tr4. Therefore, the pixel 90 cannot expand the dynamic range beyond the saturation charge amount of the photoelectric conversion element 33.

Note that FIGS. 12 to 14 illustrate an example in which one pixel 90 includes one pixel circuit 31, but the same applies to a case where two or more pixels 90 share the pixel circuit 31.

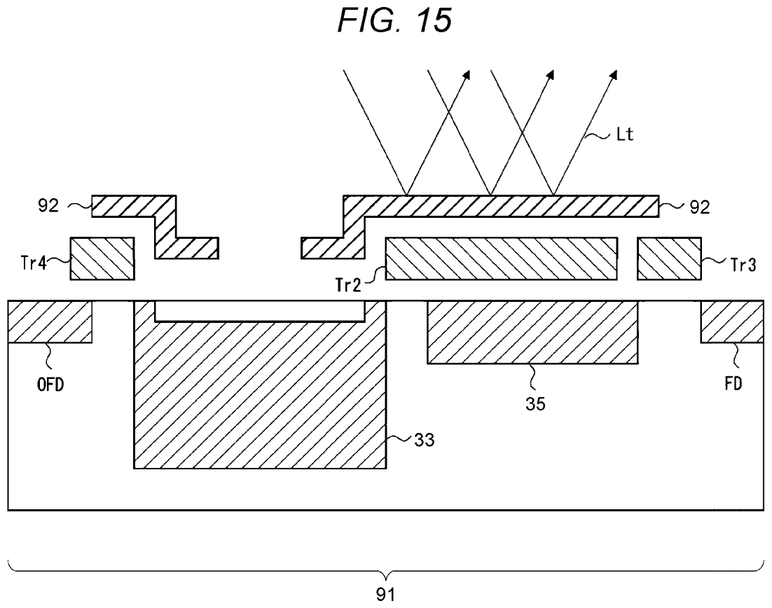

FIG. 15 is a block diagram illustrating a cross-sectional configuration of a pixel 91 according to a second comparative example. The pixel 91 is different from the configuration of the pixel 30 illustrated in FIG. 6 in that a photoelectric conversion element 33 and a GS memory 34 are arranged on the same plane. The pixel 91 in FIG. 15 includes an overflow drain OFD and a light shielding film 92.

Furthermore, the pixel 91 is a front-illuminated type. In the pixel 30 of FIG. 6, incident light is incident on a surface opposite to a surface of the photoelectric conversion element 33 on which the pixel transistor is arranged, whereas in the pixel 91 of FIG. 15, incident light Lt is incident on a surface of the photoelectric conversion element 33 on which the pixel transistor is arranged.

The overflow drain OFD is connected to a high-voltage side power supply voltage node VDD (not illustrated in FIG. 15). When sweeping out the charge of the photoelectric conversion element 33, a transfer transistor Tr4 discharges the charge of the photoelectric conversion element 33 to the high-voltage side power supply voltage node VDD via the overflow drain OFD.

The light shielding film 92 is arranged so as to cover the GS memory 34. The light shielding film 92 prevents the incident light Lt from entering the GS memory 34.

Compared with the pixel 30 of FIG. 6, in the pixel 91 of FIG. 15, the photoelectric conversion element 33 and the GS memory 34 are arranged on the same plane. The area required for the pixel 30 is the area of the photoelectric conversion element 33, the via, and the like. In addition to this, the pixel 91 requires the area of the GS memory 34. Therefore, it is difficult to miniaturize the pixel 91 as compared with the pixel 30.

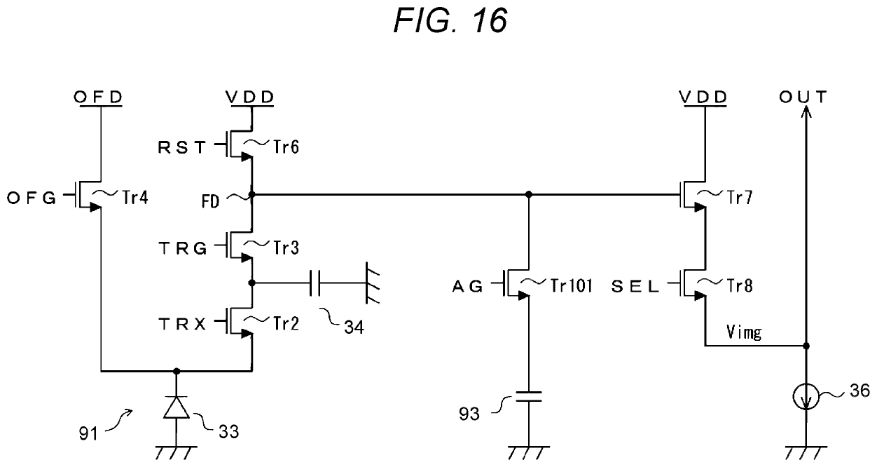

FIG. 16 is a circuit diagram of the pixel 91 according to the second comparative example. The pixel 91 according to the second comparative example does not include the transfer transistor Tr1 and the buffer unit Bf. Furthermore, instead of the OF memory 35 and the conversion efficiency transistor Tr5 in FIG. 4, the pixel 91 includes an OF memory 93 and a transfer transistor Tr101. Note that in FIG. 16, the overflow drain OFD is omitted.

One end of the transfer transistor Tr101 is connected to the OF memory 93, and the other end is connected to a floating diffusion FD and an amplification transistor Tr7. A transfer signal AG is supplied to the transfer transistor Tr101. The OF memory 93 retains charge overflowing from the photoelectric conversion element 33 via the transfer transistor Tr101. In addition, the OF memory 93 transfers the charge overflowing from the photoelectric conversion element 33 to the floating diffusion FD via the transfer transistor Tr101.

The pixel 91 can expand the dynamic range of a pixel signal Vimg by the OF memory 93, similarly to the pixel 30 according to the first embodiment of the present disclosure.

However, the configuration of FIG. 16 is based on the premise that the charge overflowing from the photoelectric conversion element 33 is transferred to the OF memory 93 via the floating diffusion FD. On the other hand, in the configuration in which the photoelectric conversion element 33 and the GS memory 34 are arranged on different planes as illustrated in FIG. 6 and other drawings, the charge overflowing from the photoelectric conversion element 33 is discharged to the high-voltage side power supply voltage node VDD without passing through the floating diffusion FD in order to improve the blooming characteristics.

Therefore, the OF memory 93 and the transfer transistor Tr101 illustrated in FIG. 16 cannot be applied to a configuration in which the photoelectric conversion element 33 and the GS memory 34 are arranged on different planes.

As described above, in the pixel 30 according to the first embodiment of the present disclosure, the charge overflowing from the photoelectric conversion element 33 at the time of exposure can be retained in the OF memory 35, and the retained charge of the OF memory 35 can be transferred to the floating diffusion FD by turning on the transfer transistor Tr5. As a result, the pixel 30 can expand the dynamic range of the pixel signal Vimg.

Furthermore, the pixel 30 has the second transfer path P2 for transferring charge from the photoelectric conversion element 33 to the OF memory 35. The second transfer path P2 can transfer charge to the OF memory 35 without passing through a transfer transistor. As a result, the charge of the photoelectric conversion element 33 can be retained in the OF memory 35 without performing ON/OFF control of a transfer transistor.

By providing the OF memory 35 in this manner, the dynamic range of the pixel signal Vimg can be expanded. Furthermore, in the pixel 30 of the first embodiment, since the photoelectric conversion element 33 and the GS memory 34 are arranged in the depth direction of the semiconductor regions L1 and L2, it is possible to achieve both expansion of the dynamic range and high resolution as compared with the pixel 91 of the second comparative example in which the photoelectric conversion element 33 and the GS memory 34 are arranged on the same plane.

Note that the OF memory 35 and the second transfer path P2 of the present disclosure may be applied to a configuration in which the photoelectric conversion element 33 and the GS memory 34 are arranged on the same plane.

### Second Embodiment

As can be seen from the cross-sectional view of FIG. 6, in the photoelectric conversion element 33 according to the present embodiment, the photoelectric conversion element 33 and the GS memory 34 are arranged in the depth direction of the semiconductor region. Therefore, there is a possibility that charge generated by photoelectric conversion in the photoelectric conversion element 33 directly enters the GS memory 34, which may cause blooming. The second embodiment is characterized by preventing such a problem.

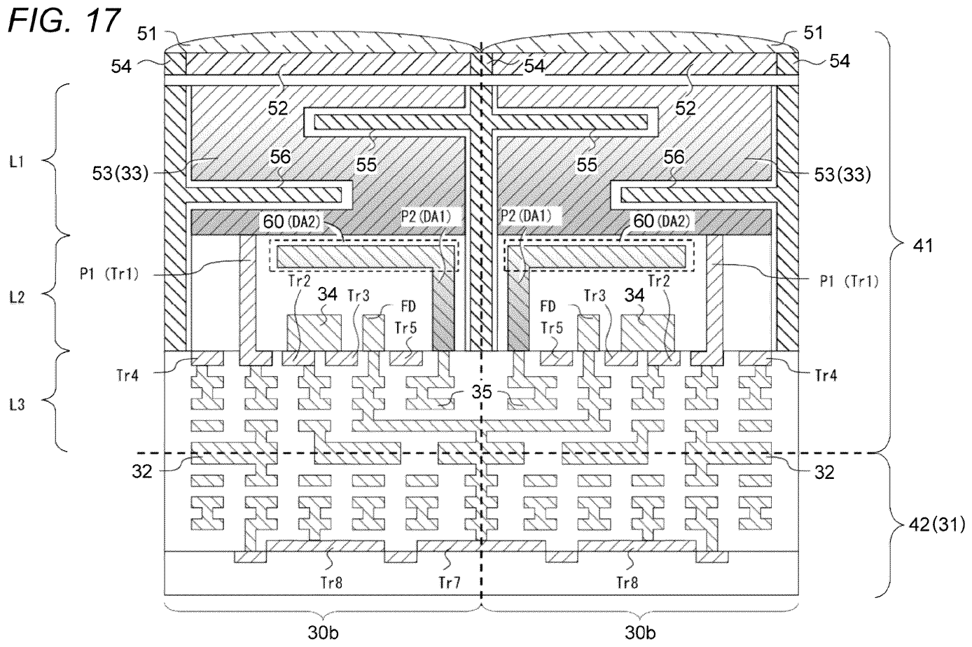

FIG. 17 is a cross-sectional view of a photodetection device 2 according to the second embodiment of the present disclosure. A pixel 30b illustrated in FIG. 17 includes a charge capturing portion 60 arranged between a photoelectric conversion element 33 and a GS memory 34. The charge capturing portion 60 includes a second diffusion region DA2.

As illustrated in FIG. 17, the charge capturing portion 60 is arranged in a second region L2 which is a part of a semiconductor region. Furthermore, the charge capturing portion 60 is arranged to cover the entire region of the GS memory 34 in plan view. Therefore, it is possible to prevent the charge generated by the photoelectric conversion element 33 from directly entering the GS memory 34.

The charge capturing portion 60 is connected to a second transfer path P2 (first diffusion region DA1), and can transfer the captured charge to an OF memory 35 via the second transfer path P2.

The second diffusion region DA2 which is a constituent material of the charge capturing portion 60 is a diffusion region in which the impurity concentration changes continuously or stepwise from the photoelectric conversion element 33 side to the GS memory 34 side.

Furthermore, the impurity concentration of first diffusion region DA1 connected to second diffusion region DA2 increases toward the side closer to the OF memory 35. As a result, the charge captured by the charge capturing portion 60 from the photoelectric conversion element 33 passes through the second diffusion region DA2 and the first diffusion region DA1 and is transferred to the OF memory 35.

As described above, since the pixel 30b according to the second embodiment covers the entire region of the GS memory 34 and includes the charge capturing portion 60 connected to the first diffusion region DA1, the stored charge of the photoelectric conversion element 33 can be efficiently transferred to the OF memory 35, and the stored charge of the photoelectric conversion element 33 can be prevented from directly entering the GS memory 34, whereby the blooming characteristics can be improved.

### Third Embodiment

Similarly to the first transfer path P1, the second transfer path P2 arranged between the photoelectric conversion element 33 and the OF memory 35 may include a vertical transistor.

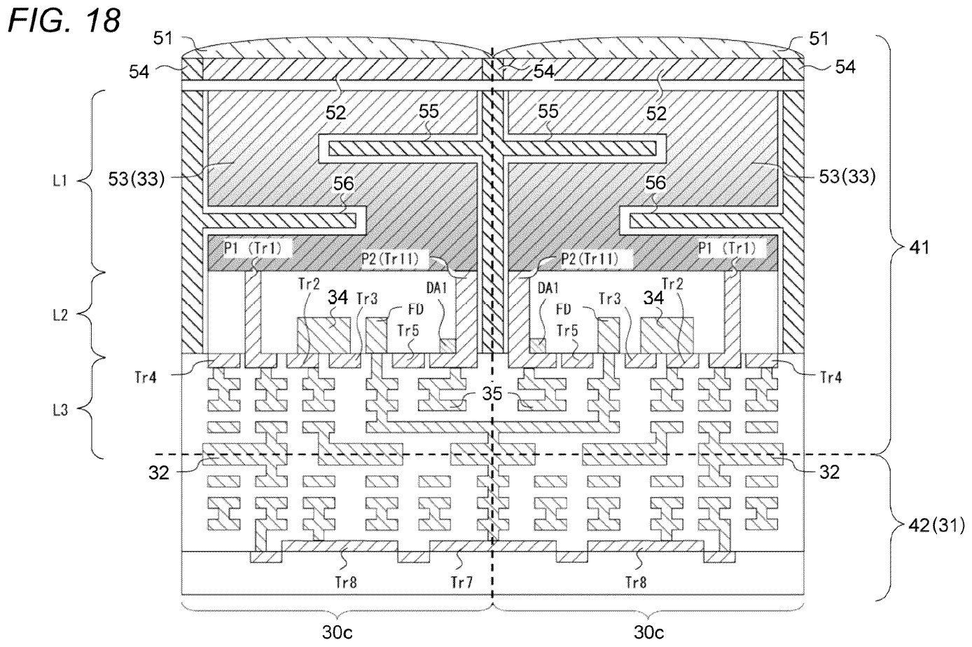

FIG. 18 is a cross-sectional view of a photodetection device 2 according to a third embodiment of the present disclosure. A pixel 30c illustrated in FIG. 18 includes a transfer transistor (second transistor) Tr11 arranged along a second transfer path P2.

The transfer transistor Tr11 is a vertical transistor extending from a photoelectric conversion element 33 to an OF memory 35 in the depth direction of a second region L2. The gate of the transfer transistor Tr11 is set to a predetermined potential. In the second transfer path P2 of FIG. 18, the potential barrier can be controlled by the potential of the gate of the transfer transistor Tr11.

As described above, in the third embodiment, since the second transfer path P2 arranged between the photoelectric conversion element 33 and the OF memory 35 is configured by a vertical transistor, the potential barrier of the second transfer path P2 can be optimized by controlling the gate voltage of the vertical transistor, and the charge overflowing from the photoelectric conversion element 33 at the time of exposure can be efficiently retained in the OF memory 35.

### Fourth Embodiment

In the first to third embodiments, the OF memory 35 and the conversion efficiency transistor Tr5 are arranged on the first pixel chip 41, but the OF memory 35 and the conversion efficiency transistor Tr5 may be arranged on the second pixel chip 42.

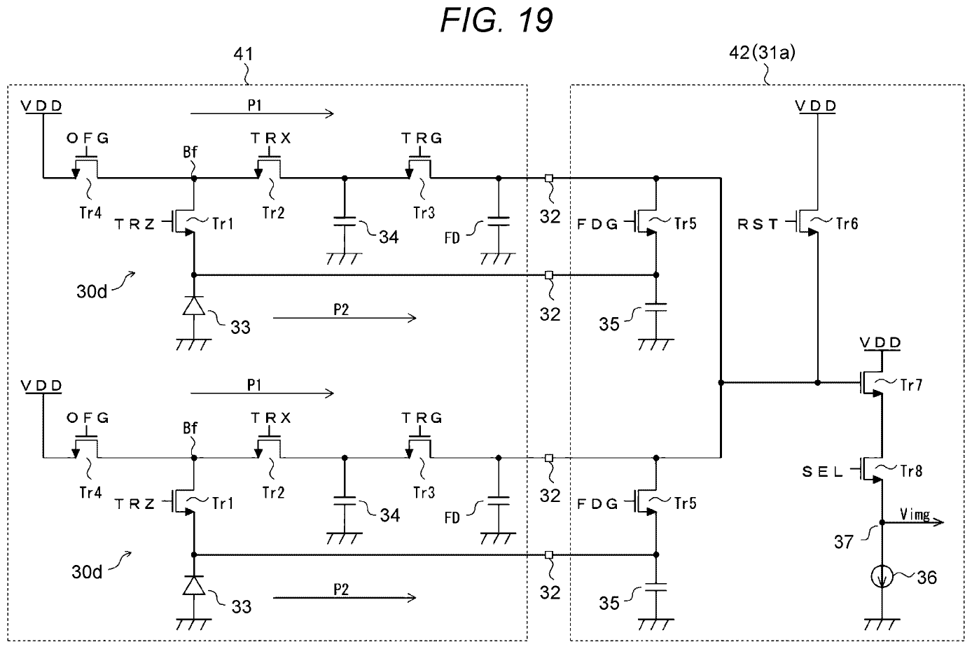

FIG. 19 is a circuit diagram of a pixel 30d and a pixel circuit 31a according to a fourth embodiment of the present disclosure. In FIG. 19, the pixel 30d arranged on a first pixel chip 41 does not include the OF memory 35 and the conversion efficiency transistor Tr5. On the other hand, the pixel circuit 31a arranged on a second pixel chip 42 includes an OF memory 35 and a conversion efficiency transistor Tr5 for each pixel 30d.

Furthermore, in FIG. 19, the pixel 30d does not include the reset transistor Tr6. On the other hand, the pixel circuit 31a includes a reset transistor Tr6 shared by the plurality of pixels 30d. Note that the pixel circuit 31a may include a reset transistor Tr6 for each pixel 30d.

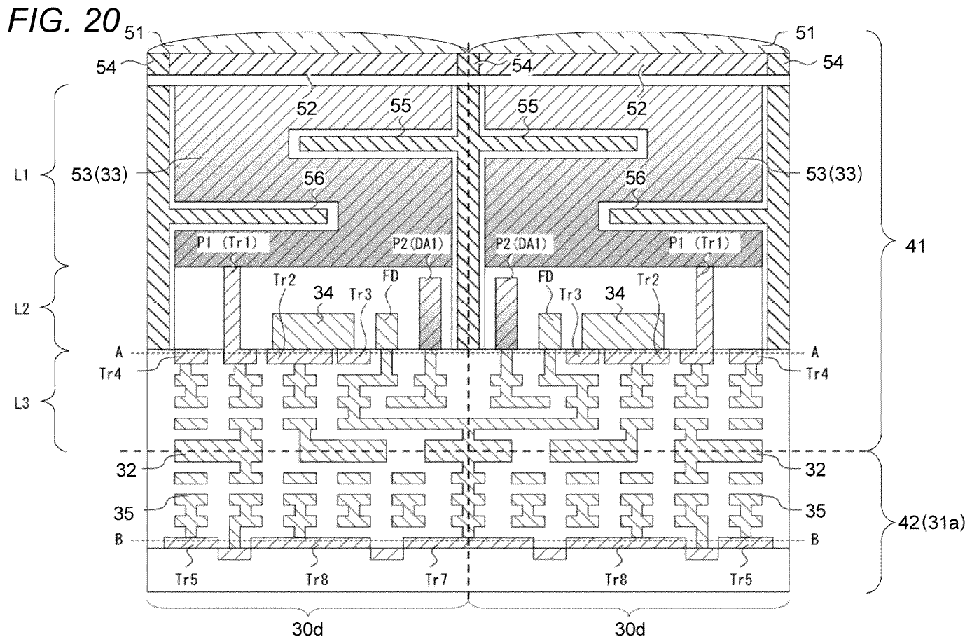

FIG. 20 is a cross-sectional view of a photodetection device 2 according to the fourth embodiment of the present disclosure. As described above, the conversion efficiency transistor Tr5 (and reset transistor Tr6) is arranged on the second pixel chip 42 side. As a result, the area of a GS memory 34 can be enlarged in the first pixel chip 41, and the charge retention amount of the GS memory 34 can be increased.

The OF memory 35 can include, for example, a wiring layer (and diffusion layer) of the second pixel chip 42. In addition, the OF memory 35 may include wiring layers (and diffusion layers) of both the first pixel chip 41 and the second pixel chip 42 via Cu—Cu bonding or the like of a bonding portion 32. As a result, it is easy to increase the capacitance of the OF memory 35.

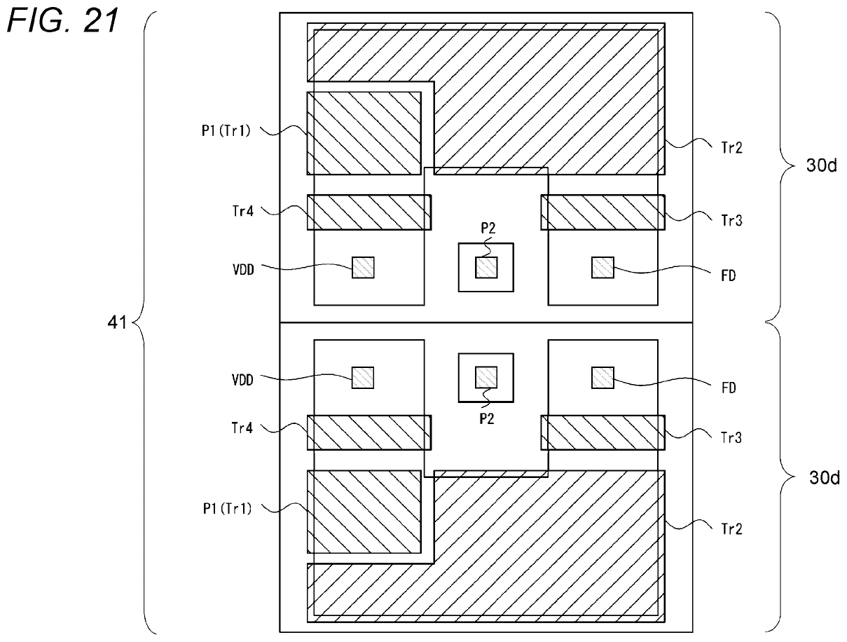

FIG. 21 is a plan layout diagram of the first pixel chip 41 according to the fourth embodiment of the present disclosure. As described above, the pixel 30d in FIG. 21 does not include the conversion efficiency transistor Tr5 and the reset transistor Tr6. Furthermore, in the pixel 30d, a second transfer path P2 is arranged in order to connect the OF memory 35 and a photoelectric conversion element 33.

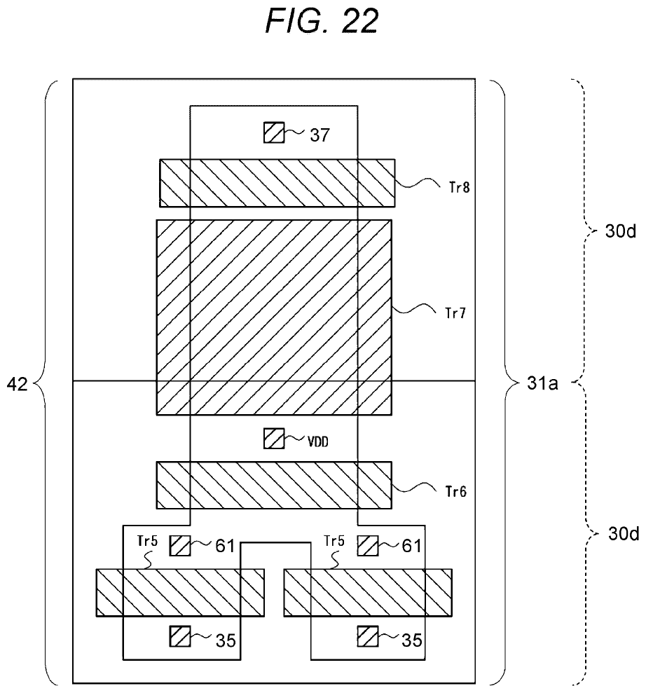

FIG. 22 is a plan layout diagram of the second pixel chip 42 according to the fourth embodiment of the present disclosure. In the pixel circuit 31a of FIG. 22, the reset transistor Tr6 is arranged on a side of a high-voltage side power supply voltage node VDD opposite to an amplification transistor Tr7. Furthermore, on a side of the reset transistor Tr6 opposite to the high-voltage side power supply voltage node VDD, a plurality of conversion efficiency transistors Tr5 and a plurality of connection portions with the OF memories 35 are arranged for each pixel 30d.

Between the reset transistor Tr6 and the conversion efficiency transistor Tr5 for each pixel 30d, a connection portion 61 with the floating diffusion FD is arranged for each pixel 30d. The connection portion 61 is used to transfer the charge of the OF memory 35 to the floating diffusion FD arranged on the first pixel chip 41 via the conversion efficiency transistor Tr5.

As described above, in the fourth embodiment, unlike the first to third embodiments, the OF memory 35 and the conversion efficiency transistor Tr5 are arranged not on the first pixel chip 41 but on the second pixel chip 42. As a result, the area of the GS memory 34 arranged on the first pixel chip 41 can be expanded, the capacitance of the GS memory 34 can be increased, and the capacitance of the OF memory 35 arranged on the second pixel chip 42 can also be increased.

### Fifth Embodiment

In the first to fourth embodiments, the example in which the conversion efficiency can be switched in two stages in the conversion efficiency transistor Tr5 has been described, but the conversion efficiency may be switched in three or more stages.

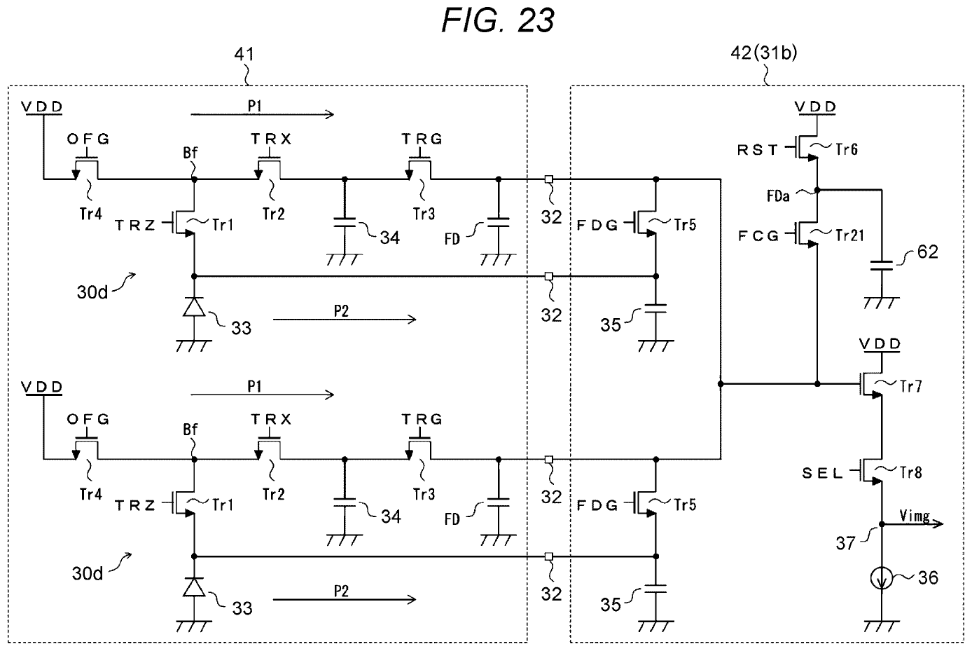

FIG. 23 is a circuit diagram of a pixel 30d and a pixel circuit 31b according to a fifth embodiment of the present disclosure. The pixel circuit 31b in FIG. 23 newly includes a conversion efficiency transistor (fourth transistor) Tr21 and a charge retention unit (third retention unit) 62. The conversion efficiency transistor Tr21 is arranged between a reset transistor Tr6 and an amplification transistor Tr7. The charge retention unit 62 is arranged between the reset transistor Tr6 and the conversion efficiency transistor Tr21. In addition, a floating diffusion FDa is arranged between the reset transistor Tr6, the conversion efficiency transistor Tr21, and the charge retention unit 62. Similarly to the reset transistor Tr6, the conversion efficiency transistor Tr21 and the charge retention unit 62 are shared by a plurality of pixels 30d.

Charge is transferred from a photoelectric conversion element 33 to the charge retention unit 62 via a floating diffusion FD and the conversion efficiency transistor Tr21. The capacitance of the charge retention unit 62 is smaller than the capacitance of an OF memory 35. The conversion efficiency transistor Tr21 switches whether or not to read the charge retained in the charge retention unit 62. In the floating diffusion FDa, the charge transferred from the pixel 30d, the charge transferred from the OF memory 35, and the charge retained by the charge retention unit 62 are combined. Note that charge transferred from the pixel 30d is more specifically charge transferred from a GS memory 34 of each pixel 30d.

In the example of FIG. 23, similarly to FIG. 19, the OF memory 35, a conversion efficiency transistor Tr5, and the reset transistor Tr6 are arranged on a second pixel chip 42 side, but the present invention is not limited thereto. At least one of the OF memory 35, the conversion efficiency transistor Tr5, the reset transistor Tr6, the conversion efficiency transistor Tr21, and the charge retention unit 62 may be arranged on a first pixel chip 41 side.

The pixel circuit 31b in FIG. 23 can output a first pixel signal Vimga based on the charge of the photoelectric conversion element 33, a second pixel signal Vimgb based on the charge obtained by combining the charge of the charge retention unit 62 with the charge of the photoelectric conversion element 33, and a third pixel signal Vimgc based on the charge obtained by combining the charge of the charge retention unit 62 and the OF memory 35 with the charge of the photoelectric conversion element 33. As described above, the first pixel signal Vimga is a pixel signal based on the retained charge of the GS memory 34. The second pixel signal Vimgb is a pixel signal based on the retained charge of the GS memory 34 and the charge retention unit 62. The third pixel signal Vimgc is a pixel signal based on the GS memory 34, the charge retention unit 62, and the OF memory 35.

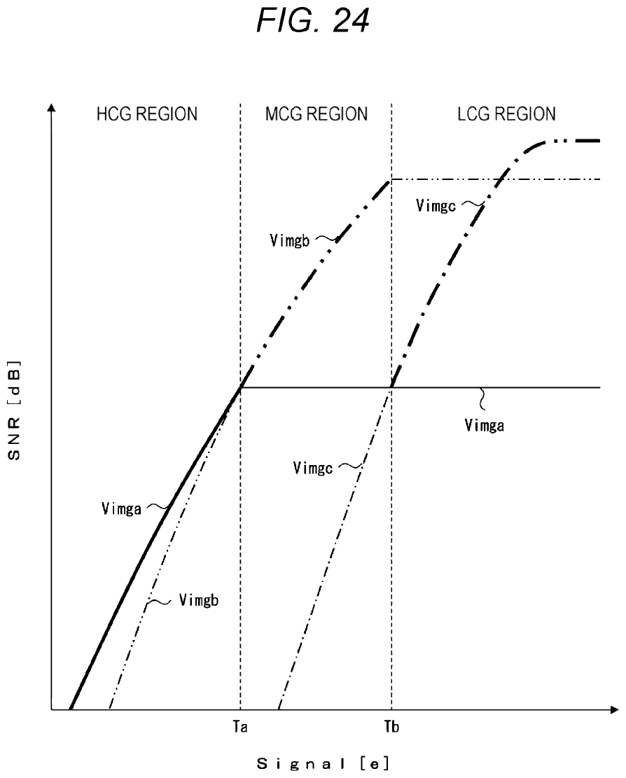

FIG. 24 is a graph illustrating signal characteristics of the first pixel signal Vimga, the second pixel signal Vimgb, and the third pixel signal Vimgc. In the graph of FIG. 24, the horizontal axis represents a signal amount (Signal), and the vertical axis represents a signal-noise rate (SNR). The SNR of the first pixel signal Vimga monotonously improves according to the signal amount up to a predetermined signal amount Ta of a second light amount, but is saturated and becomes constant when exceeding the signal amount Ta of the second light amount. The SNR of the second pixel signal Vimgb monotonously improves according to the signal amount up to a signal amount Tb of a predetermined third light amount, but is saturated and becomes constant when exceeding the signal amount Tb of the third light amount.

A region equal to or less than the signal amount Ta of the second light amount is also called a high conversion gain (HCG) region. A region greater than the signal amount Ta of the second light amount and equal to or less than the signal amount Tb of the third light amount is also called a middle conversion gain (MCG) region. A region greater than the signal amount Tb of the third light amount is also called a low conversion gain (LCG) region.

The pixel circuit 31b outputs the first pixel signal Vimga in the HCG region, outputs the second pixel signal Vimgb in the MCG region, and outputs the third pixel signal Vimgc in the LCG region. As a result, the pixel circuit 31b can improve the SNR of the pixel signal Vimg according to the signal amount in any of the HCG region, the MCG region, and the LCG region.

Note that when the second pixel signal Vimgb is switched to the third pixel signal Vimgc by the signal amount Tb, the SNR temporarily decreases, but since the SNR after the decrease is also sufficiently high, there is no possibility that the SNR becomes a problem.

The capacitance of the charge retention unit 62 is smaller than the capacitance of an OF memory 35. As a result, it is possible to provide the MCG region for reading out the charge of the photoelectric conversion element 33 and the charge retention unit 62 between the HCG region for reading out only the charge of the photoelectric conversion element 33 and the LCG region for reading out the charge of the OF memory 35.

In the signal amount Ta of the second light amount, the difference in SNR between the first pixel signal Vimga and the second pixel signal Vimgb is extremely small. Therefore, it can be considered that the SNR is monotonically improved even in the signal amount Ta of the second light amount. That is, by using the first pixel signal Vimga and the second pixel signal Vimgb, the pixel circuit 31b can continue to monotonically improve the SNR according to the signal amount in a wide range up to the signal amount Tb of the third light amount.

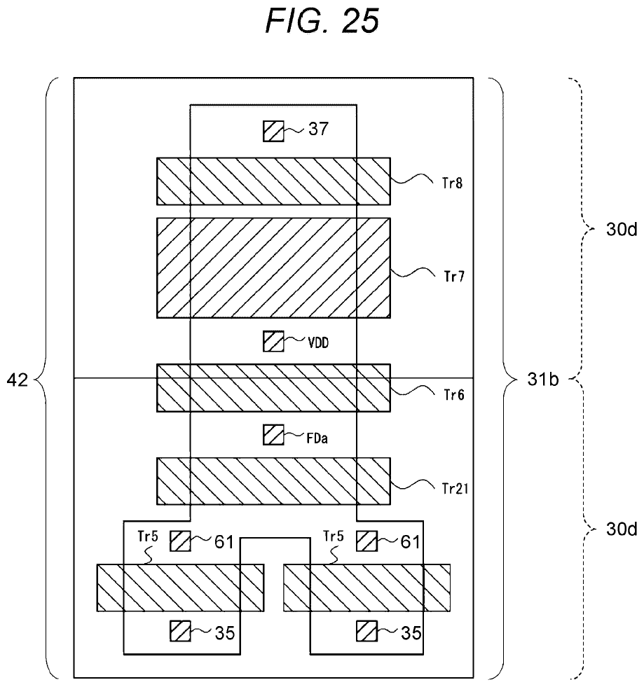

FIG. 25 is a plan layout diagram of the second pixel chip 42 according to the fifth embodiment of the present disclosure. The pixel circuit 31b in FIG. 25 includes the conversion efficiency transistor Tr21 between the reset transistor Tr6 and a connection portion 61 with the floating diffusion FD. In addition, a connection portion with the floating diffusion FDa is provided between the conversion efficiency transistor Tr21 and the reset transistor Tr6.

Note that the planar layout of the first pixel chip 41 according to the fifth embodiment is the same as that illustrated in FIG. 21.

As described above, by newly adding the conversion efficiency transistor Tr21 and the charge retention unit 62, the pixel circuit 31b according to the fifth embodiment can output the pixel signal Vimg separately in three levels according to the amount of incident light. As a result, the MCG region can be provided between the HCG region and the LCG region, the conversion efficiency can be switched in stages, and the SNR can be gradually increased over a wide range of the amount of incident light as the amount of incident light increases.

### Sixth Embodiment

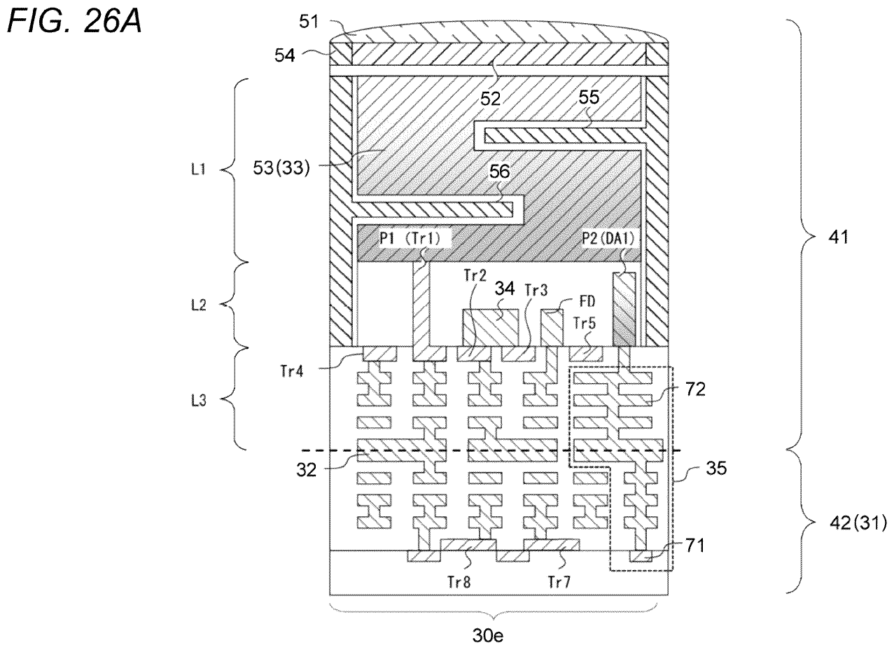

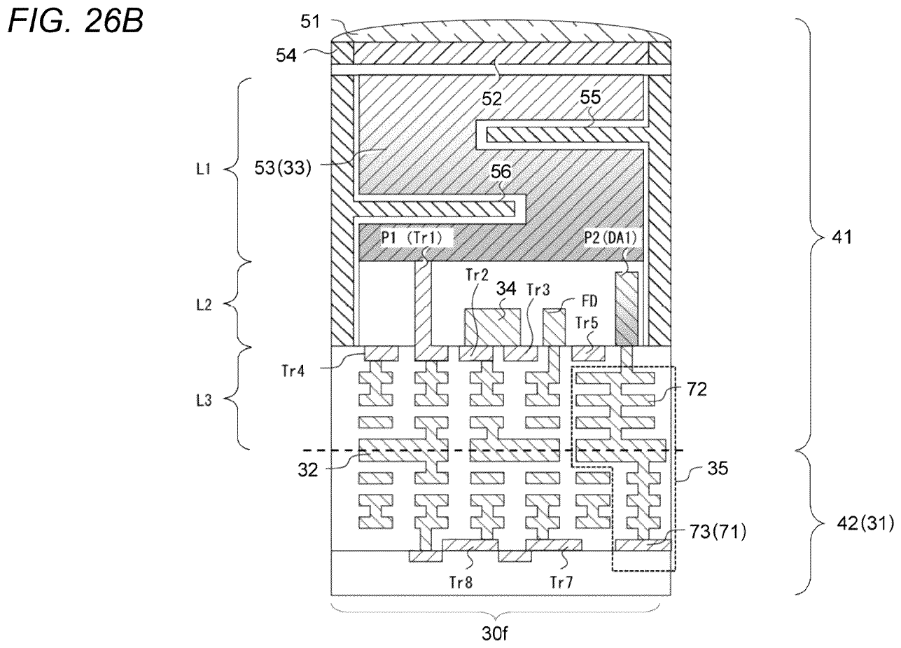

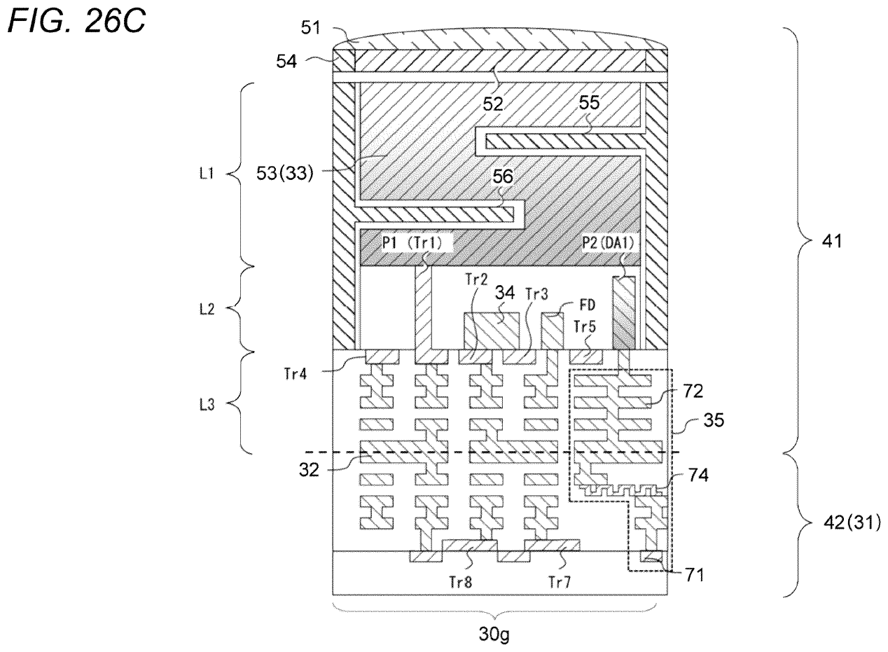

In the first embodiment, the OF memory 35 includes a diffusion layer or a wiring capacitance. Various modifications are conceivable for the structure of the OF memory 35. FIG. 26A is a cross-sectional view of a first example of a pixel 30 according to a sixth embodiment of the present disclosure. An OF memory 35 of a pixel 30e illustrated in FIG. 26A includes a diffusion layer 71 and a wiring capacitance 72. The diffusion layer 71 is arranged on a second pixel chip 42, for example. The wiring capacitance 72 may be arranged on a first pixel chip 41 or may be arranged on the second pixel chip 42. The OF memory 35 of FIG. 26A can retain more charge than the OF memory 35 according to the first embodiment.

FIG. 26B is a cross-sectional view of a second example of the pixel 30 according to the sixth embodiment of the present disclosure. An OF memory 35 of a pixel 30f illustrated in FIG. 26B includes a diffusion layer 71, a wiring capacitance 72, and a charge retention unit 73. The charge retention unit 73 is a metal-oxide-semiconductor (MOS) capacitor, and is arranged on a second pixel chip 42, for example. The OF memory 35 of FIG. 26B can retain even more charge than the OF memory 35 of FIG. 26A.

FIG. 26C is a cross-sectional view of a third example of the pixel 30 according to the sixth embodiment of the present disclosure. An OF memory 35 of a pixel 30g illustrated in FIG. 26B includes a diffusion layer 71, a wiring capacitance 72, and a charge retention unit 74. The charge retention unit 74 is a metal-insulator-metal (MIM) capacitor. The charge retention unit 74 may be arranged on a first pixel chip 41 or may be arranged on a second pixel chip 42. The OF memory 35 of FIG. 26C can retain even more charge than the OF memory 35 of FIG. 26B.

As described above, the OF memory 35 can increase the charge retention amount by optimizing its structure. As a result, the pixels 30e, 30f, and 30g of the sixth embodiment can retain more charge overflowing from a photoelectric conversion element 33, and can further expand the dynamic range of a pixel signal Vimg.

### First Application Example

As illustrated in FIG. 3, for example, the photodetection device according to the first to sixth embodiments described above can be configured by a laminated chip in which the first pixel chip (first substrate) 41, the second pixel chip (second substrate) 42, and the logic chip (third substrate) 43 are laminated. Hereinafter, an example of a specific form of this type of laminated chip will be described. Note that in the following, a configuration of a rolling shutter photodetection device will be described, but the present invention can also be applied to the global shutter photodetection devices according to the first to sixth embodiments by adding the GS memory 34 and the OF memory 35.

### 1. Embodiment

### [Functional Configuration of Imaging Device 1]

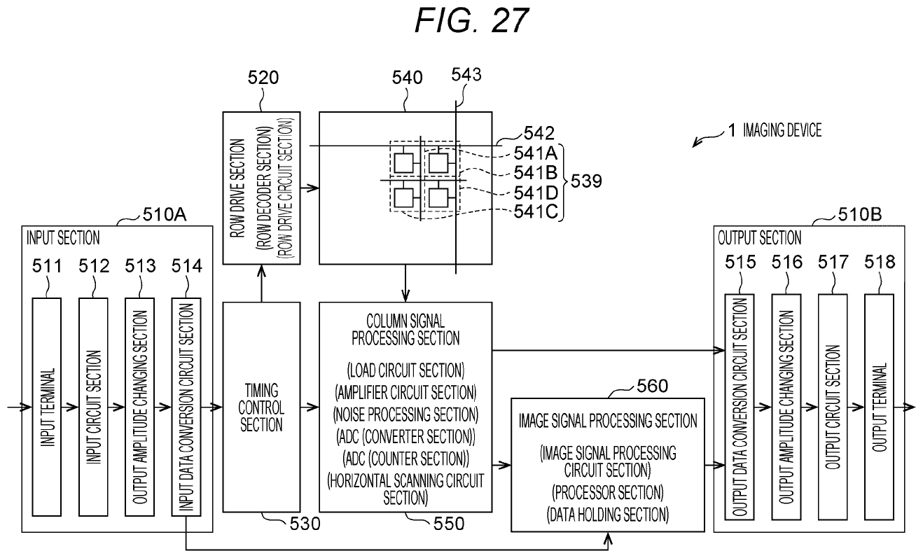

FIG. 27 is a block diagram illustrating an example of a functional configuration of an imaging device (imaging device 1) according to a first application example of the present disclosure.

The imaging device 1 of FIG. 27 includes, for example, an input section 510A, a row drive section 520, a timing control section 530, a pixel array section 540, a column signal processing section 550, an image signal processing section 560, and an output section 510B.

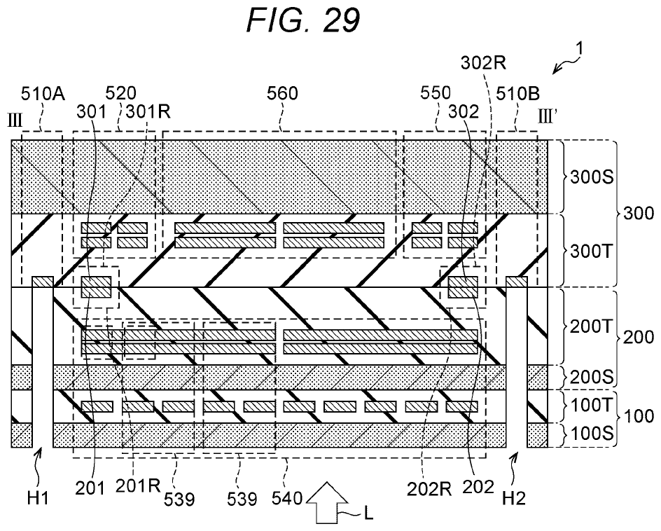

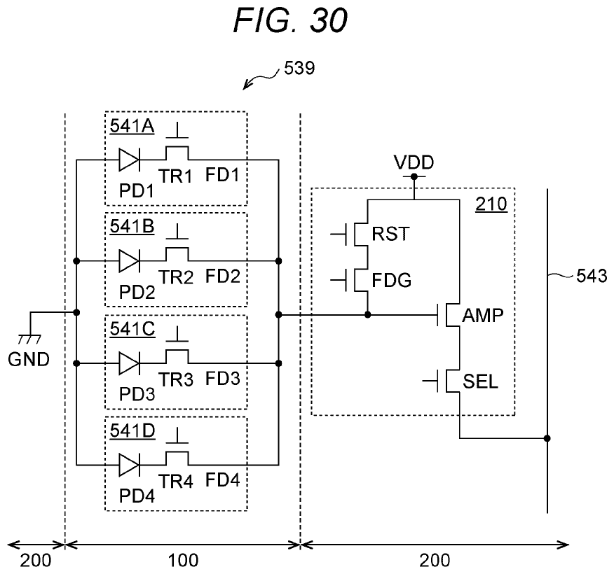

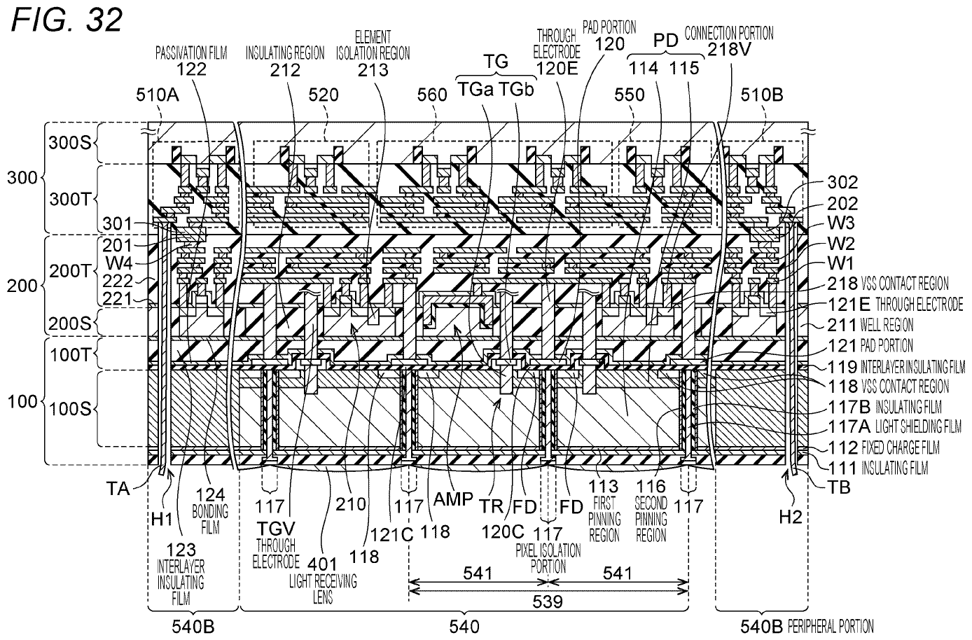

In the pixel array section 540, pixels 541 are repeatedly arranged in an array. More specifically, a pixel sharing unit 539 including a plurality of pixels is a unit of repetition, and is repeatedly arranged in an array in a row direction and a column direction. Note that in the present specification, the row direction will also be referred to as an H direction, and the column direction perpendicular to the row direction will also be referred to as a V direction for convenience. In the example of FIG. 27, each pixel sharing unit 539 includes four pixels (pixels 541A, 541B, 541C, and 541D). Each of the pixels 541A, 541B, 541C, and 541D includes a photodiode PD (illustrated in FIG. 32 and the like referred to later). The pixel sharing unit 539 is a unit in which one pixel circuit (a pixel circuit 210 in FIG. 29 referred to later) is shared. In other words, one pixel circuit (the pixel circuit 210 described later) is provided for every four pixels (pixels 541A, 541B, 541C, and 541D). By operating the pixel circuit in a time division manner, pixel signals of the individual pixels 541A, 541B, 541C, and 541D are sequentially read. The pixels 541A, 541B, 541C, and 541D are arranged in, for example, two rows and two columns. In the pixel array section 540, a plurality of row drive signal lines 542 and a plurality of vertical signal lines (column readout lines) 543 are provided together with the pixels 541A, 541B, 541C, and 541D. The row drive signal line 542 drives the pixels 541 included in each of the plurality of pixel sharing units 539 arranged in the pixel array section 540 side by side in the row direction. In the pixel sharing unit 539, each of the pixels arranged side by side in the row direction is driven. As will be described in detail later with reference to FIG. 30, the pixel sharing unit 539 is provided with a plurality of transistors. In order to drive each of the plurality of transistors, a plurality of row drive signal lines 542 is connected to one pixel sharing unit 539.

The pixel sharing unit 539 is connected to one of the vertical signal lines (column readout lines) 543. A pixel signal is read from each of the pixels 541A, 541B, 541C, and 541D included in the pixel sharing unit 539 via the vertical signal line (column readout line) 543.

The row drive section 520 includes, for example, a row address control section that determines a position of a row for driving pixels, that is, a row decoder section, and a row drive circuit section that generates signals for driving the pixels 541A, 541B, 541C, and 541D.

The column signal processing section 550 includes, for example, a load circuit section that is connected to the vertical signal line 543 and that forms a source follower circuit with the pixels 541A, 541B, 541C, and 541D (pixel sharing unit 539). The column signal processing section 550 may include an amplifier circuit section that amplifies signals read from the pixel sharing unit 539 via the vertical signal line 543. The column signal processing section 550 may include a noise processing section. In the noise processing section, for example, a noise level of a system is removed from the signals read from the pixel sharing unit 539 as a result of photoelectric conversion.

The column signal processing section 550 includes, for example, an analog-to-digital converter (ADC). In the analog-to-digital converter, the signal read from the pixel sharing unit 539 or the noise-processed analog signal described above is converted into a digital signal. The ADC includes, for example, a comparator section and a counter section. The comparator section compares an analog signal to be converted with a reference signal to be compared. In the counter section, the time until the comparison result in the comparator section is inverted is measured. The column signal processing section 550 may include a horizontal scanning circuit section that performs control for scanning a column to be read.

The timing control section 530 supplies a signal for controlling timing to the row drive section 520 and the column signal processing section 550 on the basis of a reference clock signal and a timing control signal input to the device.

The image signal processing section 560 is a circuit that performs various types of signal processing on data obtained as a result of photoelectric conversion, in other words, data obtained as a result of an imaging operation in the imaging device 1. The image signal processing section 560 includes, for example, an image signal processing circuit section and a data retention section. The image signal processing section 560 may include a processor section.

An example of the signal processing performed by the image signal processing section 560 is tone curve correction processing for providing a large number of gradations in a case where imaging data obtained as a result of AD conversion is data obtained by capturing an image of a dark subject and reducing the number of gradations in a case where imaging data obtained as a result of AD conversion is data obtained by capturing an image of a bright subject. In this case, it is desirable to store characteristic data regarding a tone curve in the data retention section of the image signal processing section 560 in advance to determine how the tone curve corrects gradation of imaging data.

The input section 510A is, for example, for inputting the above-described reference clock signal, the timing control signal, the characteristic data, and the like from the outside of the device to the imaging device 1. The timing control signal is, for example, a vertical synchronization signal, a horizontal synchronization signal, or the like. The characteristic data is, for example, to be stored in the data retention section of the image signal processing section 560. The input section 510A includes, for example, an input terminal 511, an input circuit section 512, an input amplitude changing section 513, an input data conversion circuit section 514, and a power supply section (not illustrated).

The input terminal 511 is an external terminal for inputting data. The input circuit section 512 is for taking a signal input to the input terminal 511 into the imaging device 1. In the input amplitude changing section 513, the amplitude of the signal captured by the input circuit section 512 is changed to an amplitude that can be easily used inside the imaging device 1. In the input data conversion circuit section 514, the arrangement of data strings of the input data is changed. The input data conversion circuit section 514 includes, for example, a serial-to-parallel conversion circuit. In this serial-to-parallel conversion circuit, a serial signal received as input data is converted into a parallel signal. Note that in the input section 510A, the input amplitude changing section 513 and the input data conversion circuit section 514 may be omitted. The power supply section supplies power set to various voltages required inside the imaging device 1 on the basis of power supplied to the imaging device 1 from the outside.

When the imaging device 1 is connected to an external memory device, the input section 510A may be provided with a memory interface circuit that receives data from the external memory device. The external memory device is, for example, a flash memory, an SRAM, a DRAM, or the like.

The output section 510B outputs image data to the outside of the device. The image data is, for example, image data captured by the imaging device 1, image data subjected to signal processing by the image signal processing section 560, and the like. The output section 510B includes, for example, an output data conversion circuit section 515, an output amplitude changing section 516, an output circuit section 517, and an output terminal 518.

The output data conversion circuit section 515 includes, for example, a parallel-to-serial conversion circuit, and in the output data conversion circuit section 515, a parallel signal used inside the imaging device 1 is converted into a serial signal. The output amplitude changing section 516 changes the amplitude of a signal used inside the imaging device 1. The signal having the changed amplitude is easily used in an external device connected to the outside of the imaging device 1. The output circuit section 517 is a circuit that outputs data from the inside of the imaging device 1 to the outside of the device, and wiring outside the imaging device 1 connected to the output terminal 518 is driven by the output circuit section 517. At the output terminal 518, data is output from the imaging device 1 to the outside of the device. In the output section 510B, the output data conversion circuit section 515 and the output amplitude changing section 516 may be omitted.

When the imaging device 1 is connected to an external memory device, the output section 510B may be provided with a memory interface circuit that outputs data to the external memory device. The external memory device is, for example, a flash memory, an SRAM, a DRAM, or the like.

[schematic Configuration of Imaging Device 1]

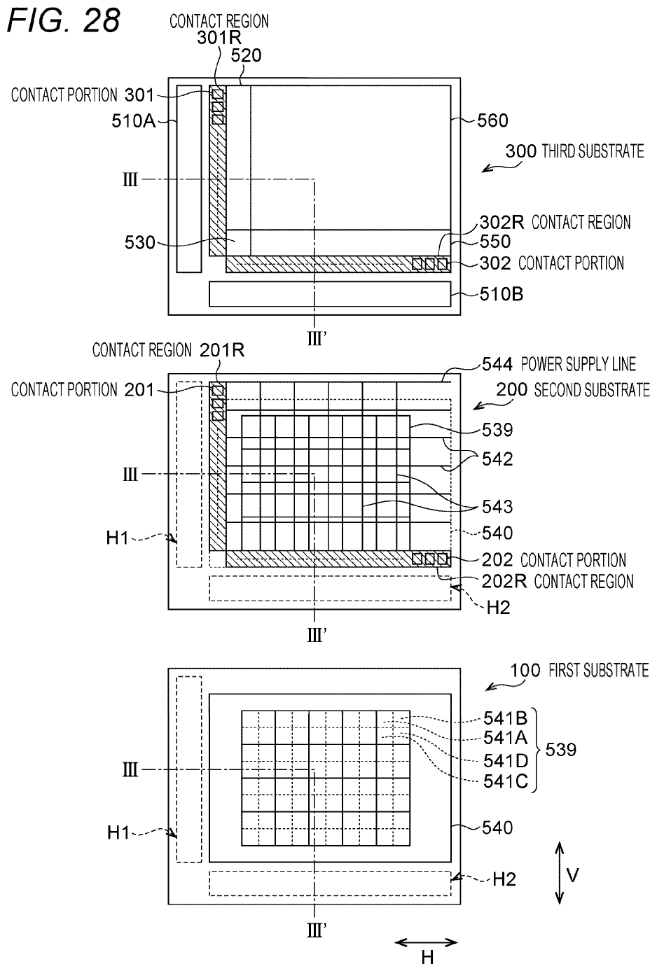

FIGS. 28 and 29 are diagrams illustrating an example of a schematic configuration of the imaging device 1. The imaging device 1 includes three substrates (first substrate 100, second substrate 200, and third substrate 300). FIG. 28 schematically illustrates planar configurations of the first substrate 100, the second substrate 200, and the third substrate 300, and FIG. 29 schematically illustrates a cross-sectional configuration of the first substrate 100, the second substrate 200, and the third substrate 300 laminated on each other. FIG. 29 corresponds to a cross-sectional configuration taken along line III-III′ illustrated in FIG. 28. The imaging device 1 is an imaging device having a three-dimensional structure formed by bonding three substrates (first substrate 100, second substrate 200, and third substrate 300). The first substrate 100 includes a semiconductor layer 100S and a wiring layer 100T. The second substrate 200 includes a semiconductor layer 200S and a wiring layer 200T. The third substrate 300 includes a semiconductor layer 300S and a wiring layer 300T. Here, a combination of wiring included in each of the first substrate 100, the second substrate 200, and the third substrate 300 and an interlayer insulating film around the wiring will be referred to as a wiring layer (100T, 200T, or 300T) provided in each substrate (the first substrate 100, the second substrate 200, and the third substrate 300) for convenience. The first substrate 100, the second substrate 200, and the third substrate 300 are laminated on each other in this order, and the semiconductor layer 100S, the wiring layer 100T, the semiconductor layer 200S, the wiring layer 200T, the wiring layer 300T, and the semiconductor layer 300S are arranged in this order along a laminating direction. Specific configurations of the first substrate 100, the second substrate 200, and the third substrate 300 will be described later. The arrow illustrated in FIG. 29 indicates the incident direction of light L on the imaging device 1. In the present specification, for convenience, in the following cross-sectional views, the light incident side in the imaging device 1 may be referred to as “lower”, “lower side”, and “lower direction”, and the side opposite to the light incident side may be referred to as “upper”, “upper side”, and “upper direction”. In addition, in the present specification, for convenience, in a substrate including a semiconductor layer and a wiring layer, a side of the wiring layer may be referred to as a front surface, and a side of the semiconductor layer may be referred to as a back surface. Note that the description of the specification is not limited to the above terms. The imaging device 1 is, for example, a back-illuminated imaging device in which light enters from the back surface side of the first substrate 100 having a photodiode.

Both the pixel array section 540 and the pixel sharing unit 539 included in the pixel array section 540 are configured using both the first substrate 100 and the second substrate 200. The first substrate 100 is provided with a plurality of pixels 541A, 541B, 541C, and 541D included in the pixel sharing unit 539. Each of these pixels 541 includes a photodiode (a photodiode PD described later) and a transfer transistor (a transfer transistor TR described later). The second substrate 200 is provided with a pixel circuit (the pixel circuit 210 described later) included in the pixel sharing unit 539. The pixel circuit reads the pixel signal transferred from the photodiode of each of the pixels 541A, 541B, 541C, and 541D via the transfer transistor, or resets the photodiode. In addition to such a pixel circuit, the second substrate 200 includes a plurality of row drive signal lines 542 extending in the row direction and a plurality of vertical signal lines 543 extending in the column direction. The second substrate 200 further includes a power supply line 544 extending in the row direction. The third substrate 300 includes, for example, the input section 510A, the row drive section 520, the timing control section 530, the column signal processing section 550, the image signal processing section 560, and the output section 510B. The row drive section 520 is provided, for example, in a region of the first substrate 100, the second substrate 200, and the third substrate 300 where a part thereof overlaps the pixel array section 540 in the laminating direction (hereinafter simply referred to as a laminating direction). More specifically, the row drive section 520 is provided in a region overlapping the vicinity of an end portion of the pixel array section 540 in an H direction in the laminating direction (FIG. 28). The column signal processing section 550 is provided, for example, in a region partially overlapping the pixel array section 540 in the laminating direction. More specifically, the column signal processing section 550 is provided in a region overlapping the vicinity of an end portion of the pixel array section 540 in a V direction in the laminating direction (FIG. 28). Although not illustrated, the input section 510A and the output section 510B may be arranged in a portion other than the third substrate 300, and, for example, may be arranged on the second substrate 200, instead. Alternatively, the input section 510A and the output section 510B may be provided on a back surface (light incident surface) side of the first substrate 100. Note that the pixel circuit provided in the second substrate 200 described above may be referred to as a pixel transistor circuit, a pixel transistor group, a pixel transistor, a pixel readout circuit, or a readout circuit as another name. In the present specification, the term “pixel circuit” is used.

The first substrate 100 and the second substrate 200 are electrically connected to each other by, for example, through electrodes (through electrodes 120E and 121E in FIG. 32 described later). The second substrate 200 and the third substrate 300 are electrically connected via, for example, a contact portion 201, 202, 301, or 302. The contact portions 201 and 202 are provided on the second substrate 200, and the contact portions 301 and 302 are provided on the third substrate 300. The contact portion 201 of the second substrate 200 is in contact with the contact portion 301 of the third substrate 300, and the contact portion 202 of the second substrate 200 is in contact with the contact portion 302 of the third substrate 300. The second substrate 200 includes a contact region 201R in which a plurality of contact portions 201 is provided and a contact region 202R in which a plurality of contact portions 202 is provided. The third substrate 300 includes a contact region 301R in which a plurality of contact portions 301 is provided and a contact region 302R in which a plurality of contact portions 302 is provided. The contact regions 201R and 301R are provided between the pixel array section 540 and the row drive section 520 in the laminating direction (FIG. 29). In other words, the contact regions 201R and 301R are provided, for example, in a region where the row drive section 520 (third substrate 300) and the pixel array section 540 (second substrate 200) overlap in the laminating direction or in a region in the vicinity thereof. The contact regions 201R and 301R are arranged, for example, in an end portion of such a region in the H direction (FIG. 28). In the third substrate 300, for example, the contact region 301R is provided at a position overlapping a part of the row drive section 520, or more specifically, an end portion of the row drive section 520 in the H direction (FIGS. 28 and 29). The contact portions 201 and 301 connect, for example, the row drive section 520 provided on the third substrate 300 and the row drive line 542 provided on the second substrate 200. For example, the contact portions 201 and 301 may connect the input section 510A provided on the third substrate 300 to the power supply line 544 and a reference potential line (reference potential line VSS described later). The contact regions 202R and 302R are provided between the pixel array section 540 and the column signal processing section 550 in the laminating direction (FIG. 29). In other words, the contact regions 202R and 302R are provided, for example, in a region where the column signal processing section 550 (third substrate 300) and the pixel array section 540 (second substrate 200) overlap in the laminating direction or in a vicinity region thereof. The contact regions 202R and 302R are arranged, for example, in an end portion of such a region in the V direction (FIG. 28). In the third substrate 300, for example, the contact region 301R is provided at a position overlapping with a part of the column signal processing section 550, or more specifically, an end portion of the column signal processing section 550 in the V direction (FIGS. 28 and 29). The contact portions 202 and 302 are, for example, for connecting a pixel signal (a signal corresponding to the amount of charge generated as a result of photoelectric conversion in a photodiode) output from each of the plurality of pixel sharing units 539 included in the pixel array section 540 to the column signal processing section 550 provided on the third substrate 300. The pixel signal is transmitted from the second substrate 200 to the third substrate 300.

FIG. 29 is an example of a cross-sectional view of the imaging device 1 as described above. The first substrate 100, the second substrate 200, and the third substrate 300 are electrically connected to each other via the wiring layers 100T, 200T, and 300T. For example, the imaging device 1 includes an electrical connection portion that electrically connects the second substrate 200 and the third substrate 300. Specifically, the contact portions 201, 202, 301, and 302 are constituted by an electrode constituted by a conductive material. The conductive material is constituted by, for example, a metal material such as copper (Cu), aluminum (Al), or gold (Au). The contact regions 201R, 202R, 301R, and 302R electrically connect the second substrate and the third substrate by directly bonding wires formed as electrodes, for example, and enable signal input and/or output between the second substrate 200 and the third substrate 300.

The electrical connection portion that electrically connects the second substrate 200 and the third substrate 300 to each other can be provided at a desired location. For example, as described as the contact regions 201R, 202R, 301R, and 302R in FIG. 29, the electrical connection portion may be provided in a region overlapping the pixel array section 540 in the laminating direction. In addition, the electrical connection portion may be provided in a region not overlapping the pixel array section 540 in the laminating direction. Specifically, the electrical connection portion may be provided in a region overlapping a peripheral portion arranged outside the pixel array section 540 in the laminating direction.

The first substrate 100 and the second substrate 200 are provided with, for example, connection holes H1 and H2. The connection holes H1 and H2 penetrate the first substrate 100 and the second substrate 200 (FIG. 29). The connection holes H1 and H2 are provided outside the pixel array section 540 (or portions overlapping the pixel array section 540) (FIG. 28). For example, the connection hole H1 is arranged outside the pixel array section 540 in the H direction, and the connection hole H2 is arranged outside the pixel array section 540 in the V direction. For example, the connection hole H1 reaches the input section 510A provided in the third substrate 300, and the connection hole H2 reaches the output section 510B provided in the third substrate 300. The connection holes H1 and H2 may be hollow, and at least a part thereof may contain a conductive material. For example, there is a configuration in which a bonding wire is connected to an electrode formed as the input section 510A and/or the output section 510B. Alternatively, there is a configuration in which the electrode formed as the input section 510A and/or the output section 510B is connected to the conductive material provided in the connection holes H1 and H2. The conductive material provided in the connection holes H1 and H2 may be embedded in a part or all of the connection holes H1 and H2, and the conductive material may be formed on the side walls of the connection holes H1 and H2.

Note that in FIG. 29, the input section 510A and the output section 510B are provided in the third substrate 300, but the present invention is not limited to thereto. For example, by sending a signal of the third substrate 300 to the second substrate 200 via the wiring layers 200T and 300T, the input section 510A and/or the output section 510B can be provided in the second substrate 200. Similarly, by sending a signal of the second substrate 200 to the first substrate 1000 via the wiring layers 100T and 200T, the input section 510A and/or the output section 510B can be provided on the first substrate 100.

FIG. 30 is an equivalent circuit diagram illustrating an example of configuration of the pixel sharing unit 539. The pixel sharing unit 539 includes the plurality of pixels 541 (FIG. 30 illustrates the four pixels 541, namely the pixels 541A, 541B, 541C, and 541D), one pixel circuit 210 connected to the plurality of pixels 541, and a vertical signal line 5433 connected to the pixel circuit 210. The pixel circuit 210 includes, for example, four transistors, or more specifically, an amplification transistor AMP, a selection transistor SEL, a reset transistor RST, and an FD conversion gain switching transistor FD. As described above, the pixel sharing unit 539 sequentially outputs the pixel signals of the four pixels 541 (pixels 541A, 541B, 541C, and 541D) included in the pixel sharing unit 539 to the vertical signal line 543 by operating one pixel circuit 210 in a time division manner. One pixel circuit 210 is connected to the plurality of pixels 541, and a mode in which the pixel signals of the plurality of pixels 541 are output by the pixel circuit 210 in a time division manner will be referred to as “the plurality of pixels 541 shares one pixel circuit 210”.

The pixels 541A, 541B, 541C, and 541D have common components. Hereinafter, in order to distinguish the components of the pixels 541A, 541B, 541C, and 541D from each other, an identification number 1 is assigned to the end of the reference sign of the component of the pixel 541A, an identification number 2 is assigned to the end of the reference sign of the component of the pixel 541B, an identification number 3 is assigned to the end of the reference sign of the component of the pixel 541C, and an identification number 4 is assigned to the end of the reference sign of the component of the pixel 541D. In a case where it is not necessary to distinguish the components of the pixels 541A, 541B, 541C, and 541D from each other, the identification numbers at the ends of the reference signs of the components of the pixels 541A, 541B, 541C, and 541D are omitted.

The pixels 541A, 541B, 541C, and 541D include, for example, the photodiode PD, the transfer transistor TR electrically connected to the photodiode PD, and the floating diffusion FD electrically connected to the transfer transistor TR. In the photodiode PD (PD1, PD2, PD3, or PD4), a cathode is electrically connected to a source of the transfer transistor TR, and an anode is electrically connected to a reference potential line (for example, ground). The photodiode PD photoelectrically converts incident light and generates a charge corresponding to the amount of received light. The transfer transistor TR (transfer transistor TR1, TR2, TR3, or TR4) is, for example, an n-type complementary metal oxide semiconductor (CMOS) transistor. In the transfer transistor TR, a drain is electrically connected to the floating diffusion FD, and a gate is electrically connected to a drive signal line. The drive signal line is part of the plurality of row drive signal lines 542 (see FIG. 27) connected to one pixel sharing unit 539. The transfer transistor TR transfers the charge generated in the photodiode PD to the floating diffusion FD. The floating diffusion FD (floating diffusion FD1, FD2, FD3, or FD4) is an n-type diffusion layer region formed in the p-type semiconductor layer. The floating diffusion FD is a charge retention means for temporarily retaining the charge transferred from the photodiode PD, and is a charge-to-voltage conversion means for generating a voltage corresponding to the amount of charge.

The four floating diffusions FD (floating diffusions FD1, FD2, FD3, and FD4) included in one pixel sharing unit 539 are electrically connected to each other, and are electrically connected to the gate of the amplification transistor AMP and the source of the FD conversion gain switching transistor FDG. A drain of the FD conversion gain switching transistor FDG is connected to a source of the reset transistor RST, and a gate of the FD conversion gain switching transistor FDG is connected to a drive signal line. This drive signal line is part of the plurality of row drive signal lines 542 connected to one pixel sharing unit 539. A drain of the reset transistor RST is connected to a power supply line VDD, and a gate of the reset transistor RST is connected to the drive signal line. This drive signal line is part of the plurality of row drive signal lines 542 connected to one pixel sharing unit 539. The gate of the amplification transistor AMP is connected to the floating diffusion FD, a drain of the amplification transistor AMP is connected to the power supply line VDD, and a source of the amplification transistor AMP is connected to a drain of the selection transistor SEL. A source of the selection transistor SEL is connected to the vertical signal line 543, and a gate of the selection transistor SEL is connected to the drive signal line. This drive signal line is part of the plurality of row drive signal lines 542 connected to one pixel sharing unit 539.

The transfer transistor TR transfers charge of the photodiode PD to the floating diffusion FD when turned on. A gate (transfer gate TG) of the transfer transistor TR includes, for example, a so-called vertical electrode, and is provided in such a way as to extend from a surface of a semiconductor layer (the semiconductor layer 100S in FIG. 32 described later) to a depth reaching the PD as illustrated in FIG. 32 described later. The reset transistor RST resets potentials of the floating diffusions FD to a predetermined potential. The reset transistor RST resets the potentials of the floating diffusions FD to a potential of the power supply line VDD when turned on. The selection transistor SEL controls output timing of a pixel signal from the pixel circuit 210. The amplification transistor AMP generates signals of voltages corresponding to levels of charge retained in the floating diffusions FD as pixel signals. The amplification transistor AMP is connected to the vertical signal line 543 via the selection transistor SEL. The amplification transistor AMP constitutes a source follower together with a load circuit section (see FIG. 27) connected to the vertical signal line 543 in the column signal processing section 550. When the selection transistor SEL is turned on, the amplification transistor AMP outputs voltages of the floating diffusions FD to the column signal processing section 550 via the vertical signal line 543. The reset transistor RST, the amplification transistor AMP, and the selection transistor SEL are, for example, n-type CMOS transistors.

The FD conversion gain switching transistor FDG is used to change gain of charge-to-voltage conversion in the floating diffusions FD. In general, a pixel signal is small at a time of capture of an image in a dark place. Since Q=CV, if capacitance (FD capacitance C) of the floating diffusion FD is high when charge-to-voltage conversion is performed, V obtained by the amplification transistor AMP as a result of the conversion into a voltage becomes low. Since a pixel signal becomes large in a bright place, on the other hand, the floating diffusion FD cannot receive charge of the photodiode PD unless the FD capacitance C is high. Moreover, the FD capacitance C needs to be high so that V obtained by the amplification transistor AMP as a result of the conversion into a voltage does not become too high (in other words, becomes low). For these reasons, when the FD conversion gain switching transistor FDG is turned on, gate capacitance of the FD conversion gain switching transistor FDG increases, and entire FD capacitance C increases. When the FD conversion gain switching transistor FDG is turned off, on the other hand, the entire FD capacitance C decreases. The FD capacitance C can thus be made variable and conversion efficiency can be switched by turning on and off the FD conversion gain switching transistor FDG. The FD conversion gain switching transistor FDG is, for example, an n-type CMOS transistor.

Note that a configuration in which the FD conversion gain switching transistor FDG is not provided is also possible. At this time, for example, the pixel circuit 210 includes three transistors, namely, for example, an amplification transistor AMP, a selection transistor SEL, and a reset transistor RST. The pixel circuit 210 includes, for example, at least one of pixel transistors such as an amplification transistor AMP, a selection transistor SEL, a reset transistor RST, or an FD conversion gain switching transistor FDG.

The selection transistor SEL may be provided between the power supply line VDD and the amplification transistor AMP. In this case, a drain of the reset transistor RST is electrically connected to the power supply line VDD and a drain of the selection transistor SEL. A source of the selection transistor SEL is electrically connected to a drain of the amplification transistor AMP, and a gate of the selection transistor SEL is electrically connected to the row drive signal line 542 (see FIG. 27). A source of the amplification transistor AMP (an output terminal of the pixel circuit 210) is electrically connected to the vertical signal line 543, and a gate of the amplification transistor AMP is electrically connected to a source of the reset transistor RST. Note that although not illustrated, the number of pixels 541 that share one pixel circuit 210 may be other than four. For example, two or eight pixels 541 may share one pixel circuit 210, instead.

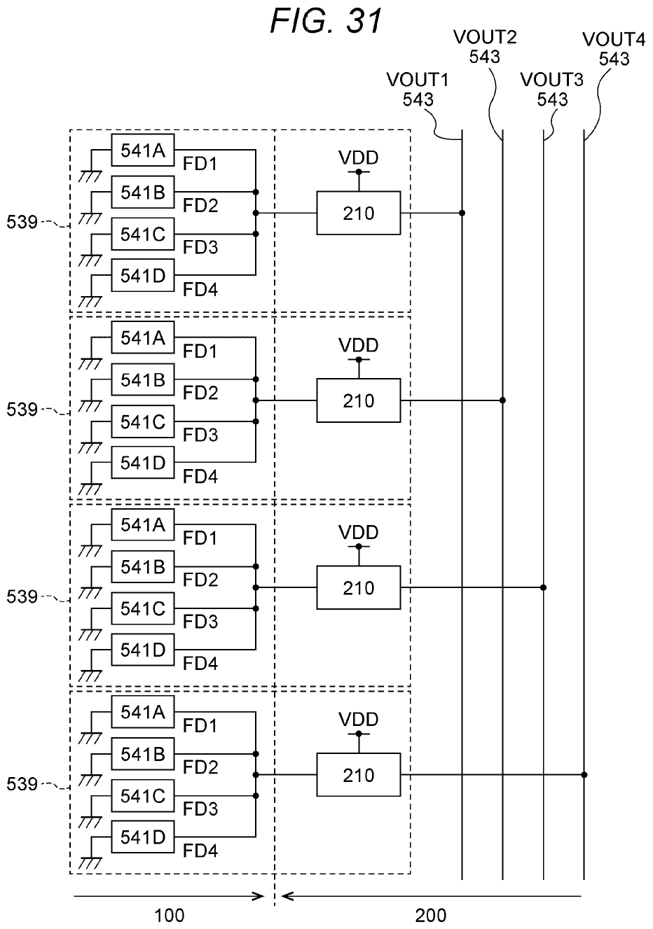

FIG. 31 illustrates an example of a connection mode between the plurality of pixel sharing units 539 and the vertical signal lines 543. For example, the four pixel sharing units 539 arranged in the column direction are divided into four groups, and a vertical signal line 543 is connected to each of the four groups. Although FIG. 31 illustrates an example in which four groups each include one pixel sharing unit 539 in order to simplify description, the four groups may each include a plurality of pixel sharing units 539. As described above, in the imaging device 1, the plurality of pixel sharing units 539 arranged in the column direction may be divided into groups including one or a plurality of pixel sharing units 539. For example, the vertical signal line 543 and the column signal processing circuit 550 are connected to each group, and pixel signals can be simultaneously read from each group. Alternatively, in the imaging device 1, one vertical signal line 543 may be connected to the plurality of pixel sharing units 539 arranged in the column direction. At this time, pixel signals are sequentially read, in a time division manner, from the plurality of pixel sharing units 539 connected to one vertical signal line 543.

### [Specific Configuration of Imaging Device 1]

FIG. 32 illustrates an example of a cross-sectional configuration in a direction perpendicular to the main surfaces of the first substrate 100, the second substrate 200, and the third substrate 300 of the imaging device 1. FIG. 32 schematically illustrates a positional relationship of the components for easy understanding, and may be different from an actual cross section. In the imaging device 1, the first substrate 100, the second substrate 200, and the third substrate 300 are laminated in this order. The imaging device 1 further includes a light receiving lens 401 on the back surface side (light incident surface side) of the first substrate 100. A color filter layer (not illustrated) may be provided between the light receiving lens 401 and the first substrate 100. The light receiving lens 401 is provided in each of the pixels 541A, 541B, 541C, and 541D, for example. The imaging device 1 is, for example, a back-illuminated imaging device. The imaging device 1 includes a pixel array section 540 arranged in a central portion and a peripheral portion 540B arranged outside the pixel array section 540.

The first substrate 100 includes an insulating film 111, a fixed charge film 112, the semiconductor layer 100S, and the wiring layer 100T in this order from the light receiving lens 401 side. The semiconductor layer 100S includes, for example, a silicon substrate. The semiconductor layer 100S includes, for example, a p-well layer 115 in a part of a front surface (a surface on a wiring layer 100T side) thereof and in the vicinity of the part and an n-type semiconductor region 114 in another region (a region deeper than the p-well layer 115). For example, the n-type semiconductor region 114 and the p-well layer 115 constitute a photodiode PD of a p-n junction type. The p-well layer 115 is a p-type semiconductor region.

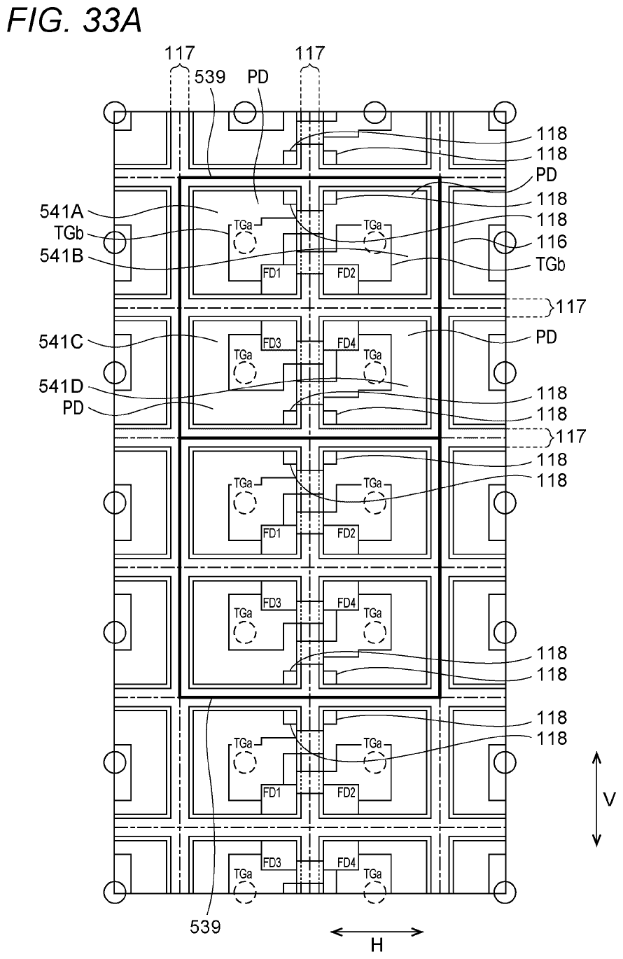

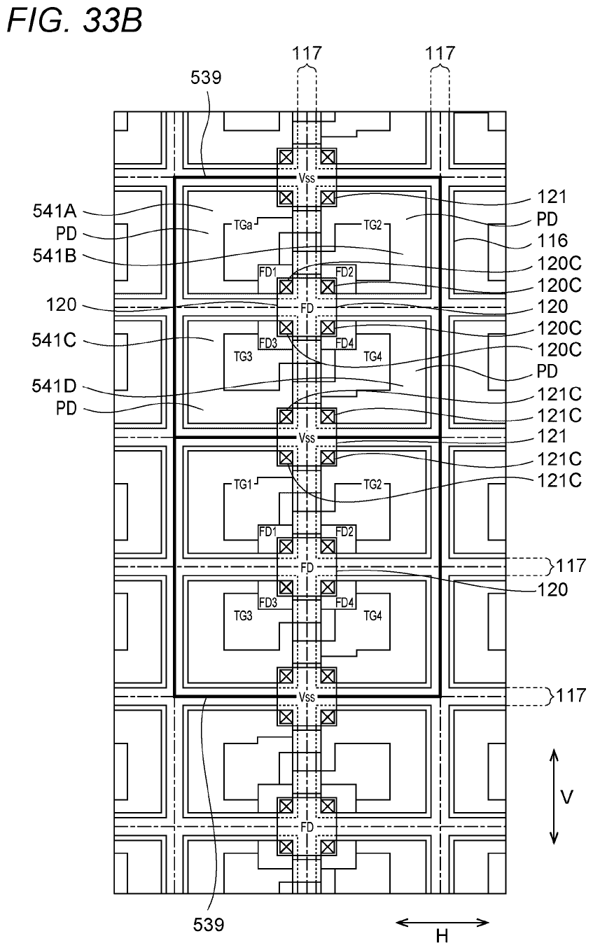

FIG. 33A illustrates an example of a planar configuration of the first substrate 100. FIG. 33A mainly illustrates a planar configuration of a pixel isolation portion 117, the photodiodes PD, floating diffusions FD, VSS contact regions 118, and transfer transistors TR of the first substrate 100. Configuration of the first substrate 100 will be described with reference to FIG. 33A together with FIG. 32.

The floating diffusions FD and the VSS contact regions 118 are provided in the vicinity of the surface of the semiconductor layer 100S. The floating diffusions FD each include an n-type semiconductor region provided in the p-well layer 115. The floating diffusions FD (the floating diffusion FD1, FD2, FD3, or FD4) of the individual pixels 541A, 541B, 541C, and 541D are provided, for example, close to each other in a central portion of the pixel sharing unit 539 (FIG. 33A). Although details will be described later, the four floating diffusions (floating diffusions FD1, FD2, FD3, and FD4) included in the sharing unit 539 are electrically connected to each other in the first substrate 100 (more specifically, in the wiring layer 100T) via electrical connection means (pad portion 120 described later). Moreover, the floating diffusion FD is connected from the first substrate 100 to the second substrate 200 (more specifically, from the wiring layer 100T to the wiring layer 200T) via electrical means (through electrode 120E described later). In the second substrate 200 (more specifically, inside the wiring layer 200T), the floating diffusions FD are electrically connected to the gate of the amplification transistor AMP and the source of the FD conversion gain switching transistor FDG by this electrical means.

The VSS contact regions 118 are regions electrically connected to the reference potential line VSS, and arranged away from the floating diffusions FD. For example, in each of the pixels 541A, 541B, 541C, and 541D, the floating diffusion FD is arranged at one end of the pixel in the V direction, and the VSS contact region 118 is arranged at another end (FIG. 33A). The VSS contact region 118 includes, for example, a p-type semiconductor region. The VSS contact region 118 is connected to, for example, a ground potential or a fixed potential. As a result, the reference potential is supplied to the semiconductor layer 100S.

The transfer transistors TR are provided in the first substrate 100 together with the photodiodes PD, the floating diffusions FD, and the VSS contact regions 118. The photodiode PD, the floating diffusion FD, the VSS contact region 118, and the transfer transistor TR are provided in each of the pixels 541A, 541B, 541C, and 541D. The transfer transistor TR is provided on the front surface side (side opposite to light incident surface side, second substrate 200 side) of the semiconductor layer 100S. The transfer transistor TR includes a transfer gate TG. The transfer gate TG includes, for example, a horizontal portion TGb facing the surface of the semiconductor layer 100S and a vertical portion TGa provided in the semiconductor layer 100S. The vertical portion TGa extends in a thickness direction of the semiconductor layer 100S. An end of the vertical portion TGa is in contact with the horizontal portion TGb, and another end is provided in the n-type semiconductor region 114. By configuring the transfer transistor TR with such a vertical transistor, transfer failure of a pixel signal hardly occurs, and readout efficiency of the pixel signal can be improved.

The horizontal portion TGb of the transfer gate TG extends from a position facing the vertical portion TGa toward, for example, the central portion of the pixel sharing unit 539 in the H direction (FIG. 33A). As a result, the position in the H direction of the through electrode (through electrode TGV to be described later) reaching the transfer gate TG can be brought close to the position in the H direction of the through electrode (through electrodes 120E and 121E to be described later) connected to the floating diffusion FD and the VSS contact region 118. For example, the plurality of pixel sharing units 539 provided in the first substrate 100 has the same configuration (FIG. 33A).

The semiconductor layer 100S is provided with the pixel isolation portion 117 that isolates the pixels 541A, 541B, 541C, and 541D from each other. The pixel isolation portion 117 is formed in such a way as to extend in a normal direction of the semiconductor layer 100S (a direction perpendicular to the surface of the semiconductor layer 100S). The pixel isolation portion 117 is provided in such a way as to partition the pixels 541A, 541B, 541C, and 541D from each other, and has, for example, a grid-like planar shape (FIG. 33A and FIG. 33B). For example, the pixel isolation portion 117 electrically and optically isolates the pixels 541A, 541B, 541C, and 541D from each other. The pixel isolation portion 117 includes, for example, a light shielding film 117A and an insulating film 117B. For example, tungsten (W) or the like is used for the light shielding film 117A. The insulating film 117B is provided between the light shielding film 117A and the p-well layer 115 or the n-type semiconductor region 114. The insulating film 117B includes, for example, silicon oxide (SiO). The pixel isolation portion 117 has, for example, a full trench isolation (FTI) structure and penetrates the semiconductor layer 100S. Although not illustrated, the pixel isolation portion 117 is not limited to the FTI structure penetrating the semiconductor layer 100S. For example, a deep trench isolation (DTI) structure that does not penetrate the semiconductor layer 100S may be employed. The pixel isolation portion 117 extends in the normal direction of the semiconductor layer 100S and is formed in a region of the semiconductor layer 100S.

In the semiconductor layer 100S, for example, a first pinning region 113 and a second pinning region 116 are provided. The first pinning region 113 is provided in the vicinity of the back surface of the semiconductor layer 100S, and is arranged between the n-type semiconductor region 114 and the fixed charge film 112. The second pinning region 116 is provided on a side surface of the pixel isolation portion 117, or more specifically, between the pixel isolation portion 117 and the p-well layer 115 or the n-type semiconductor region 114. The first pinning region 113 and the second pinning region 116 include, for example, a p-type semiconductor region.

The fixed charge film 112 having negative fixed charge is provided between the semiconductor layer 100S and the insulating film 111. The first pinning region 113 of a hole accumulation layer is formed at an interface on a light receiving surface (back surface) side of the semiconductor layer 100S by an electric field induced by the fixed charge film 112. As a result, generation of a dark current due to an interface state on the light receiving surface side of the semiconductor layer 100S is suppressed. The fixed charge film 112 includes, for example, an insulating film having negative fixed charge. Examples of a material of the insulating film having negative fixed charge include hafnium oxide, zircon oxide, aluminum oxide, titanium oxide, and tantalum oxide.

The light shielding film 117A is provided between the fixed charge film 112 and the insulating film 111. The light shielding film 117A may be provided continuously with the light shielding film 117A constituting the pixel isolation portion 117. The light shielding film 117A between the fixed charge film 112 and the insulating film 111 is selectively provided, for example, in the semiconductor layer 100S at a position facing the pixel isolation portion 117. The insulating film 111 is provided in such a way as to cover the light shielding film 117A. The insulating film 111 includes, for example, silicon oxide.

The wiring layer 100T provided between the semiconductor layer 100S and the second substrate 200 includes an interlayer insulating film 119, pad portions 120 and 121, a passivation film 122, an interlayer insulating film 123, and a bonding film 124 in this order from the semiconductor layer 100S side. The horizontal portion TGb of the transfer gate TG is provided in the wiring layer 100T, for example. The interlayer insulating film 119 is provided over the entire surface of the semiconductor layer 100S and in contact with the semiconductor layer 100S. The interlayer insulating film 119 includes, for example, a silicon oxide film. Note that configuration of the wiring layer 100T is not limited to the above, and may be a configuration including wiring and an insulating film.

FIG. 33B illustrates configuration of the pad portions 120 and 121 together with the planar configuration illustrated in FIG. 33A. The pad portions 120 and 121 are provided in a selective region on the interlayer insulating film 119. The pad portion 120 is for connecting the floating diffusions FD (floating diffusions FD1, FD2, FD3, and FD4) of the pixels 541A, 541B, 541C, and 541D to each other. For example, the pad portion 120 is arranged for each of the pixel sharing units 539 at the central portion of the pixel sharing unit 539 in plan view (FIG. 33B). The pad portion 120 is provided across the pixel isolation portion 117, and is arranged in such a way as to overlap at least a part of each of the floating diffusions FD1, FD2, FD3, and FD4 (FIG. 32 and FIG. 33B). Specifically, the pad portion 120 is formed in a region overlapping at least a part of each of the plurality of floating diffusions FD (floating diffusions FD1, FD2, FD3, and FD4) sharing the pixel circuit 210 and at least a part of the pixel isolation portion 117 formed between the plurality of photodiodes PD (photodiodes PD1, PD2, PD3, and PD4) sharing the pixel circuit 210 in a direction perpendicular to the surface of the semiconductor layer 100S. The interlayer insulating film 119 is provided with a connection via 120C for electrically connecting the pad portion 120 and the floating diffusions FD1, FD2, FD3, and FD4. The connection via 120C is provided in each of the pixels 541A, 541B, 541C, and 541D. For example, by embedding a part of the pad portion 120 in the connection via 120C, the pad portion 120 and the floating diffusions FD1, FD2, FD3, and FD4 are electrically connected.

The pad portion 121 is used to connect the plurality of VSS contact regions 118 to each other. For example, the VSS contact region 118 provided in the pixels 541C and 541D of one pixel sharing unit 539 adjacent in the V direction and the VSS contact region 118 provided in the pixels 541A and 541B of the other pixel sharing unit 539 are electrically connected by the pad portion 121. The pad portion 121 is provided across the pixel isolation portion 117, for example, and is arranged to overlap at least a part of each of the four VSS contact regions 118. Specifically, the pad portion 121 is formed in a region overlapping at least a part of each of the plurality of VSS contact regions 118 and at least a part of the pixel isolation portion 117 formed between the plurality of VSS contacts 118 in a direction perpendicular to the surface of the semiconductor layer 100S. The interlayer insulating film 119 is provided with a connection via 121C for electrically connecting the pad portion 121 and the VSS contact region 118. The connection via 121C is provided in each of the pixels 541A, 541B, 541C, and 541D. For example, by embedding a part of the pad portion 121 in the connection via 121C, the pad portion 121 and the VSS contact region 118 are electrically connected to each other. For example, the pad portion 120 and the pad portion 121 of each of the plurality of pixel sharing units 539 arranged in the V direction are arranged at substantially the same position in the H direction (FIG. 33B).

By providing the pad portion 120, it is possible to reduce the number of wires for connecting each floating diffusion FD to the pixel circuit 210 (for example, the gate electrode of the amplification transistor AMP) in the entire chip. Similarly, by providing the pad portion 121, the number of wires for supplying a potential to each VSS contact region 118 can be reduced in the entire chip. As a result, it is possible to reduce the area of the entire chip, suppress electrical interference between the wires in the miniaturized pixels, and/or reduce a cost by reducing the number of components.

The pad portions 120 and 121 can be provided in the first substrate 100 and the second substrate 200 at desired positions. Specifically, the pad portions 120 and 121 can be provided in either the wiring layer 100T or an insulating region 212 of the semiconductor layer 200S. In a case where the pad portions 120 and 121 are provided in the wiring layer 100T, the pad portions 120 and 121 may be brought into direct contact with the semiconductor layer 100S. Specifically, the pad portions 120 and 121 may be directly connected to at least a part of each of the floating diffusion FD and/or the VSS contact region 118. In addition, connection vias 120C and 121C may be provided from the floating diffusion FD and/or the VSS contact region 118 connected to the pad portions 120 and 121, respectively, and the pad portions 120 and 121 may be provided at desired positions of an insulating region 2112 of the wiring layer 100T and the semiconductor layer 200S.

In particular, in a case where the pad portions 120 and 121 are provided in the wiring layer 100T, it is possible to reduce the number of wires connected to the floating diffusion FD and/or the VSS contact region 118 in the insulating region 212 of the semiconductor layer 200S. As a result, in the second substrate 200 forming the pixel circuit 210, the area of the insulating region 212 for forming the through wiring for connecting the floating diffusion FD to the pixel circuit 210 can be reduced. Therefore, it is possible to secure a large area of the second substrate 200 forming the pixel circuit 210. By securing the area of the pixel circuit 210, it is possible to form a large pixel transistor and contribute to image quality improvement through noise reduction or the like.

In particular, since it is preferable to provide the floating diffusion FD and/or the VSS contact region 118 in each pixel 541 in a case where the FTI structure is used for the pixel isolation portion 117, the number of wires connecting the first substrate 100 and the second substrate 200 to each other can be greatly reduced by using the configuration of the pad portions 120 and 121.

Furthermore, as illustrated in FIG. 33B, for example, the pad portion 120 to which the plurality of floating diffusions FD is connected and the pad portion 121 to which the plurality of VSS contacts 118 is connected are alternately arranged linearly in the V direction. In addition, the pad portions 120 and 121 are formed at positions surrounded by the plurality of photodiodes PD, the plurality of transfer gates TG, and the plurality of floating diffusions FD. As a result, elements other than the floating diffusion FD and the VSS contact region 118 can be freely arranged in the first substrate 100 forming a plurality of elements, and efficiency of the layout of the entire chip can be improved. Furthermore, symmetry in the layout of the elements formed in each pixel sharing unit 539 can be secured, and variation in characteristics of each pixel 541 can be suppressed.

The pad portions 120 and 121 are constituted by, for example, polysilicon (Poly Si), more specifically, doped polysilicon doped with impurities. The pad portions 120 and 121 are preferably constituted by a conductive material having high heat resistance such as polysilicon, tungsten (W), titanium (Ti), or titanium nitride (TiN). As a result, the pixel circuit 210 can be formed after the semiconductor layer 200S of the second substrate 200 is bonded to the first substrate 100. A reason for this will be described hereinafter. Note that, in the following description, a method for forming the pixel circuit 210 after bonding the first substrate 100 and the semiconductor layer 200S of the second substrate 200 to each other will be referred to as a first manufacturing method.

Here, it is also conceivable to bond, after forming the pixel circuit 210 on the second substrate 200, the second substrate 200 to the first substrate 100 (hereinafter referred to as a second manufacturing method). In the second manufacturing method, an electrode for electrical connection is formed in advance on each of the surface of the first substrate 100 (the surface of the wiring layer 100T) and the surface of the second substrate 200 (the surface of the wiring layer 200T). When the first substrate 100 and the second substrate 200 are bonded to each other, the electrodes for electrical connection formed on the surface of the first substrate 100 and the surface of the second substrate 200 come into contact with each other. As a result, an electrical connection is formed between the wiring included in the first substrate 100 and the wiring included in the second substrate 200. Therefore, by employing the configuration of the imaging device 1 using the second manufacturing method, for example, manufacturing can be performed using an appropriate process according to the configuration of each of the first substrate 100 and the second substrate 200, and a high-quality and high-performance imaging apparatus can be manufactured.

In such a second manufacturing method, when the first substrate 100 and the second substrate 200 are bonded to each other, an error in alignment might occur due to a manufacturing apparatus for bonding. In addition, the first substrate 100 and the second substrate 200 have a size of, for example, about several tens of centimeters in diameter, but when the first substrate 100 and the second substrate 200 are bonded to each other, there is a possibility that expansion and contraction of the substrates occur in microscopic regions of the respective parts of the first substrate 100 and the second substrate 200. This expansion and contraction of the substrates is caused by a slight shift in the timing of contact between the substrates. Due to such expansion and contraction of the first substrate 100 and the second substrate 200, an error may occur in the positions of the electrodes for electrical connection formed on the surface of the first substrate 100 and the surface of the second substrate 200. In the second manufacturing method, even if such an error occurs, it is preferable to take measures so that the electrodes of the first substrate 100 and the second substrate 200 come into contact with each other. Specifically, at least one, preferably both, of the electrodes of the first substrate 100 or the second substrate 200 is increased in consideration of the above error. Therefore, when the second manufacturing method is used, for example, the size of the electrode formed on the surface of the first substrate 100 or the second substrate 200 (the size in the substrate planar direction) is larger than the size of the internal electrode extending from the inside of the first substrate 100 or the second substrate 200 to the surface in the thickness direction.

On the other hand, the pad portions 120 and 121 are constituted by a heat-resistant conductive material, so that the above-described first manufacturing method can be used. In the first manufacturing method, after the first substrate 100 including the photodiode PD, the transfer transistor TR, and the like is formed, the first substrate 100 and the second substrate 200 (semiconductor layer 2000S) are bonded to each other. At this time, the second substrate 200 is in a state in which patterns such as active elements and wiring layers constituting the pixel circuit 210 are not formed. Since the second substrate 200 is in a state before the pattern is formed, even if an error occurs in the bonding position when the first substrate 100 and the second substrate 200 are bonded, an error does not occur in alignment between the pattern of the first substrate 100 and the pattern of the second substrate 200 due to the bonding error. This is because the pattern of the second substrate 200 is formed after the first substrate 100 and the second substrate 200 are bonded. Note that, when a pattern is formed on the second substrate, for example, in an exposure apparatus for pattern formation, the pattern is formed while the pattern formed on the first substrate is set as an alignment target. For the above reason, the error in the bonding position between the first substrate 100 and the second substrate 200 does not cause a problem in manufacturing the imaging device 1 in the first manufacturing method. For a similar reason, an error caused by expansion and contraction of the substrate caused by the second manufacturing method does not cause a problem in manufacturing the imaging device 1 in the first manufacturing method.

In the first manufacturing method, after the first substrate 100 and the second substrate 200 (semiconductor layer 200S) are bonded in this manner, an active element is formed on the second substrate 200. Thereafter, the through electrodes 120E and 121E and the through electrode TGV (FIG. 32) are formed. In the formation of the through electrodes 120E, 121E, and TGV, for example, a pattern of the through electrode is formed from above the second substrate 200 using reduced projection exposure by an exposure apparatus. Since the reduced exposure projection is used, even if an error occurs in the alignment between the second substrate 200 and the exposure apparatus, the magnitude of the error is only a fraction (inverse of the reduced exposure projection magnification) of the magnitude of the error of the above-described second manufacturing method in the second substrate 200. Therefore, by employing the configuration of the imaging device 1 using the first manufacturing method, it is easy to align the elements formed on each of the first substrate 100 and the second substrate 200, and it is possible to manufacture a high-quality and high-performance imaging apparatus.

The imaging device 1 manufactured using such a first manufacturing method has features different from those of the imaging apparatus manufactured by the second manufacturing method. Specifically, in the imaging device 1 manufactured by the first manufacturing method, for example, the through electrodes 120E, 121E, and TGV have substantially constant thicknesses (sizes in the substrate planar direction) from the second substrate 200 to the first substrate 100. Alternatively, when the through electrodes 120E, 121E, and TGV have a tapered shape, they have a tapered shape with a constant inclination. In the imaging device 1 including such through electrodes 120E, 121E, and TGV, the pixel 541 is easily miniaturized.

Here, when the imaging device 1 is manufactured by the first manufacturing method, since the active element is formed on the second substrate 200 after the first substrate 100 and the second substrate 200 (semiconductor layer 200S) are bonded together, the first substrate 100 is also affected by the heating treatment necessary for forming the active element. Therefore, as described above, it is preferable to use a conductive material having high heat resistance for the pad portions 120 and 121 provided on the first substrate 100. For example, the pad portions 120 and 121 are preferably constituted by a material having a higher melting point (that is, higher heat resistance) than at least a part of the wiring material included in the wiring layer 200T of the second substrate 200. For example, a conductive material having high heat resistance such as doped polysilicon, tungsten, titanium, or titanium nitride is used for the pad portions 120 and 121. As a result, the imaging device 1 can be manufactured using the above-described first manufacturing method.

The passivation film 122 is provided over the entire surface of the semiconductor layer 100S, for example, in such a way as to cover the pad portions 120 and 121 (FIG. 32). The passivation film 122 includes, for example, a silicon nitride (SiN) film. The interlayer insulating film 123 covers the pad portions 120 and 121 with the passivation film 122 interposed therebetween. The interlayer insulating film 123 is provided over the entire surface of the semiconductor layer 100S, for example. The interlayer insulating film 123 includes, for example, a silicon oxide (SiO) film. The bonding film 124 is provided on a bonding surface between the first substrate 100 (specifically, the wiring layer 100T) and the second substrate 200. That is, the bonding film 124 is in contact with the second substrate 200. The bonding film 124 is provided over the entire main surface of the first substrate 100. The bonding film 124 includes, for example, a silicon nitride film.

The light receiving lens 401 faces, for example, the semiconductor layer 100S with the fixed charge film 112 and the insulating film 111 interposed therebetween, for example (FIG. 32). The light receiving lens 401 is provided, for example, at a position facing the photodiode PD of each of the pixels 541A, 541B, 541C, and 541D.

The second substrate 200 includes the semiconductor layer 200S and the wiring layer 200T in this order from the first substrate 100 side. The semiconductor layer 200S includes a silicon substrate. In the semiconductor layer 200S, a well region 211 is provided over the thickness direction. The well region 211 is, for example, a p-type semiconductor region. The second substrate 200 is provided with a pixel circuit 210 arranged for each pixel sharing unit 539. The pixel circuit 210 is provided, for example, on the front surface side (wiring layer 200T side) of the semiconductor layer 200S. In the imaging device 1, the second substrate 200 is bonded to the first substrate 100 such that the back surface side (semiconductor layer 200S side) of the second substrate 200 faces the front surface side (wiring layer 100T side) of the first substrate 100. That is, the second substrate 200 is bonded to the first substrate 100 in a face-to-back manner.

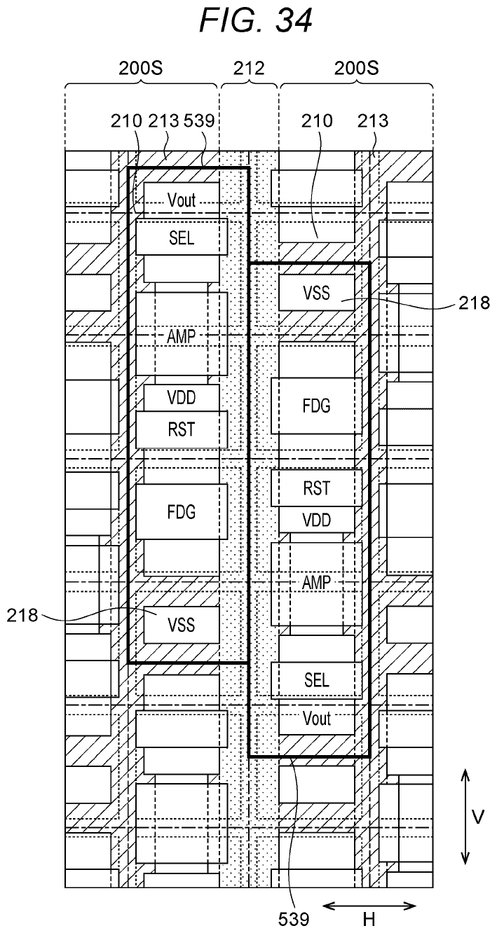

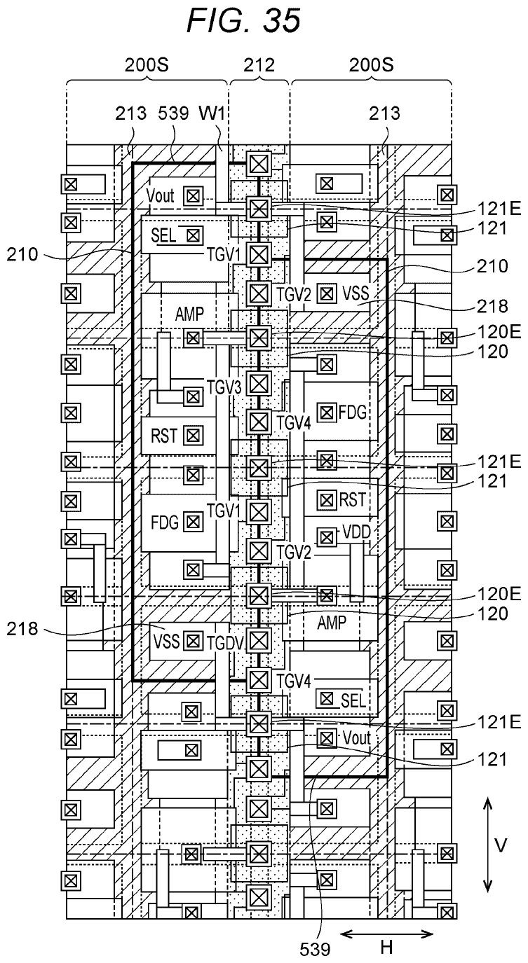

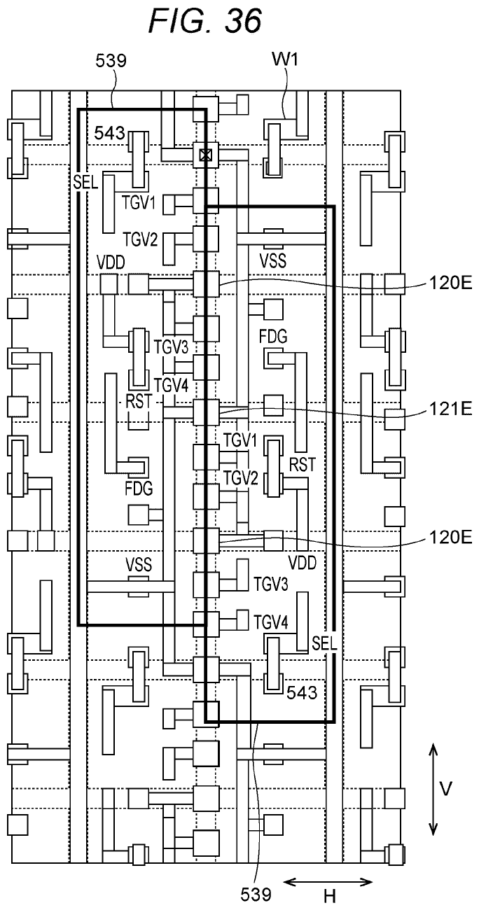

FIGS. 34 to 38 schematically illustrate an example of a planar configuration of the second substrate 200. FIG. 34 illustrates a configuration of the pixel circuit 210 provided in the vicinity of the surface of the semiconductor layer 200S. FIG. 35 schematically illustrates a configuration of each part of the wiring layer 200T (specifically, a first wiring layer W1 described later), the semiconductor layer 200S connected to the wiring layer 200T, and the first substrate 100. FIGS. 36 to 38 illustrate an example of a planar configuration of the wiring layer 200T. The configuration of the second substrate 200 will be described hereinafter with reference to FIGS. 34 to 38 together with FIG. 32. In FIGS. 34 and 35, the outer shape of the photodiode PD (the boundary between the pixel isolation portion 117 and the photodiode PD) is indicated by a broken line, and the boundary between the semiconductor layer 200S and an element isolation region 213 or an insulating region 214 in a portion overlapping the gate electrode of each transistor constituting the pixel circuit 210 is indicated by a dotted line. In a portion overlapping the gate electrode of the amplification transistor AMP, a boundary between the semiconductor layer 200S and the element isolation region 213 and a boundary between the element isolation region 213 and the insulating region 213 are provided on one side in the channel width direction.

The second substrate 200 is provided with the insulating region 212 that divides the semiconductor layer 200S and the element isolation region 213 provided in a part of the semiconductor layer 200S in the thickness direction (FIG. 32). For example, the through electrodes 120E and 121E and the through electrodes TGV (through electrodes TGV1, TGV2, TGV3, and TGV4) of the two pixel sharing units 539 connected to the two pixel circuits 210 are arranged in the insulating region 212 provided between the two pixel circuits 210 adjacent in the H direction (FIG. 35).

The insulating region 212 has substantially the same thickness as the thickness of the semiconductor layer 200S (FIG. 32). The semiconductor layer 200S is divided by the insulating region 212. The through electrodes 120E and 121E and the through electrode TGV are arranged in the insulating region 212. The insulating region 212 includes, for example, silicon oxide.

The through electrodes 120E and 121E are provided to penetrate the insulating region 212 in the thickness direction. The upper ends of the through electrodes 120E and 121E are connected to wiring (first wiring W1, second wiring W2, third wiring W3, and fourth wiring W4 to be described later) of the wiring layer 200T. The through electrodes 120E and 121E are provided to penetrate the insulating region 212, the bonding film 124, the interlayer insulating film 123, and the passivation film 122, and the lower end thereof is connected to the pad portions 120 and 121 (FIG. 32). The through electrode 120E is for electrically connecting the pad portion 120 and the pixel circuit 210. That is, the floating diffusion FD of the first substrate 100 is electrically connected to the pixel circuit 210 of the second substrate 200 by the through electrode 120E. The through electrode 121E is for electrically connecting the pad portion 121 and the reference potential line VSS of the wiring layer 200T. That is, the VSS contact region 118 of the first substrate 100 is electrically connected to the reference potential line VSS of the second substrate 200 by the through electrode 121E.

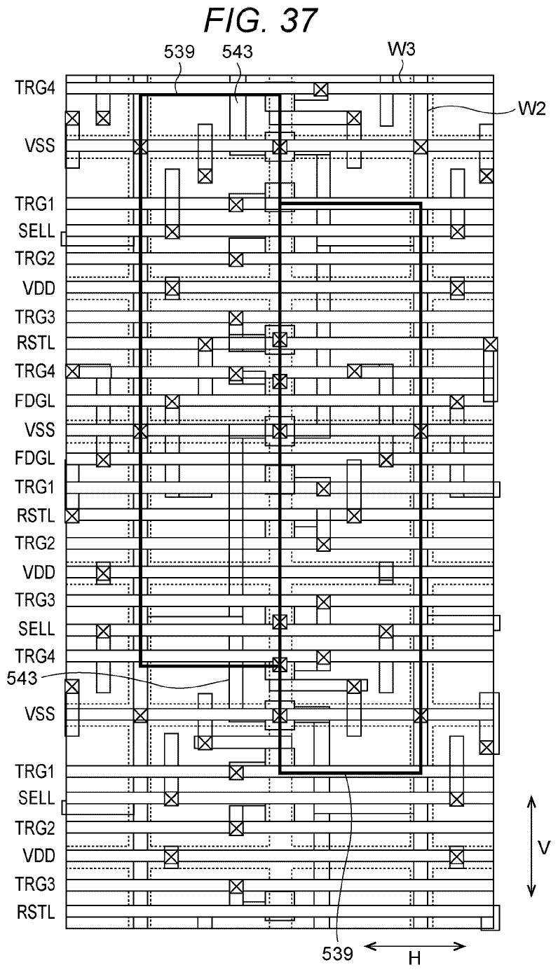

The through electrode TGV is provided to penetrate the insulating region 212 in the thickness direction. The upper end of the through electrode TGV is connected to the wiring of the wiring 200T. The through electrode TGV is provided to penetrate the insulating region 212, the bonding film 124, the interlayer insulating film 123, the passivation film 122, and the interlayer insulating film 119, and the lower end thereof is connected to the transfer gate TG (FIG. 32). Such a through electrode TGV is for electrically connecting the transfer gate TG (transfer gates TG1, TG2, TG3, and TG4) of each of the pixels 541A, 541B, 541C, and 541D to the wiring (a part of the row drive signal line 542, specifically, wiring lines TRG1, TRG2, TRG3, and TRG4 in FIG. 37 described later) of the wiring layer 200T. That is, the transfer gate TG of the first substrate 100 is electrically connected to the wiring TRG of the second substrate 200 by the through electrode TGV, and a drive signal is sent to each of the transfer transistors TR (transfer transistors TR1, TR2, TR3, and TR4).

The insulating region 212 is a region for insulating the through electrodes 120E and 121E and the through electrode TGV for electrically connecting the first substrate 100 and the second substrate 200 from the semiconductor layer 200S. For example, the through electrodes 120E and 121E and the through electrode TGV (through electrodes TGV1, TGV2, TGV3, and TGV4) connected to the two pixel circuits 210 are arranged in the insulating region 212 provided between the two pixel circuits 210 (sharing unit 539) adjacent in the H direction. The insulating region 212 is provided, for example, to extend in the V direction (FIG. 34 and FIG. 35). Here, by devising the arrangement of the horizontal portion TGb of the transfer gate TG, the through electrode TGV is arranged such that the position of the through electrode TGV in the H direction approaches the positions of the through electrodes 120E and 121E in the H direction as compared with the position of the vertical portion TGa (FIG. 33A, FIG. 35). For example, the through electrode TGV is arranged at substantially the same position as the through electrodes 120E and 120E in the H direction. As a result, the through electrodes 120E and 121E and the through electrode TGV can be collectively provided in the insulating region 212 extending in the V direction. As another arrangement example, it is also conceivable to provide the horizontal portion TGb only in a region overlapping the vertical portion TGa. In this case, the through electrode TGV is formed substantially immediately above the vertical portion TGa, and for example, the through electrode TGV is arranged substantially at the central portion in the H direction and the V direction of each pixel 541. At this time, the position of the through electrode TGV in the H direction greatly deviates from the positions of the through electrodes 120E and 121E in the H direction. For example, the insulating region 212 is provided around the through electrode TGV and the through electrodes 120E and 121E in order to electrically insulate them from the adjacent semiconductor layer 200S. In a case where the position of the through electrode TGV in the H direction and the positions of the through electrodes 120E and 121E in the H direction are greatly separated from each other, it is necessary to provide the insulating region 212 independently around each of the through electrodes 120E, 121E, and TGV. As a result, the semiconductor layer 200S is finely divided. In comparison, the layout in which the through electrodes 120E and 121E and the through electrode TGV are collectively arranged in the insulating region 212 extending in the V direction can increase the size of the semiconductor layer 200S in the H direction. Therefore, a large area of the semiconductor element formation region in the semiconductor layer 200S can be secured. As a result, for example, the size of the amplification transistor AMP can be increased, and noise can be suppressed.

As described with reference to FIG. 30, the pixel sharing unit 539 has a structure in which the floating diffusion FD provided in each of the plurality of pixels 541 is electrically connected, and the plurality of pixels 541 shares one pixel circuit 210. Then, the floating diffusion FD is electrically connected to each other by the pad portion 120 provided on the first substrate 100 (FIG. 32 and FIG. 33B). The electrical connection portion (pad portion 120) provided on the first substrate 100 and the pixel circuit 210 provided on the second substrate 200 are electrically connected via one through electrode 120E. As another structural example, it is also conceivable to provide an electrical connection portion between the floating diffusions FD on the second substrate 200. In this case, the pixel sharing unit 539 is provided with four through electrodes connected to the floating diffusions FD1, FD2, FD3, and FD4, respectively. Therefore, in the second substrate 200, the number of through electrodes penetrating the semiconductor layer 200S increases, and the insulating region 212 that insulates the periphery of these through electrodes increases. In comparison, in the structure in which the pad portion 120 is provided on the first substrate 100 (FIG. 32 and FIG. 33B), the number of through electrodes can be reduced, and the insulating region 212 can be reduced. Therefore, a large area of the semiconductor element formation region in the semiconductor layer 200S can be secured. As a result, for example, the size of the amplification transistor AMP can be increased, and noise can be suppressed.

The element isolation region 213 is provided on the front surface side of the semiconductor layer 200S. The element isolation region 213 has a shallow trench isolation (STI) structure. In the element isolation region 213, the semiconductor layer 200S is dug in the thickness direction (the direction perpendicular to the main surface of the second substrate 200), and an insulating film is embedded in the dug. This insulating film includes, for example, silicon oxide. The element isolation region 213 isolates the plurality of transistors constituting the pixel circuit 210 from each other in accordance with the layout of the pixel circuit 210. The semiconductor layer 200S (specifically, well region 211) extends below the element isolation region 213 (deep portion of the semiconductor layer 200S).

Here, a difference between the outer shape (outer shape in the substrate planar direction) of the pixel sharing unit 539 on the first substrate 100 and the outer shape of the pixel sharing unit 539 on the second substrate 200 will be described with reference to FIGS. 33A, 33B, and 34.

In the imaging device 1, the pixel sharing unit 539 is provided over both the first substrate 100 and the second substrate 200. For example, the outer shape of the pixel sharing unit 539 provided on the first substrate 100 is different from the outer shape of the pixel sharing unit 539 provided on the second substrate 200.

In FIGS. 33A and 33B, the outline of the pixels 541A, 541B, 541C, and 541D is indicated by a one-dot chain line, and the outer shape of the pixel sharing unit 539 is indicated by a thick line. For example, the pixel sharing unit 539 of the first substrate 100 includes two pixels 541 (pixels 541A and 541B) arranged adjacent to each other in the H direction and two pixels 541 (pixels 541C and 541D) arranged adjacent to each other in the V direction. That is, the pixel sharing unit 539 of the first substrate 100 includes four pixels 541 in adjacent two rows x two columns, and the pixel sharing unit 539 of the first substrate 100 has a substantially square outer shape. In the pixel array section 540, such pixel sharing units 539 are arranged adjacent to each other at a two-pixel pitch (a pitch corresponding to two pixels 541) in the H direction and a two-pixel pitch (a pitch corresponding to two pixels 541) in the V direction.

In FIGS. 34 and 35, the outline of the pixels 541A, 541B, 541C, and 541D is indicated by a one-dot chain line, and the outer shape of the pixel sharing unit 539 is indicated by a thick line. For example, the outer shape of the pixel sharing unit 539 of the second substrate 200 is smaller than the pixel sharing unit 539 of the first substrate 100 in the H direction and larger than the pixel sharing unit 539 of the first substrate 100 in the V direction. For example, the pixel sharing unit 539 of the second substrate 200 is formed in a size (region) corresponding to one pixel in the H direction, and is formed in a size corresponding to four pixels in the V direction. That is, the pixel sharing unit 539 of the second substrate 200 is formed in a size corresponding to the pixels arranged in adjacent one row x four columns, and the pixel sharing unit 539 of the second substrate 200 has a substantially rectangular outer shape.

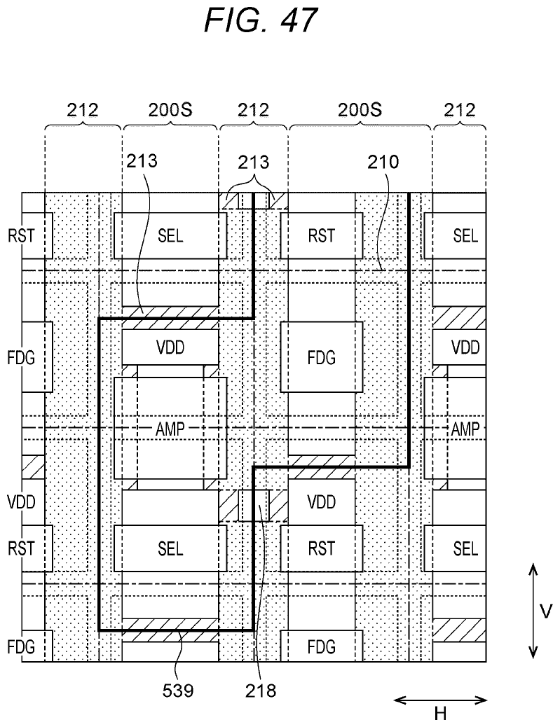

For example, in each pixel circuit 210, the selection transistor SEL, the amplification transistor AMP, the reset transistor RST, and the FD conversion gain switching transistor FDG are arranged in this order in the V direction (FIG. 34). By providing the outer shape of each pixel circuit 210 in a substantially rectangular shape as described above, four transistors (selection transistor SEL, amplification transistor AMP, reset transistor RST, and FD conversion gain switching transistor FDG) can be arranged side by side in one direction (V direction in FIG. 34). As a result, the drain of the amplification transistor AMP and the drain of the reset transistor RST can be shared by one diffusion region (diffusion region connected to the power supply line VDD). For example, the formation region of each pixel circuit 210 can be provided in a substantially square shape (see FIG. 47 described later). In this case, two transistors are arranged along one direction, and it is difficult to share the drain of the amplification transistor AMP and the drain of the reset transistor RST in one diffusion region. Therefore, by providing the formation region of the pixel circuit 210 in a substantially rectangular shape, the four transistors can be easily arranged close to each other, and the formation region of the pixel circuit 210 can be reduced. That is, the pixels can be miniaturized. Furthermore, when it is unnecessary to reduce the formation region of the pixel circuit 210, the formation region of the amplification transistor AMP can be increased to suppress noise.

For example, in the vicinity of the surface of the semiconductor layer 200S, a VSS contact region 218 connected to the reference potential line VSS is provided in addition to the selection transistor SEL, the amplification transistor AMP, the reset transistor RST, and the FD conversion gain switching transistor FDG. The VSS contact region 218 includes, for example, a p-type semiconductor region. The VSS contact region 218 is electrically connected to the VSS contact region 118 of the first substrate 100 (semiconductor layer 100S) via the wiring of the wiring layer 200T and the through electrode 121E. The VSS contact region 218 is provided, for example, at a position adjacent to the source of the FD conversion gain switching transistor FDG with the element isolation region 213 interposed therebetween (FIG. 34).

Next, a positional relationship between the pixel sharing unit 539 provided on the first substrate 100 and the pixel sharing unit 539 provided on the second substrate 200 will be described with reference to FIGS. 33B and 34. For example, one (for example, the upper side on the paper surface of FIG. 33B) pixel sharing unit 539 of the two pixel sharing units 539 arranged in the V direction on the first substrate 100 is connected to one (for example, the left side on the paper surface of FIG. 34) pixel sharing unit 539 of the two pixel sharing units 539 arranged in the H direction on the second substrate 200. For example, the other (for example, the lower side on the paper surface of FIG. 33B) pixel sharing unit 539 of the two pixel sharing units 539 arranged in the V direction on the first substrate 100 is connected to the other (for example, the right side on the paper surface of FIG. 34) pixel sharing unit 539 of the two pixel sharing units 539 arranged in the H direction on the second substrate 200.

For example, in the two pixel sharing units 539 arranged in the H direction of the second substrate 200, the internal layout (arrangement of transistors and the like) of one pixel sharing unit 539 is substantially equal to the layout obtained by inverting the internal layout of the other pixel sharing unit 539 in the V direction and the H direction. Hereinafter, effects obtained by this layout will be described.

In the two pixel sharing units 539 arranged in the V direction of the first substrate 100, each pad portion 120 is arranged at the central portion of the outer shape of the pixel sharing unit 539, that is, at the central portions in the V direction and the H direction of the pixel sharing unit 539 (FIG. 33B). On the other hand, since the pixel sharing unit 539 of the second substrate 200 has a substantially rectangular outer shape long in the V direction as described above, for example, the amplification transistor AMP connected to the pad portion 120 is arranged at a position shifted upward on the paper surface from the center of the pixel sharing unit 539 in the V direction. For example, when the internal layouts of the two pixel sharing units 539 arranged in the H direction of the second substrate 200 are the same, the distance between the amplification transistor AMP of one pixel sharing unit 539 and the pad portion 120 (for example, the pad portion 120 of the pixel sharing unit 539 on the upper side on the paper surface of FIG. 33) becomes relatively short. However, the distance between the amplification transistor AMP of the other pixel sharing unit 539 and the pad portion 120 (for example, the pad portion 120 of the pixel sharing unit 539 on the lower side on the paper surface of FIG. 33) becomes long. For this reason, the area of the wiring required for connecting the amplification transistor AMP and the pad portion 120 increases, and the wiring layout of the pixel sharing unit 539 may become complicated. This may affect miniaturization of the imaging device 1.

On the other hand, by inverting the internal layout of the two pixel sharing units 539 arranged in the H direction of the second substrate 200 at least in the V direction, the distance between the amplification transistor AMP and the pad portion 120 of both of the two pixel sharing units 539 can be shortened. Therefore, it is easy to miniaturize the imaging device 1 as compared with a configuration in which the internal layouts of the two pixel sharing units 539 arranged in the H direction of the second substrate 200 are the same. Note that the planar layout of each of the plurality of pixel sharing units 539 of the second substrate 200 is bilaterally symmetrical in the range illustrated in FIG. 34, but is bilaterally asymmetrical when including the layout of the first wiring layer W1 described later in FIG. 35.

Furthermore, it is preferable that the internal layouts of the two pixel sharing units 539 arranged in the H direction of the second substrate 200 are also inverted in the H direction. A reason for this will be described hereinafter. As illustrated in FIG. 35, each of the two pixel sharing units 539 arranged in the H direction on the second substrate 200 is connected to the pad portions 120 and 121 of the first substrate 100. For example, the pad portions 120 and 121 are arranged at the central portion in the H direction (between the two pixel sharing units 539 arranged in the H direction) of the two pixel sharing units 539 arranged in the H direction on the second substrate 200. Therefore, it is possible to reduce the distance between each of the plurality of pixel sharing units 539 of the second substrate 200 and the pad portions 120 and 121 by inverting the internal layouts of the two pixel sharing units 539 arranged in the H direction of the second substrate 200 in the H direction. That is, it is easier to miniaturize the imaging device 1.

Furthermore, the position of the outline of the pixel sharing unit 539 of the second substrate 200 may not be aligned with the position of any outline of the pixel sharing unit 539 of the first substrate 100. For example, in one (for example, the left side of the paper surface of FIG. 35) pixel sharing unit 539 of the two pixel sharing units 539 arranged in the H direction on the second substrate 200, the outline of one (for example, the upper side on the paper surface of FIG. 35) in the V direction is arranged outside the outline of one in the V direction of the pixel sharing unit 539 (for example, the upper side on the paper surface of FIG. 33B) of the corresponding first substrate 100. Furthermore, in the other (for example, the right side on the paper surface of FIG. 35) pixel sharing unit 539 of the two pixel sharing units 539 arranged in the H direction on the second substrate 200, the outline of the other (for example, the lower side on the paper surface of FIG. 35) in the V direction is arranged outside the outline of the other in the V direction of the pixel sharing unit 539 (for example, the lower side on the paper surface of FIG. 33B) of the corresponding first substrate 100. As described above, by arranging the pixel sharing unit 539 of the second substrate 200 and the pixel sharing unit 539 of the first substrate 100 to each other, the distance between the amplification transistor AMP and the pad portion 120 can be shortened. Therefore, it is easy to miniaturize the imaging device 1.

Furthermore, the positions of the outlines of the plurality of pixel sharing units 539 of the second substrate 200 may not be aligned. For example, the two pixel sharing units 539 arranged in the H direction of the second substrate 200 are arranged such that the positions of the outlines in the V direction are shifted. As a result, the distance between the amplification transistor AMP and the pad portion 120 can be shortened. Therefore, it is easy to miniaturize the imaging device 1.

The repetitive arrangement of the pixel sharing units 539 in the pixel array section 540 will be described with reference to FIGS. 33B and 35. The pixel sharing unit 539 of the first substrate 100 has the sizes of two pixels 541 in the H direction and the sizes of two pixels 541 in the V direction (FIG. 33B). For example, in the pixel array section 540 of the first substrate 100, the pixel sharing units 539 having sizes corresponding to the four pixels 541 are repeatedly arranged adjacent to each other at a pitch of two pixels in the H direction (a pitch corresponding to two pixels 541) and at a pitch of two pixels in the V direction (a pitch corresponding to two pixels 541). Alternatively, the pixel array section 540 of the first substrate 100 may be provided with a pair of pixel sharing units 539 in which two pixel sharing units 539 are arranged adjacent to each other in the V direction. In the pixel array section 540 of the first substrate 100, for example, the pair of pixel sharing units 539 is repeatedly arranged adjacent to each other at a pitch of two pixels in the H direction (a pitch corresponding to two pixels 541) and at a pitch of four pixels in the V direction (a pitch corresponding to four pixels 541). The pixel sharing unit 539 of the second substrate 200 has the size of one pixel 541 in the H direction and the size of four pixels 541 in the V direction (FIG. 35). For example, the pixel array section 540 of the second substrate 200 is provided with a pair of pixel sharing units 539 including two pixel sharing units 539 having a size corresponding to the four pixels 541. The pixel sharing units 539 are arranged adjacent to each other in the H direction and are arranged to be shifted in the V direction. In the pixel array section 540 of the second substrate 200, for example, the pair of pixel sharing units 539 is repeatedly arrayed adjacent to each other without a gap at a pitch of two pixels in the H direction (a pitch corresponding to two pixels 541) and at a pitch of four pixels in the V direction (a pitch corresponding to four pixels 541). Such repetitive arrangement of the pixel sharing units 539 enables the pixel sharing units 539 to be arranged without any gap. Therefore, it is easy to miniaturize the imaging device 1.

The amplification transistor AMP preferably has, for example, a three-dimensional structure such as a Fin type (FIG. 32). As a result, the size of the effective gate width increases, and noise can be suppressed. The selection transistor SEL, the reset transistor RST, and the FD conversion gain switching transistor FDG have, for example, a planar structure. The amplification transistor AMP may have a planar structure. Alternatively, the selection transistor SEL, the reset transistor RST, or the FD conversion gain switching transistor FDG may have a three-dimensional structure.

The wiring layer 200T includes, for example, a passivation film 221, an interlayer insulating film 222, and a plurality of wirings (first wiring layer W1, second wiring layer W2, third wiring layer W3, and fourth wiring layer W4). The passivation film 221 is, for example, in contact with the surface of the semiconductor layer 200S and covers the entire surface of the semiconductor layer 200S. The passivation film 221 covers the gate electrodes of the selection transistor SEL, the amplification transistor AMP, the reset transistor RST, and the FD conversion gain switching transistor FDG. The interlayer insulating film 222 is provided between the passivation film 221 and the third substrate 300. A plurality of wirings (first wiring layer W1, second wiring layer W2, third wiring layer W3, and fourth wiring layer W4) is separated by the interlayer insulating film 222. The interlayer insulating film 222 includes, for example, silicon oxide.

In the wiring layer 200T, for example, a first wiring layer W1, a second wiring layer W2, a third wiring layer W3, a fourth wiring layer W4, and contact portions 201 and 202 are provided in this order from the semiconductor layer 200S side, and these layers are insulated from each other by an interlayer insulating film 222. The interlayer insulating film 222 is provided with a plurality of connection portions that connect the first wiring layer W1, the second wiring layer W2, the third wiring layer W3 or the fourth wiring layer W4 and lower layers thereof. The connection portion is a portion in which a conductive material is embedded in a connection hole provided in the interlayer insulating film 222. For example, the interlayer insulating film 222 is provided with a connection portion 218V that connects the first wiring layer W1 and the VSS contact region 218 of the semiconductor layer 200S. For example, the hole diameter of the connection portion connecting the elements of such a second substrate 200 is different from the hole diameters of the through electrodes 120E and 121E and the through electrode TGV. Specifically, the hole diameter of the connection hole connecting the elements of the second substrate 200 is preferably smaller than the hole diameters of the through electrodes 120E and 121E and the through electrode TGV. A reason for this will be described hereinafter. The depth of the connection portion (the connection portion 218V or the like) provided in the wiring layer 200T is smaller than the depths of the through electrodes 120E and 121E and the through electrode TGV. Therefore, the connection portion can easily fill the conductive material in the connection hole as compared with the through electrodes 120E and 121E and the through electrode TGV. By making the hole diameter of the connection portion smaller than the hole diameters of the through electrodes 120E and 121E and the through electrode TGV, it is easy to miniaturize the imaging device 1.

For example, the through electrode 120E is connected to the gate of the amplification transistor AMP and the source of the FD conversion gain switching transistor FDG (specifically, a connection hole reaching the source of the FD conversion gain switching transistor FDG) by the first wiring layer W1. The first wiring layer W1 connects, for example, the through electrode 121E and the connection portion 218V, whereby the VSS contact region 218 of the semiconductor layer 200S and the VSS contact region 118 of the semiconductor layer 100S are electrically connected.

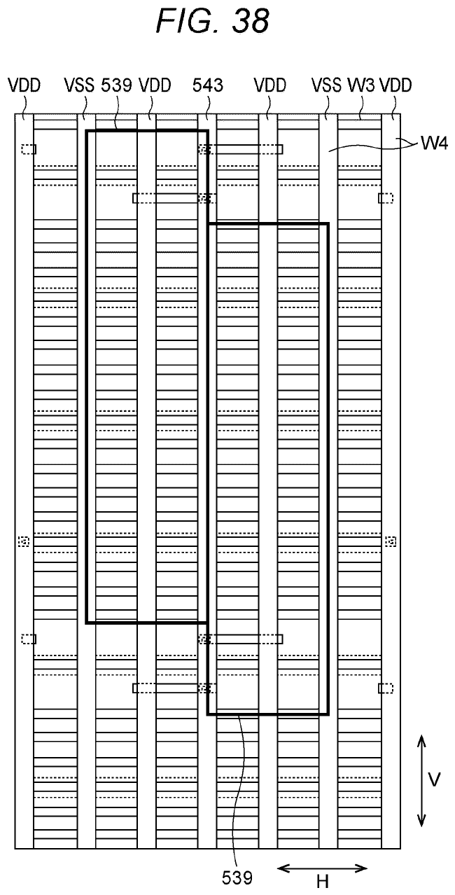

Next, a planar configuration of the wiring layer 200T will be described with reference to FIGS. 36 to 38. FIG. 36 illustrates an example of a planar configuration of the first wiring layer W1 and the second wiring layer W2. FIG. 37 illustrates an example of a planar configuration of the second wiring layer W2 and the third wiring layer W3. FIG. 38 illustrates an example of a planar configuration of the third wiring layer W3 and the fourth wiring layer W4.

For example, the third wiring layer W3 includes wiring lines TRG1, TRG2, TRG3, TRG4, SELL, RSTL, and FDGL extending in the H direction (row direction) (FIG. 37). These wirings correspond to the plurality of row drive signal lines 542 described with reference to FIG. 30. The wirings TRG1, TRG2, TRG3, and TRG4 are for sending drive signals to the transfer gates TG1, TG2, TG3, and TG4, respectively. The wirings TRG1, TRG2, TRG3, and TRG4 are connected to the transfer gates TG1, TG2, TG3, and TG4 via the second wiring layer W2, the first wiring layer W1, and the through electrode 120E, respectively. The wiring SELL is for sending a drive signal to the gate of the selection transistor SEL, the wiring RSTL is for sending a drive signal to the gate of the reset transistor RST, and the wiring FDGL is for sending a drive signal to the gate of the FD conversion gain switching transistor FDG. The wirings SELL, RSTL, and FDGL are connected to the gates of the selection transistor SEL, the reset transistor RST, and the FD conversion gain switching transistor FDG via the second wiring layer W2, the first wiring layer W1, and the connection portion, respectively.

For example, the fourth wiring layer W4 includes a power supply line VDD, a reference potential line VSS, and a vertical signal line 543 extending in the V direction (column direction) (FIG. 38). The power supply line VDD is connected to the drain of the amplification transistor AMP and the drain of the reset transistor RST via the third wiring layer W3, the second wiring layer W2, the first wiring layer W1, and the connection portion. The reference potential line VSS is connected to the VSS contact region 218 via the third wiring layer W3, the second wiring layer W2, the first wiring layer W1, and the connection portion 218V. In addition, the reference potential line VSS is connected to the VSS contact region 118 of the first substrate 100 via the third wiring layer W3, the second wiring layer W2, the first wiring layer W1, the through electrode 121E, and the pad portion 121. The vertical signal line 543 is connected to the source (Vout) of the selection transistor SEL via the third wiring layer W3, the second wiring layer W2, the first wiring layer W1, and the connection portion.

The contact portions 201 and 202 may be provided at a position overlapping the pixel array section 540 in plan view (for example, FIG. 29), or may be provided in the peripheral portion 540B outside the pixel array section 540 (for example, FIG. 32). The contact portions 201 and 202 are provided on the surface (surface on the wiring layer 200T side) of the second substrate 200. The contact portions 201 and 202 are constituted by metal such as copper (Cu) and aluminum (Al), for example. The contact portions 201 and 202 are exposed on the surface (surface on the third substrate 300 side) of the wiring layer 200T. The contact portions 201 and 202 are used for electrical connection between the second substrate 200 and the third substrate 300 and bonding between the second substrate 200 and the third substrate 300.

FIG. 32 illustrates an example in which a peripheral circuit is provided in the peripheral portion 540B of the second substrate 200. The peripheral circuit may include a part of the row drive section 520, a part of the column signal processing section 550, or the like. Furthermore, as illustrated in FIG. 29, the peripheral circuit may not be arranged in the peripheral portion 540B of the second substrate 200, and the connection holes H1 and H2 may be arranged in the vicinity of the pixel array section 540.

The third substrate 300 includes, for example, a wiring layer 300T and a semiconductor layer 300S in this order from the second substrate 200 side. For example, the surface of the semiconductor layer 300S is provided on the second substrate 200 side. The semiconductor layer 300S includes a silicon substrate. A circuit is provided in a portion on the front surface side of the semiconductor layer 300S. Specifically, for example, at least a part of the input section 510A, the row drive section 520, the timing control section 530, the column signal processing section 550, the image signal processing section 560, and the output section 510B is provided in the portion on the front surface side of the semiconductor layer 300S. The wiring layer 300T provided between the semiconductor layer 300S and the second substrate 200 includes, for example, an interlayer insulating film, a plurality of wiring layers separated by the interlayer insulating film, and contact portions 301 and 302. The contact portions 301 and 302 are exposed on the surface (the surface on the second substrate 200 side) of the wiring layer 300T, the contact portion 301 is in contact with the contact portion 201 of the second substrate 200, and the contact portion 302 is in contact with the contact portion 202 of the second substrate 200. The contact portions 301 and 302 are electrically connected to a circuit (for example, at least one of the input section 510A, the row drive section 520, the timing control section 530, the column signal processing section 550, the image signal processing section 560, or the output section 510B) formed in the semiconductor layer 300S. The contact portions 301 and 302 are constituted by metal such as copper (Cu) and aluminum (Al), for example. For example, the external terminal TA is connected to the input section 510A via the connection hole H1, and the external terminal TB is connected to the output section 510B via the connection hole H2.

Here, features of the imaging device 1 will be described.

In general, an imaging apparatus mainly includes a photodiode and a pixel circuit. Here, when the area of the photodiode is increased, the charge generated as a result of photoelectric conversion increases, and as a result, the signal/noise ratio (S/N ratio) of the pixel signal is improved, and the imaging apparatus can output better image data (image information). On the other hand, when the size of the transistor (particularly, the size of the amplification transistor) included in the pixel circuit is increased, noise generated in the pixel circuit is reduced, and as a result, the S/N ratio of the imaging signal is improved, and the imaging apparatus can output better image data (image information).

However, in an imaging apparatus in which a photodiode and a pixel circuit are provided on the same semiconductor substrate, if the area of the photodiode is increased in a limited area of the semiconductor substrate, the size of a transistor included in the pixel circuit may be reduced. Furthermore, if the size of the transistor included in the pixel circuit is increased, the area of the photodiode may be reduced.

In order to solve these problems, for example, the imaging device 1 of the present embodiment uses a structure in which a plurality of pixels 541 shares one pixel circuit 210, and the shared pixel circuit 210 is arranged to be superimposed on the photodiode PD. Thus, it is possible to achieve making the area of the photodiode PD as large as possible and making the size of the transistor included in the pixel circuit 210 as large as possible within the limited area of the semiconductor substrate. As a result, the S/N ratio of the pixel signal can be improved, and the imaging device 1 can output better image data (image information).

When a structure in which the plurality of pixels 541 shares one pixel circuit 210 and the pixel circuit is superimposed and arranged on the photodiode PD is realized, a plurality of wirings connected to one pixel circuit 210 extends from the floating diffusion FD of each of the plurality of pixels 541. In order to secure a large area of the semiconductor substrate 200 forming the pixel circuit 210, for example, a connection wiring can be formed in which a plurality of extending wirings is connected to each other and integrated into one. Similarly, for the plurality of wirings extending from the VSS contact region 118, it is possible to form a connection wiring in which the plurality of extending wirings is connected to each other and integrated into one.

For example, when a connection wiring that mutually connects a plurality of wirings extending from the floating diffusion FD of each of the plurality of pixels 541 is formed in the semiconductor substrate 200 forming the pixel circuit 210, it is conceivable that an area for forming a transistor included in the pixel circuit 210 is reduced. Similarly, when a connection wiring that interconnects a plurality of wirings extending from the VSS contact region 118 of each of the plurality of pixels 541 and combines the plurality of wirings into one is formed on the semiconductor substrate 200 forming the pixel circuit 210, it is conceivable that an area for forming a transistor included in the pixel circuit 210 is reduced.

In order to solve these problems, for example, the imaging device 1 of the present embodiment can have a structure in which a plurality of pixels 541 shares one pixel circuit 210, and the shared pixel circuit 210 is arranged to be superimposed on the photodiode PD, and a structure in which a connection wiring that connects the floating diffusions FD of each of the plurality of pixels 541 to each other and integrates them into one, and a connection wiring that connects the VSS contact regions 118 included in each of the plurality of pixels 541 to each other and integrates them into one are provided on the first substrate 100.

Here, when the above-described second manufacturing method is used as a manufacturing method for providing, on the first substrate 100, the connection wiring that connects the floating diffusions FD of each of the plurality of pixels 541 to each other and integrates them into one and the connection wiring that connects the VSS contact regions 118 of each of the plurality of pixels 541 to each other and integrates them into one, for example, it is possible to manufacture an imaging apparatus with high quality and high performance using an appropriate process according to the configuration of each of the first substrate 100 and the second substrate 200. In addition, the connection wiring of the first substrate 100 and the second substrate 200 can be formed by an easy process. Specifically, in the case of using the second manufacturing method described above, an electrode connected to the floating diffusion FD and an electrode connected to the VSS contact region 118 are provided on the surface of the first substrate 100 and the surface of the second substrate 200, which are the bonding boundary surfaces of the first substrate 100 and the second substrate 200, respectively. Furthermore, it is preferable to enlarge the electrodes formed on the two substrate surfaces so that the electrodes formed on the two substrate surfaces come into contact with each other even if positional deviation occurs between the electrodes provided on the two substrate surfaces when the first substrate 100 and the second substrate 200 are bonded together. In this case, it is conceivable that it becomes difficult to arrange the electrode described above in a limited area of each pixel included in the imaging device 1.

In order to solve the problem that a large electrode is required at the bonding boundary surface between the first substrate 100 and the second substrate 200, for example, the imaging device 1 of the present embodiment can use the first manufacturing method described above as a manufacturing method in which a plurality of pixels 541 shares one pixel circuit 210, and the shared pixel circuit 210 is arranged to be superimposed on the photodiode PD. As a result, it is easy to align the elements formed on the first substrate 100 and the second substrate 200, and a high-quality and high-performance imaging apparatus can be manufactured. Furthermore, a unique structure generated by using this manufacturing method can be provided. That is, the imaging apparatus includes a structure in which the semiconductor layer 100S and the wiring layer 100T of the first substrate 100 and the semiconductor layer 200S and the wiring layer 200T of the second substrate 200 are laminated in this order, in other words, a structure in which the first substrate 100 and the second substrate 200 are laminated in a face-to-back manner, and the through electrodes 120E and 121E that penetrate the semiconductor layer 200S, the wiring layer 100T of the first substrate 100, and reach the surface of the semiconductor layer 100S of the first substrate 100 from the front surface side of the semiconductor layer 200S of the second substrate 200.

In a structure in which the connection wiring that connects the floating diffusions FD of the plurality of pixels 541 to each other and integrates them into one and the connection wiring that connects the VSS contact regions 118 of the plurality of pixels 541 to each other and integrates them into one are provided on the first substrate 100, when this structure and the second substrate 200 are laminated using the first manufacturing method to form the pixel circuit 210 on the second substrate 200, there is a possibility that the influence of the heating treatment required when the active element included in the pixel circuit 210 is formed may reach the above-described connection wiring formed on the first substrate 100.

Therefore, in order to solve the problem that the above-described connection wiring is affected by the heating treatment when the above-described active element is formed, it is desirable that the imaging device 1 of the present embodiment use a conductive material having high heat resistance for the connection wiring that connects the floating diffusions FD of the plurality of pixels 541 to each other and integrates them into one and the connection wiring that connects the VSS contact regions 118 of the plurality of pixels 541 to each other and integrates them into one. Specifically, as the conductive material having high heat resistance, a material having a melting point higher than that of at least a part of the wiring material included in the wiring layer 200T of the second substrate 200 can be used.

As described above, for example, the imaging device 1 of the present embodiment includes: (1) a structure in which the first substrate 100 and the second substrate 200 are laminated in a face-to-back manner (specifically, a structure in which the semiconductor layer 100S and the wiring layer 100T of the first substrate 100 and the semiconductor layer 200S and the wiring layer 200T of the second substrate 200 are laminated in this order); (2) a structure in which the through electrodes 120E and 121E are provided from the front surface side of the semiconductor layer 200S of the second substrate 200, penetrating the semiconductor layer 200S and the wiring layer 100T of the first substrate 100, and reaching the surface of the semiconductor layer 100S of the first substrate 100; and (3) a structure in which the connection wiring that connects the floating diffusions FD included in the plurality of pixels 541 to each other and integrates them into one and the connection wiring that connects the VSS contact regions 118 included in the plurality of pixels 541 to each other and integrates them into one are constituted by a conductive material having high heat resistance. Therefore, without providing a large electrode at the interface between the first substrate 100 and the second substrate 200, the first substrate 100 can be provided with the connection wiring that connects the floating diffusions FD included in the plurality of pixels 541 to each other and integrates them into one and the connection wiring that connects the VSS contact regions 118 included in the plurality of pixels 541 to each other and integrates them into one.

### [Operation of Imaging Device 1]

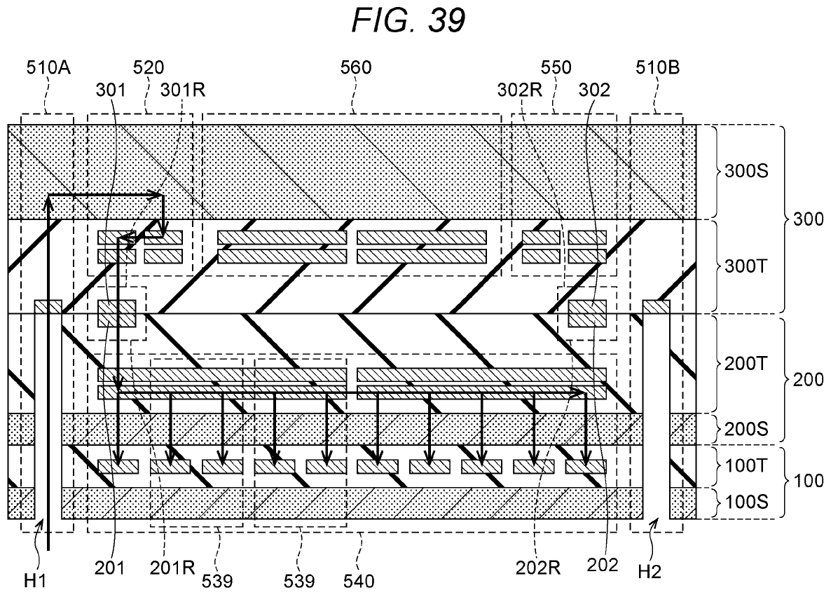

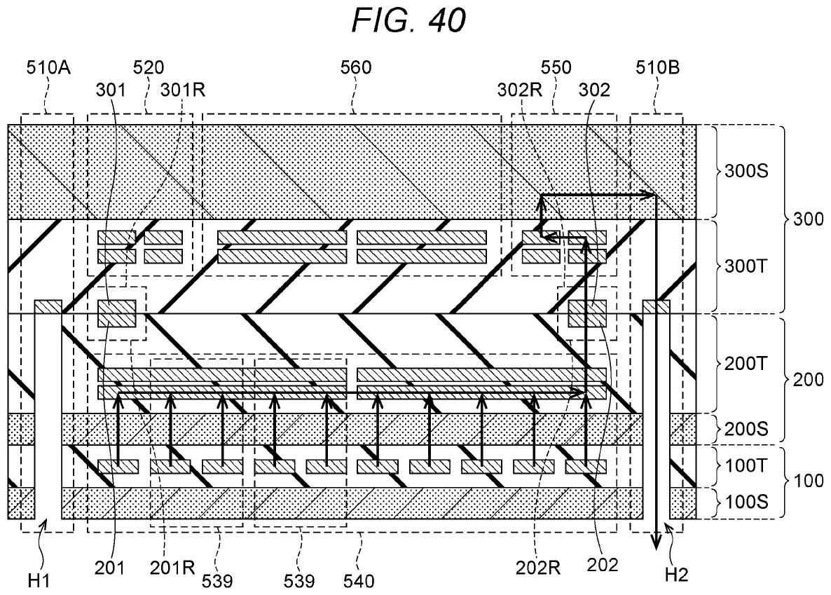

Next, the operation of the imaging device 1 will be described with reference to FIGS. 39 and 40. In FIGS. 39 and 40, an arrow representing a path of each signal is added to FIG. 29. In FIG. 39, an input signal input to the imaging device 1 from the outside, and paths of a power supply potential and a reference potential are indicated by arrows. In FIG. 40, a signal path of a pixel signal output from the imaging device 1 to the outside is indicated by an arrow. For example, an input signal (for example, a pixel clock and a synchronization signal) input to the imaging device 1 via the input section 510A is transmitted to the row drive section 520 of the third substrate 300, and the row drive section 520 creates a row drive signal. The row drive signal is sent to the second substrate 200 via the contact portions 301 and 201. Moreover, the row drive signal reaches each of the pixel sharing units 539 of the pixel array section 540 via the row drive signal line 542 in the wiring layer 200T. Among the row drive signals reaching the pixel sharing unit 539 of the second substrate 200, drive signals other than the transfer gate TG are input to the pixel circuit 210, and each transistor included in the pixel circuit 210 is driven. A drive signal of the transfer gate TG is input to the transfer gates TG1, TG2, TG3, and TG4 of the first substrate 100 via the through electrode TGV, and the pixels 541A, 541B, 541C, and 541D are driven (FIG. 39). Furthermore, the power supply potential and the reference potential supplied from the outside of the imaging device 1 to the input section 510A (input terminal 511) of the third substrate 300 are sent to the second substrate 200 via the contact portions 301 and 201, and supplied to the pixel circuit 210 of each of the pixel sharing units 539 via the wiring in the wiring layer 200T. The reference potential is further supplied to the pixels 541A, 541B, 541C, and 541D of the first substrate 100 via the through electrode 121E. On the other hand, the pixel signal photoelectrically converted by the pixels 541A, 541B, 541C, and 541D of the first substrate 100 is sent to the pixel circuit 210 of the second substrate 200 for each pixel sharing unit 539 via the through electrode 120E. The pixel signal based on this pixel signal is sent from the pixel circuit 210 to the third substrate 300 via the vertical signal line 543 and the contact portions 202 and 302. This pixel signal is processed by the column signal processing section 550 and the image signal processing section 560 of the third substrate 300, and then output to the outside via the output section 510B.

### [Effects]

In the present embodiment, the pixels 541A, 541B, 541C, and 541D (pixel sharing unit 539) and the pixel circuit 210 are provided on different substrates (first substrate 100 and second substrate 200). Thus, the areas of the pixels 541A, 541B, 541C, and 541D and the pixel circuit 210 can be enlarged as compared with a case where the pixels 541A, 541B, 541C, and 541D and the pixel circuit 210 are formed on the same substrate. As a result, the amount of pixel signals obtained by photoelectric conversion can be increased, and transistor noise of the pixel circuit 210 can be reduced. Thus, the signal/noise ratio of the pixel signal is improved, and the imaging device 1 can output better pixel data (image information). In addition, the imaging device 1 can be miniaturized (in other words, the pixel size is reduced and the imaging device 1 is downsized). The imaging device 1 can increase the number of pixels per unit area by reducing the pixel size, and can output a high-quality image.

Furthermore, in the imaging device 1, the first substrate 100 and the second substrate 200 are electrically connected to each other by the through electrodes 120E and 121E provided in the insulating region 212. For example, a method of connecting the first substrate 100 and the second substrate 200 by bonding pad electrodes to each other, or a method of connecting the first substrate 100 and the second substrate 200 by through wiring (for example, thorough Si via (TSV)) penetrating the semiconductor layer may be considered. As compared with such a method, by providing the through electrodes 120E and 121E in the insulating region 212, the area required for connecting the first substrate 100 and the second substrate 200 can be reduced. As a result, the pixel size can be reduced, and the imaging device 1 can be further downsized.

Furthermore, the resolution can be further increased by further miniaturizing the area per pixel. When it is not necessary to reduce the chip size, the formation region of the pixels 541A, 541B, 541C, and 541D and the pixel circuit 210 can be enlarged. As a result, the amount of pixel signals obtained by photoelectric conversion can be increased, and noise of the transistor included in the pixel circuit 210 can be reduced. Thus, the signal/noise ratio of the pixel signal can be improved, and the imaging device 1 can output better pixel data (image information).

Furthermore, in the imaging device 1, the pixel circuit 210 and the column signal processing section 550 and the image signal processing section 560 are provided on different substrates (the second substrate 200 and the third substrate 300). As a result, the area of the pixel circuit 210 and the areas of the column signal processing section 550 and the image signal processing section 560 can be enlarged as compared with a case where the pixel circuit 210 and the column signal processing section 550 and the image signal processing section 560 are formed on the same substrate. Thus, noise generated in the column signal processing section 550 can be reduced, and an advanced image processing circuit can be mounted by the image signal processing section 560. Therefore, the signal/noise ratio of the pixel signal can be improved, and the imaging device 1 can output better pixel data (image information).

Furthermore, in the imaging device 1, the pixel array section 540 is provided on the first substrate 100 and the second substrate 200, and the column signal processing section 550 and the image signal processing section 560 are provided on the third substrate 300. In addition, the contact portions 201, 202, 301, and 302 connecting the second substrate 200 and the third substrate 300 is formed above the pixel array section 540. Therefore, the contact portions 201, 202, 301, and 302 can be freely laid out without receiving layout interference from various wirings provided in the pixel array. Accordingly, the contact portions 201, 202, 301, and 302 can be used for electrical connection between the second substrate 200 and the third substrate 300. By using the contact portions 201, 202, 301, and 302, for example, the column signal processing section 550 and the image signal processing section 560 have a higher degree of freedom in layout. Thus, noise generated in the column signal processing section 550 can be reduced, and an advanced image processing circuit can be mounted by the image signal processing section 560. Therefore, the signal/noise ratio of the pixel signal can be improved, and the imaging device 1 can output better pixel data (image information).

Furthermore, in the imaging device 1, the pixel isolation portion 117 penetrates the semiconductor layer 100S. As a result, color mixing among the pixels 541A, 541B, 541C, and 541D can be suppressed even in a case where the distance between adjacent pixels (pixels 541A, 541B, 541C, and 541D) is shortened due to miniaturization of the area per pixel. Thus, the signal/noise ratio of the pixel signal can be improved, and the imaging device 1 can output better pixel data (image information).

Furthermore, in the imaging device 1, a pixel circuit 210 is provided for each pixel sharing unit 539. As a result, as compared with a case where the pixel circuit 210 is provided in each of the pixels 541A, 541B, 541C, and 541D, the formation region of the transistor (amplification transistor AMP, reset transistor RST, selection transistor SEL, and FD conversion gain switching transistor FDG) constituting the pixel circuit 210 can be enlarged. For example, noise can be suppressed by increasing the formation region of the amplification transistor AMP. Thus, the signal/noise ratio of the pixel signal can be improved, and the imaging device 1 can output better pixel data (image information).

Furthermore, in the imaging device 1, the pad portion 120 that electrically connects the floating diffusions FD (floating diffusions FD1, FD2, FD3, and FD4) of the four pixels (pixels 541A, 541B, 541C, and 541D) is provided on the first substrate 100. As a result, the number of through electrodes (through electrodes 120E) connecting the first substrate 100 and the second substrate 200 can be reduced as compared with the case where such a pad portion 120 is provided on the second substrate 200. Therefore, the insulating region 212 can be made small, and the transistor formation region (semiconductor layer 200S) constituting the pixel circuit 210 can be secured with a sufficient size. As a result, noise of the transistor included in the pixel circuit 210 can be reduced, the signal/noise ratio of the pixel signal can be improved, and the imaging device 1 can output better pixel data (image information).

Hereinafter, modifications of the imaging device 1 according to the above embodiments will be described. In the following modifications, the same reference signs are given to the same configurations as those of the above embodiments.

### <2. Modification 1>

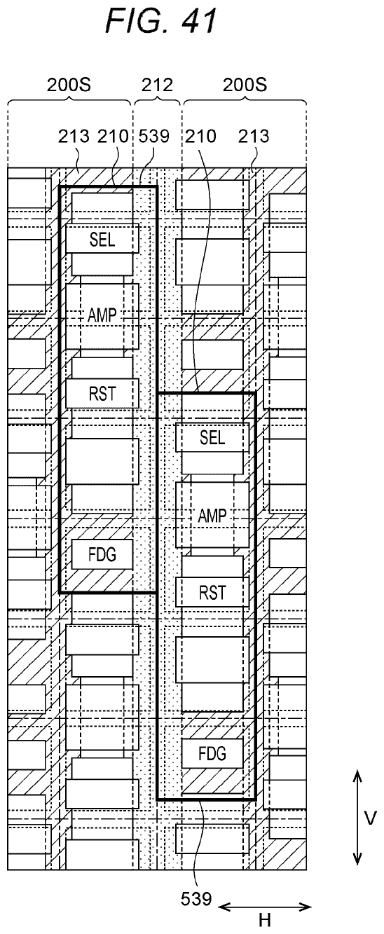

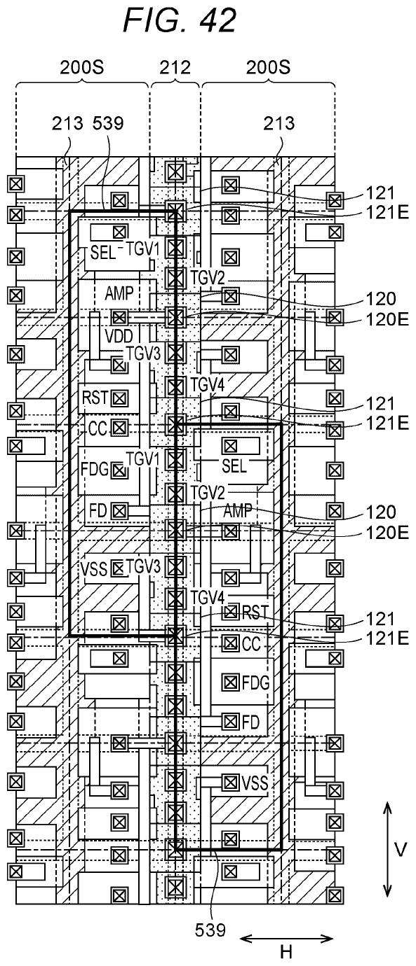

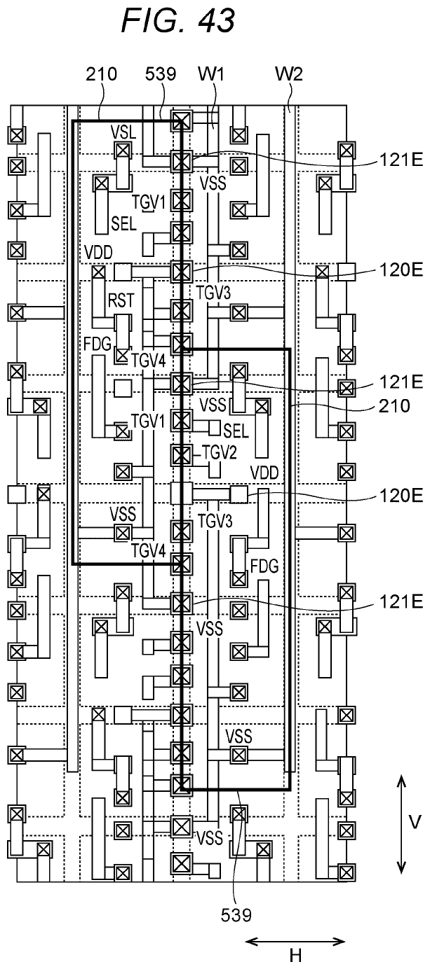

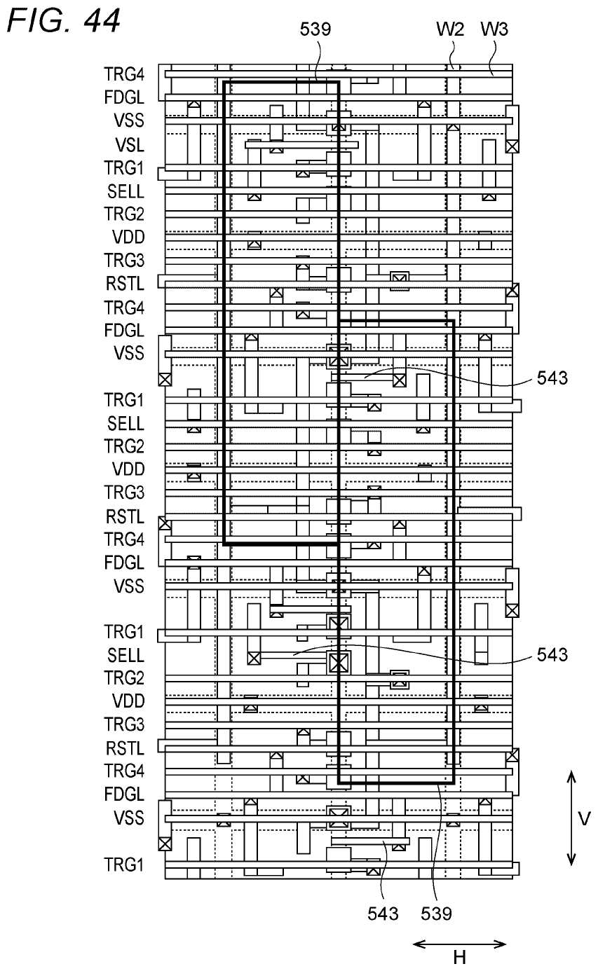

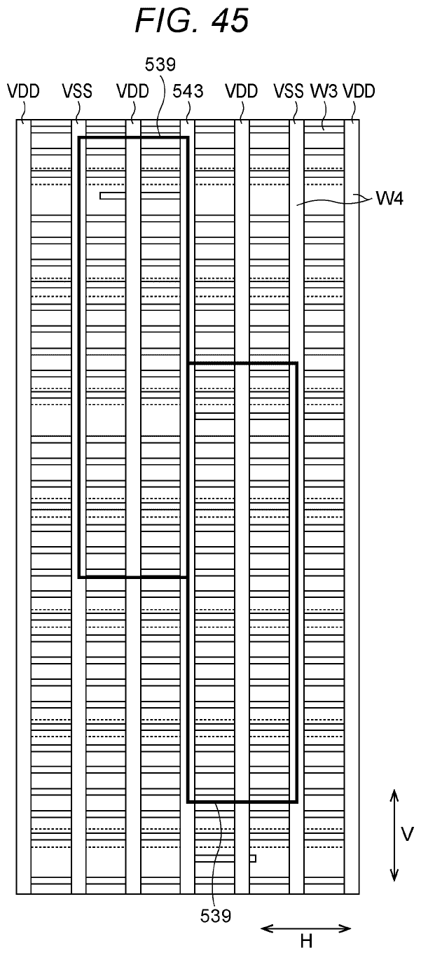

FIGS. 41 to 45 illustrate a modification of the planar configuration of the imaging device 1 according to the above embodiments. FIG. 41 schematically illustrates a planar configuration in the vicinity of the surface of the semiconductor layer 200S of the second substrate 200, and corresponds to FIG. 34 described in the above embodiments. FIG. 42 schematically illustrates a configuration of each part of the first wiring layer W1, the semiconductor layer 200S connected to the first wiring layer W1, and the first substrate 100, and corresponds to FIG. 35 described in the above embodiments. FIG. 43 illustrates an example of a planar configuration of the first wiring layer W1 and the second wiring layer W2, and corresponds to FIG. 36 described in the above embodiments. FIG. 44 illustrates an example of a planar configuration of the second wiring layer W2 and the third wiring layer W3, and corresponds to FIG. 37 described in the above embodiments. FIG. 45 illustrates an example of a planar configuration of the third wiring layer W3 and the fourth wiring layer W4, and corresponds to FIG. 38 described in the above embodiments.

In the present modification, as illustrated in FIG. 42, among the two pixel sharing units 539 arranged in the H direction on the second substrate 200, the internal layout of one (for example, the right side on the paper surface) pixel sharing unit 539 has a configuration in which the internal layout of the other (for example, the left side on the paper surface) pixel sharing unit 539 is inverted only in the H direction. In addition, the deviation in the V direction between the outline of one pixel sharing unit 539 and the outline of the other pixel sharing unit 539 is larger than the deviation (FIG. 35) described in the above embodiments. In this manner, by increasing the deviation in the V direction, the distance between the amplification transistor AMP of the other pixel sharing unit 539 and the pad portion 120 (the pad portion 120 of the other (lower side on the paper surface) of the two pixel sharing units 539 arranged in the V direction illustrated in FIG. 33) connected thereto can be reduced. With such a layout, Modification 1 of the imaging device 1 illustrated in FIGS. 41 to 45 can make the area of the planar layout of the two pixel sharing units 539 arranged in the H direction the same as the area of the pixel sharing unit 539 of the second substrate 200 described in the above embodiments without inverting the planar layout of the two pixel sharing units 539 in the V direction. Note that the planar layout of the pixel sharing unit 539 of the first substrate 100 is the same as the planar layout (FIG. 33A, FIG. 33B) described in the above embodiments. Therefore, the imaging device 1 of the present modification can obtain effects similar to those of the imaging device 1 described in the above embodiments. The arrangement of the pixel sharing unit 539 of the second substrate 200 is not limited to the arrangement described in the above embodiments and the present modification.

### <3. Modification 2>

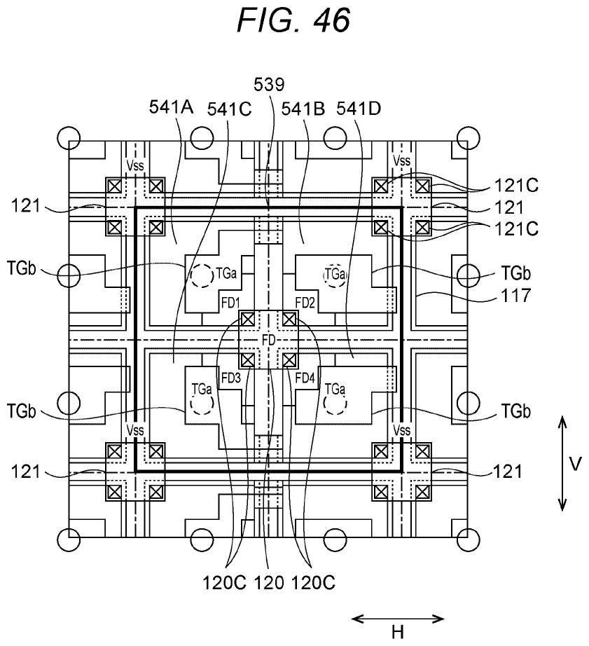

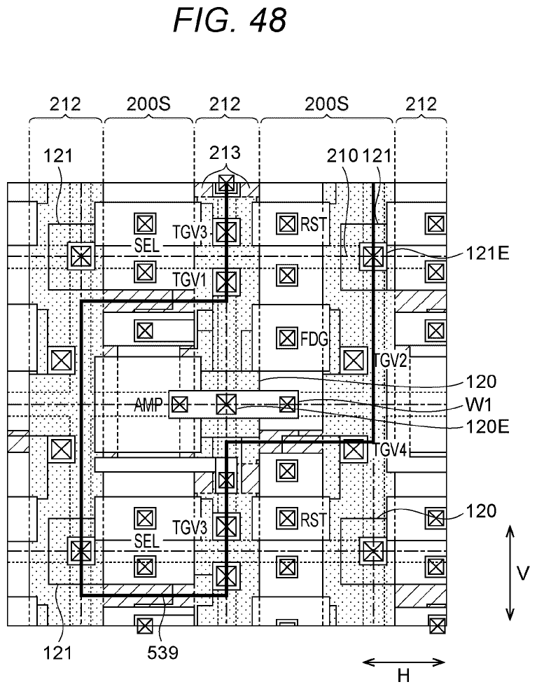

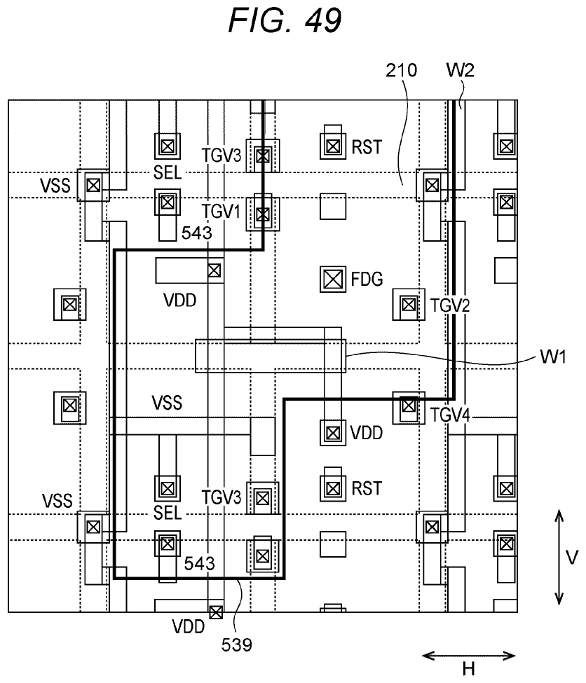

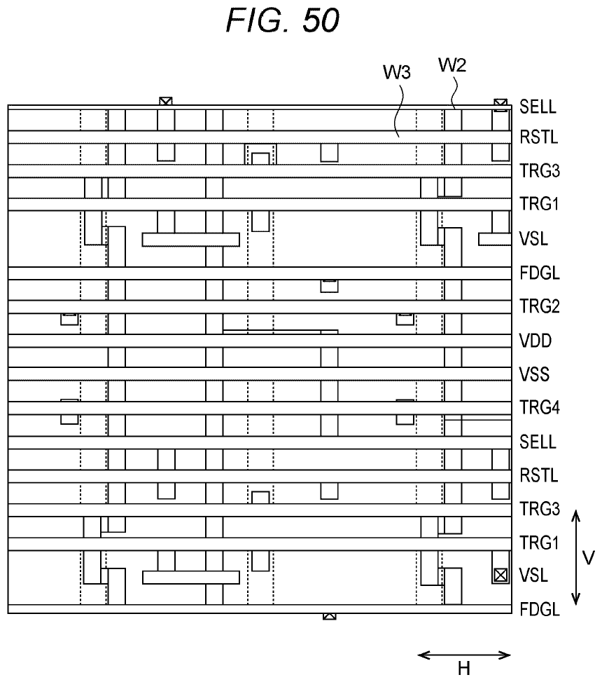

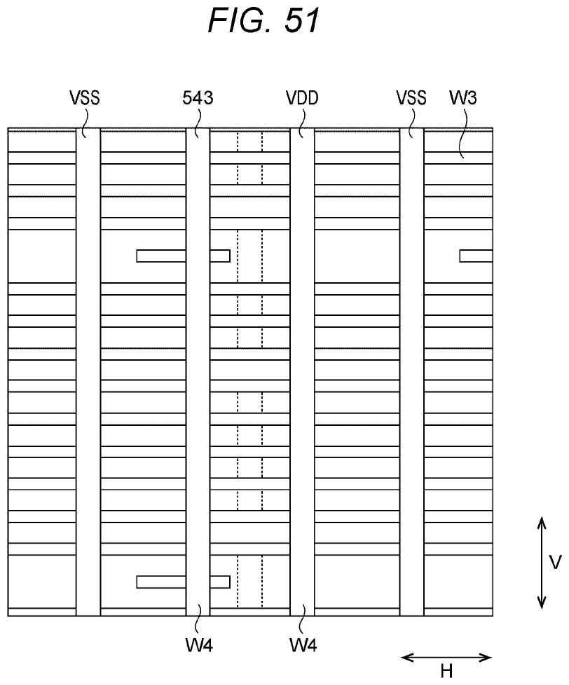

FIGS. 46 to 51 illustrate a modification of the planar configuration of the imaging device 1 according to the above embodiments. FIG. 46 schematically illustrates a planar configuration of the first substrate 100, and corresponds to FIG. 33A described in the above embodiments. FIG. 47 schematically illustrates a planar configuration in the vicinity of the surface of the semiconductor layer 200S of the second substrate 200, and corresponds to FIG. 34 described in the above embodiments. FIG. 48 schematically illustrates a configuration of each part of the first wiring layer W1, the semiconductor layer 200S connected to the first wiring layer W1, and the first substrate 100, and corresponds to FIG. 35 described in the above embodiments. FIG. 49 illustrates an example of a planar configuration of the first wiring layer W1 and the second wiring layer W2, and corresponds to FIG. 36 described in the above embodiments. FIG. 50 illustrates an example of a planar configuration of the second wiring layer W2 and the third wiring layer W3, and corresponds to FIG. 37 described in the above embodiments. FIG. 51 illustrates an example of a planar configuration of the third wiring layer W3 and the fourth wiring layer W4, and corresponds to FIG. 38 described in the above embodiments.

In the present modification, the outer shape of each pixel circuit 210 has a substantially square planar shape (FIG. 47 and the like). In this respect, the planar configuration of the imaging device 1 of the present modification is different from the planar configuration of the imaging device 1 described in the above embodiments.

For example, the pixel sharing unit 539 of the first substrate 100 is formed over a pixel region of two rows x two columns, and has a substantially square planar shape (FIG. 46), as described in the above embodiments. For example, in each pixel sharing unit 539, the horizontal portions TGb of the transfer gates TG1 and TG3 of the pixel 541A and the pixel 541C of one pixel column extend in the direction from the position overlapping the vertical portion TGa toward the central portion of the pixel sharing unit 539 in the H direction (more specifically, a direction toward the outer edges of the pixels 541A and 541C and a direction toward the central portion of the pixel sharing unit 539), and the horizontal portions TGb of the transfer gates TG2 and TG4 of the pixel 541B and the pixel 541D of the other pixel column extend in the direction from the position overlapping the vertical portion TGa toward the outside of the pixel sharing unit 539 in the H direction (more specifically, a direction toward the outer edges of the pixels 541B and 541D and a direction toward the outside of the pixel sharing unit 539). The pad portion 120 connected to the floating diffusion FD is provided at a central portion of the pixel sharing unit 539 (a central portion of the pixel sharing unit 539 in the H direction and the V direction), and the pad portion 121 connected to the VSS contact region 118 is provided at an end portion of the pixel sharing unit 539 at least in the H direction (in the H direction and the V direction in FIG. 46).

As another arrangement example, it is also conceivable to provide the horizontal portions TGb of the transfer gates TG1, TG2, TG3, and TG4 only in a region facing the vertical portion TGa. At this time, the semiconductor layer 200S is likely to be finely divided as described in the above embodiments. Therefore, it is difficult to form a large transistor of the pixel circuit 210. On the other hand, when the horizontal portions TGb of the transfer gates TG1, TG2, TG3, and TG4 are extended in the H direction from the position overlapping the vertical portion TGa as in the above modification, the width of the semiconductor layer 200S can be increased as described in the above embodiments. Specifically, the positions in the H direction of the through electrodes TGV1 and TGV3 connected to the transfer gates TG1 and TG3 can be arranged close to the position in the H direction of the through electrode 120E, and the positions in the H direction of the through electrodes TGV2 and TGV4 connected to the transfer gates TG2 and TG4 can be arranged close to the position in the H direction of the through electrode 121E (FIG. 48). As a result, the width (size in the H direction) of the semiconductor layer 200S extending in the V direction can be increased as described in the above embodiments. Therefore, it is possible to increase the size of the transistor of the pixel circuit 210, particularly, the size of the amplification transistor AMP. As a result, the signal/noise ratio of the pixel signal is improved, and the imaging device 1 can output better pixel data (image information).

The pixel sharing unit 539 of the second substrate 200 has, for example, substantially the same size in the H direction and the V direction as that of the pixel sharing unit 539 of the first substrate 100, and is provided over, for example, a region corresponding to a pixel region of approximately two rows x two columns. For example, in each pixel circuit 210, the selection transistor SEL and the amplification transistor AMP are arranged side by side in the V direction in one semiconductor layer 200S extending in the V direction, and the FD conversion gain switching transistor FDG and the reset transistor RST are arranged side by side in the V direction in one semiconductor layer 200S extending in the V direction. One semiconductor layer 200S provided with the selection transistor SEL and the amplification transistor AMP and one semiconductor layer 200S provided with the FD conversion gain switching transistor FDG and the reset transistor RST are arranged in the H direction via the insulating region 212. The insulating region 212 extends in the V direction (FIG. 47).

Here, the outer shape of the pixel sharing unit 539 of the second substrate 200 will be described with reference to FIGS. 47 and 48. For example, the pixel sharing unit 539 of the first substrate 100 illustrated in FIG. 46 is connected to the amplification transistor AMP and the selection transistor SEL provided on one side (the left side on the paper surface of FIG. 48) of the pad portion 120 in the H direction, and the FD conversion gain switching transistor FDG and the reset transistor RST provided on the other side (the right side on the paper surface of FIG. 48) of the pad portion 120 in the H direction. The outer shape of the sharing unit 541 of the second substrate 200 including the amplification transistor AMP, the selection transistor SEL, the FD conversion gain switching transistor FDG, and the reset transistor RST is determined by the following four outer edges.

The first outer edge is an outer edge of one end (end on the upper side on the paper surface of FIG. 48) in the V direction of the semiconductor layer 200S including the selection transistor SEL and the amplification transistor AMP. The first outer edge is provided between the amplification transistor AMP included in the pixel sharing unit 539 and the selection transistor SEL included in the pixel sharing unit 539 adjacent to one side (the upper side on the paper surface of FIG. 48) of the pixel sharing unit 539 in the V direction. More specifically, the first outer edge is provided at the central portion in the V direction of the element isolation region 213 between the amplification transistor AMP and the selection transistor SEL. The second outer edge is an outer edge of the other end (the lower side on the paper surface of FIG. 48) in the V direction of the semiconductor layer 200S including the selection transistor SEL and the amplification transistor AMP. The second outer edge is provided between the selection transistor SEL included in the pixel sharing unit 539 and the amplification transistor AMP included in the pixel sharing unit 539 adjacent to the other side (the lower side on the paper surface of FIG. 48) of the pixel sharing unit 539 in the V direction. More specifically, the second outer edge is provided at the central portion in the V direction of the element isolation region 213 between the selection transistor SEL and the amplification transistor AMP. The third outer edge is an outer edge of the other end (the lower side on the paper surface of FIG. 48) in the V direction of the semiconductor layer 200S including the reset transistor RST and the FD conversion gain switching transistor FDG. The third outer edge is provided between the FD conversion gain switching transistor FDG included in the pixel sharing unit 539 and the reset transistor RST included in the pixel sharing unit 539 adjacent to the other side (the lower side on the paper surface of FIG. 48) of the pixel sharing unit 539 in the V direction. More specifically, the third outer edge is provided at the central portion in the V direction of the element isolation region 213 between the FD conversion gain switching transistor FDG and the reset transistor RST. The fourth outer edge is an outer edge of one end (the upper side on the paper surface of FIG. 48) in the V direction of the semiconductor layer 200S including the reset transistor RST and the FD conversion gain switching transistor FDG. The fourth outer edge is provided between the reset transistor RST included in the pixel sharing unit 539 and the FD conversion gain switching transistor FDG (not illustrated) included in the pixel sharing unit 539 adjacent to one side (the upper side on the paper surface of FIG. 48) of the pixel sharing unit 539 in the V direction. More specifically, the fourth outer edge is provided at the central portion in the V direction of the element isolation region 213 (not illustrated) between the reset transistor RST and the FD conversion gain switching transistor FDG.

In the outer shape of the pixel sharing unit 539 of the second substrate 200 including such first, second, third, and fourth outer edges, the third and fourth outer edges are arranged to be shifted to one side in the V direction (in other words, offset to one side in the V direction) with respect to the first and second outer edges. By using such a layout, both the gate of the amplification transistor AMP and the source of the FD conversion gain switching transistor FDG can be arranged as close as possible to the pad portion 120. Therefore, the area of the wiring connecting them is reduced, and the imaging device 1 can be easily miniaturized. Note that the VSS contact region 218 is provided between the semiconductor layer 200S including the selection transistor SEL and the amplification transistor AMP and the semiconductor layer 200S including the reset transistor RST and the FD conversion gain switching transistor FDG. For example, the plurality of pixel circuits 210 has the same arrangement.

The imaging device 1 including such a second substrate 200 can also obtain effects similar to those described in the above embodiments. The arrangement of the pixel sharing unit 539 of the second substrate 200 is not limited to the arrangement described in the above embodiments and the present modification.

### <4. Modification 3>

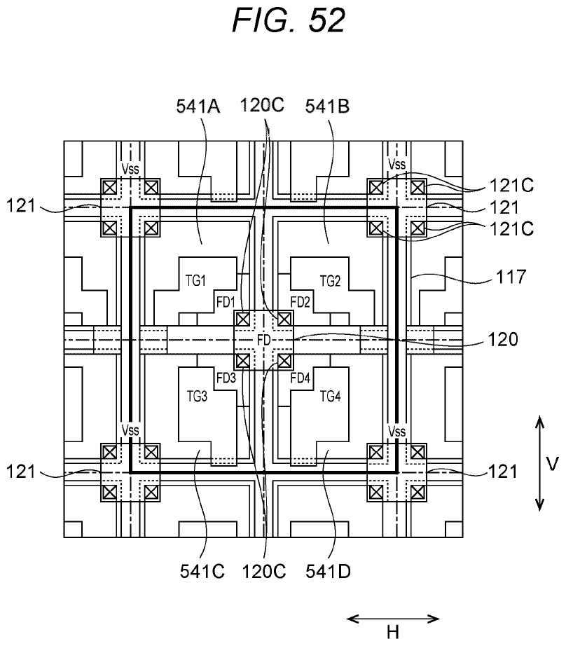

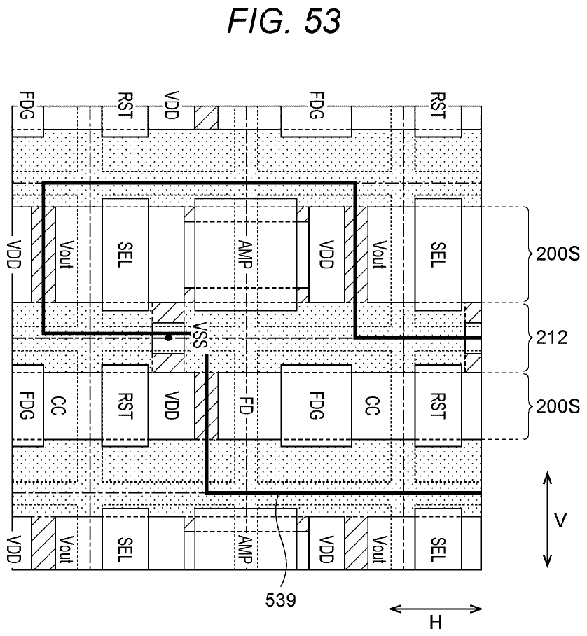

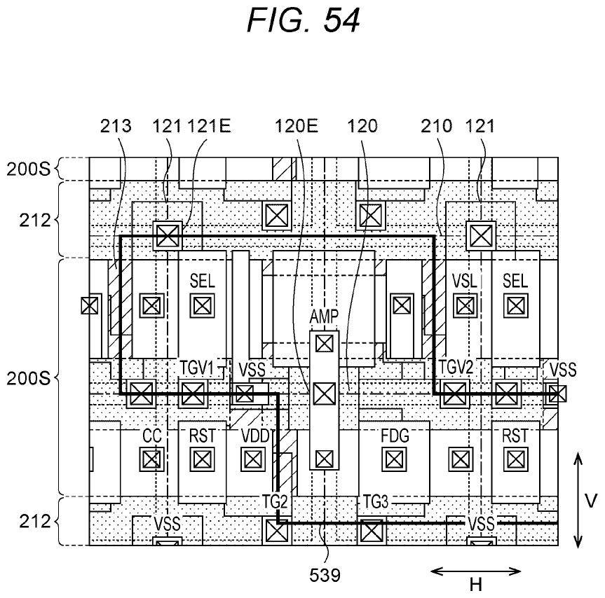

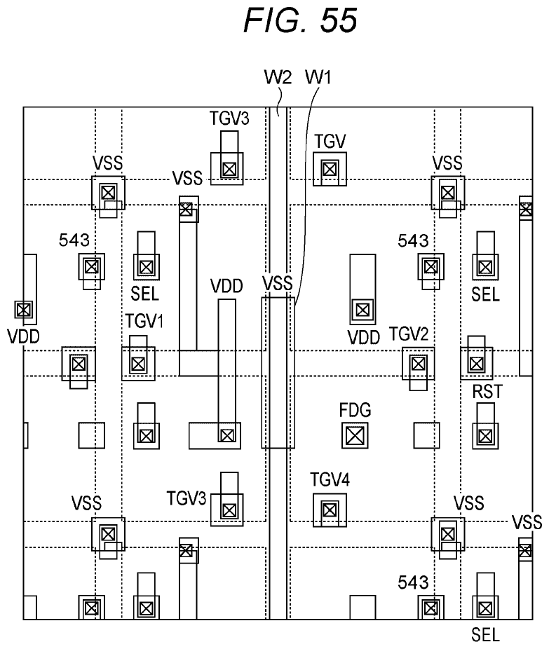

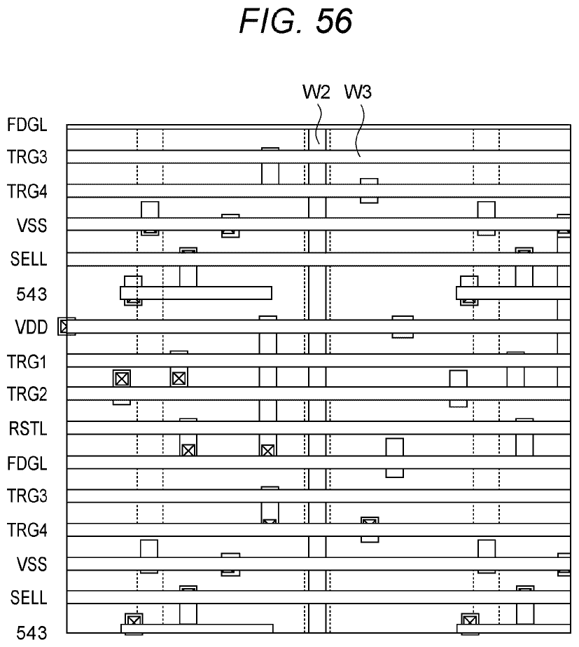

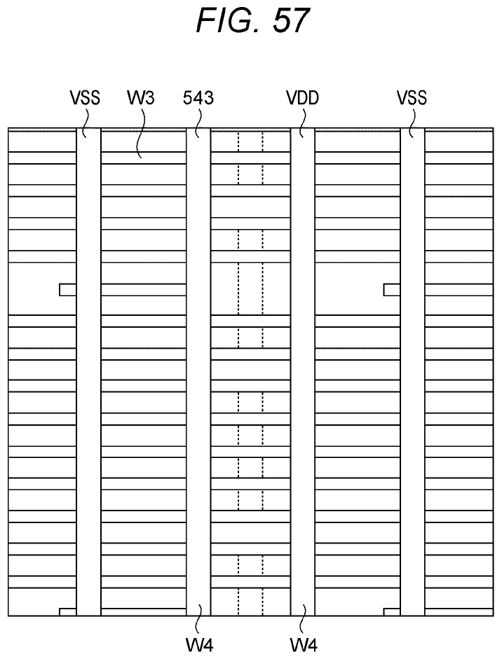

FIGS. 52 to 57 illustrate a modification of the planar configuration of the imaging device 1 according to the above embodiments. FIG. 52 schematically illustrates a planar configuration of the first substrate 100, and corresponds to FIG. 33B described in the above embodiments. FIG. 53 schematically illustrates a planar configuration in the vicinity of the surface of the semiconductor layer 200S of the second substrate 200, and corresponds to FIG. 34 described in the above embodiments. FIG. 54 schematically illustrates a configuration of each part of the first wiring layer W1, the semiconductor layer 200S connected to the first wiring layer W1, and the first substrate 100, and corresponds to FIG. 35 described in the above embodiments. FIG. 55 illustrates an example of a planar configuration of the first wiring layer W1 and the second wiring layer W2, and corresponds to FIG. 36 described in the above embodiments. FIG. 56 illustrates an example of a planar configuration of the second wiring layer W2 and the third wiring layer W3, and corresponds to FIG. 37 described in the above embodiments. FIG. 57 illustrates an example of a planar configuration of the third wiring layer W3 and the fourth wiring layer W4, and corresponds to FIG. 38 described in the above embodiments.

In the present modification, the semiconductor layer 200S of the second substrate 200 extends in the H direction (FIG. 54). That is, it substantially corresponds to the configuration in which the planar configuration of the imaging device 1 illustrated in FIG. 47 described above and the like is rotated by 90 degrees.

For example, the pixel sharing unit 539 of the first substrate 100 is formed over a pixel region of two rows x two columns, and has a substantially square planar shape (FIG. 52), as described in the above embodiments. For example, in each pixel sharing unit 539, the transfer gates TG1 and TG2 of the pixel 541A and the pixel 541B of one pixel row extend toward the central portion of the pixel sharing unit 539 in the V direction, and the transfer gates TG3 and TG4 of the pixel 541C and the pixel 541D of the other pixel row extend in the outer direction of the pixel sharing unit 539 in the V direction. The pad portion 120 connected to the floating diffusion FD is provided at a central portion of the pixel sharing unit 539, and the pad portion 121 connected to the VSS contact region 118 is provided at an end portion of the pixel sharing unit 539 at least in the V direction (in the V direction and the H direction in FIG. 52). At this time, the positions in the V direction of the through electrodes TGV1 and TGV2 of the transfer gates TG1 and TG2 approach the positions in the V direction of the through electrode 120E, and the positions in the V direction of the through electrodes TGV3 and TGV4 of the transfer gates TG3 and TG4 approach the positions in the V direction of the through electrode 121E (FIG. 54). Therefore, the width (the size in the V direction) of the semiconductor layer 200S extending in the H direction can be increased for reasons similar to those described in the above embodiments. Therefore, it is possible to increase the size of the amplification transistor AMP and suppress noise.

In each pixel circuit 210, the selection transistor SEL and the amplification transistor AMP are arranged side by side in the H direction, and the reset transistor RST is arranged at a position adjacent in the V direction with the selection transistor SEL and the insulating region 212 interposed therebetween (FIG. 53). The FD conversion gain switching transistor FDG is arranged side by side with the reset transistor RST in the H direction. The VSS contact region 218 is provided in an island shape in the insulating region 212. For example, the third wiring layer W3 extends in the H direction (FIG. 56), and the fourth wiring layer W4 extends in the V direction (FIG. 57).

The imaging device 1 including such a second substrate 200 can also obtain effects similar to those described in the above embodiments. The arrangement of the pixel sharing unit 539 of the second substrate 200 is not limited to the arrangement described in the above embodiments and the present modification. For example, the semiconductor layer 200S described in the above embodiments and Modification 1 may extend in the H direction.

### <5. Modification 4>

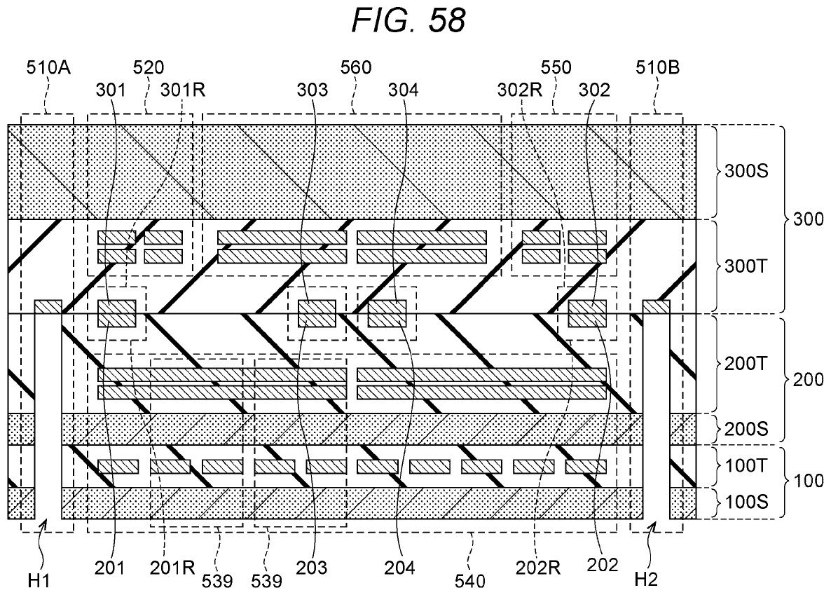

FIG. 58 schematically illustrates a modification of the cross-sectional configuration of the imaging device 1 according to the above embodiments. FIG. 58 corresponds to FIG. 29 described in the above embodiments. In the present modification, in addition to the contact portions 201, 202, 301, and 302, the imaging device 1 includes contact portions 203, 204, 303, and 304 at a position facing the central portion of the pixel array section 540. In this respect, the imaging device 1 of the present modification is different from the imaging device 1 described in the above embodiments.

The contact portions 203 and 204 are provided on the second substrate 200, and a bonding surface with the third substrate 300 is exposed. The contact portions 303 and 304 are provided on the third substrate 300 and is exposed on a bonding surface with the second substrate 200. The contact portion 203 is in contact with the contact portion 303, and the contact portion 204 is in contact with the contact portion 304. That is, in the imaging device 1, the second substrate 200 and the third substrate 300 are connected by the contact portions 203, 204, 303, and 304 in addition to the contact portions 201, 202, 301, and 302.

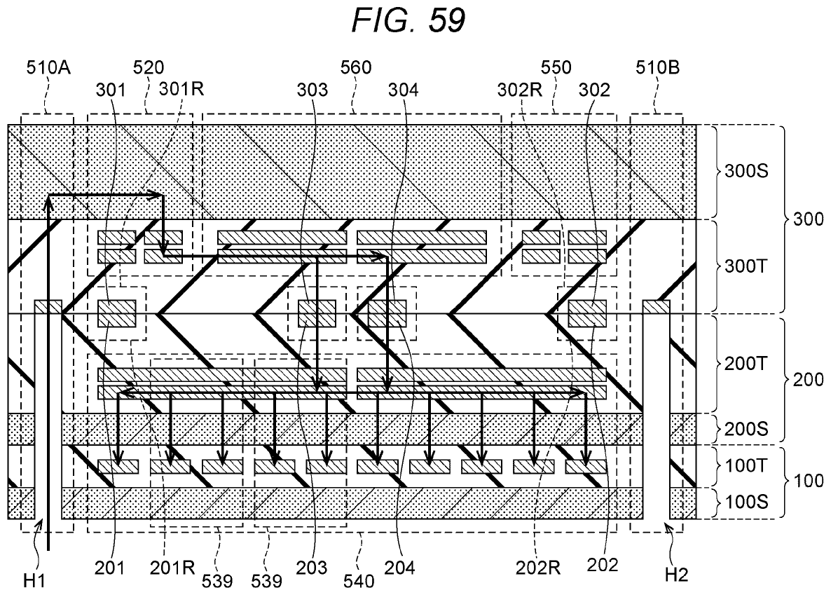

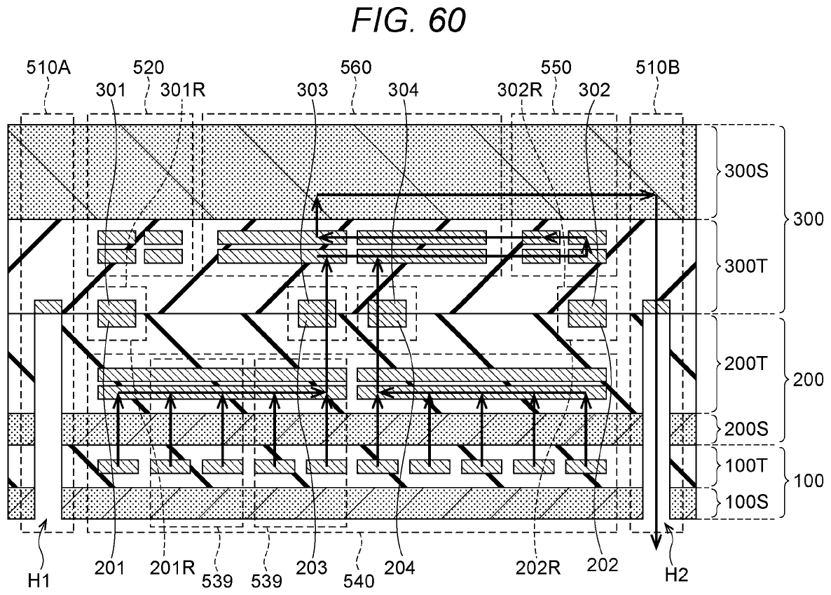

Next, the operation of the imaging device 1 will be described with reference to FIGS. 59 and 60. In FIG. 59, an input signal input to the imaging device 1 from the outside, and paths of a power supply potential and a reference potential are indicated by arrows. In FIG. 60, a signal path of a pixel signal output from the imaging device 1 to the outside is represented by an arrow. For example, an input signal input to the imaging device 1 via the input section 510A is transmitted to the row drive section 520 of the third substrate 300, and the row drive section 520 creates a row drive signal. The row drive signal is sent to the second substrate 200 via the contact portions 303 and 203. Moreover, the row drive signal reaches each of the pixel sharing units 539 of the pixel array section 540 via the row drive signal line 542 in the wiring layer 200T. Among the row drive signals reaching the pixel sharing unit 539 of the second substrate 200, drive signals other than the transfer gate TG are input to the pixel circuit 210, and each transistor included in the pixel circuit 210 is driven. A drive signal of the transfer gate TG is input to the transfer gates TG1, TG2, TG3, and TG4 of the first substrate 100 via the through electrode TGV, and the pixels 541A, 541B, 541C, and 541D are driven. Furthermore, the power supply potential and the reference potential supplied from the outside of the imaging device 1 to the input section 510A (input terminal 511) of the third substrate 300 are sent to the second substrate 200 via the contact portions 303 and 203, and supplied to the pixel circuit 210 of each of the pixel sharing units 539 via the wiring in the wiring layer 200T. The reference potential is further supplied to the pixels 541A, 541B, 541C, and 541D of the first substrate 100 via the through electrode 121E. On the other hand, the pixel signal photoelectrically converted by the pixels 541A, 541B, 541C, and 541D of the first substrate 100 is sent to the pixel circuit 210 of the second substrate 200 for each pixel sharing unit 539. The pixel signal based on this pixel signal is sent from the pixel circuit 210 to the third substrate 300 via the vertical signal line 543 and the contact portions 204 and 304. This pixel signal is processed by the column signal processing section 550 and the image signal processing section 560 of the third substrate 300, and then output to the outside via the output section 510B.

The imaging device 1 including such contact portions 203, 204, 303, and 304 can also obtain effects similar to those described in the above embodiments. The position, the number, and the like of the contact portions can be changed according to the design of the circuit or the like of the third substrate 300 to which the wiring is connected via the contact portions 303 and 304.

### <6. Modification 5>

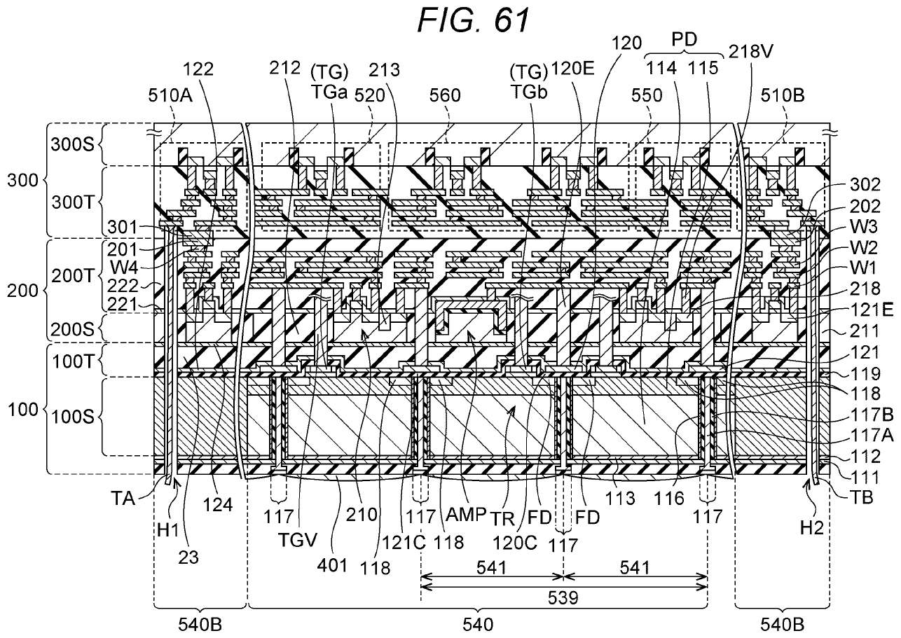

FIG. 61 illustrates a modification of the cross-sectional configuration of the imaging device 1 according to the above embodiments. FIG. 61 corresponds to FIG. 6 described in the above embodiments. In the present modification, the transfer transistor TR having a planar structure is provided on the first substrate 100. In this respect, the imaging device 1 of the present modification is different from the imaging device 1 described in the above embodiments.

In the transfer transistor TR, the transfer gate TG is configured only by the horizontal portion TGb. In other words, the transfer gate TG does not have the vertical portion TGa, and is provided to face the semiconductor layer 100S.

The imaging device 1 including the transfer transistor TR having such a planar structure can also obtain effects similar to those described in the above embodiments. Furthermore, it is also conceivable to form the photodiode PD closer to the surface of the semiconductor layer 100S by providing the planar transfer gate TG on the first substrate 100 as compared with the case where the vertical transfer gate TG is provided on the first substrate 100, thereby increasing the saturation signal amount (Qs). In addition, it can be considered that the method of forming the planar transfer gate TG on the first substrate 100 has a smaller number of manufacturing processes than the method of forming the vertical transfer gate TG on the first substrate 100, and the photodiode PD is less likely to be adversely affected due to the manufacturing process.

### <7. Modification 6>

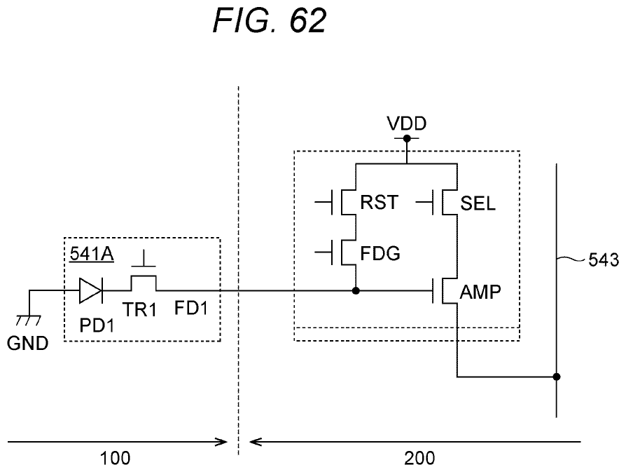

FIG. 62 illustrates a modification of the pixel circuit of the imaging device 1 according to the above embodiments. FIG. 62 corresponds to FIG. 30 described in the above embodiments. In the present modification, the pixel circuit 210 is provided for each pixel (pixel 541A). That is, the pixel circuit 210 is not shared by a plurality of pixels. In this respect, the imaging device 1 of the present modification is different from the imaging device 1 described in the above embodiments.

The imaging device 1 of the present modification is the same as the imaging device 1 described in the above embodiments in that the pixel 541A and the pixel circuit 210 are provided on different substrates (the first substrate 100 and the second substrate 200). Therefore, the imaging device 1 according to the present modification can also obtain effects similar to those described in the above embodiments.

### <8. Modification 7>

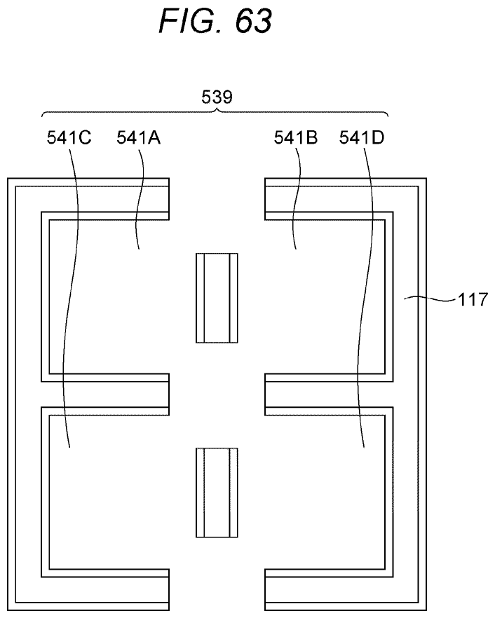

FIG. 63 illustrates a modification of the planar configuration of the pixel isolation portion 117 described in the above embodiments. A gap may be provided in the pixel isolation portion 117 surrounding each of the pixels 541A, 541B, 541C, and 541D. That is, the entire circumference of the pixels 541A, 541B, 541C, and 541D may not be surrounded by the pixel isolation portion 117. For example, the gap of the pixel isolation portion 117 is provided in the vicinity of the pad portions 120 and 121 (see FIG. 33B).

In the above embodiments, the example in which the pixel isolation portion 117 has the FTI structure penetrating the semiconductor layer 100S (see FIG. 32) has been described, but the pixel isolation portion 117 may have a configuration other than the FTI structure. For example, the pixel isolation portion 117 may not be provided so as to completely penetrate the semiconductor layer 100S, and may have a so-called deep trench isolation (DTI) structure.

### 9. Application Example

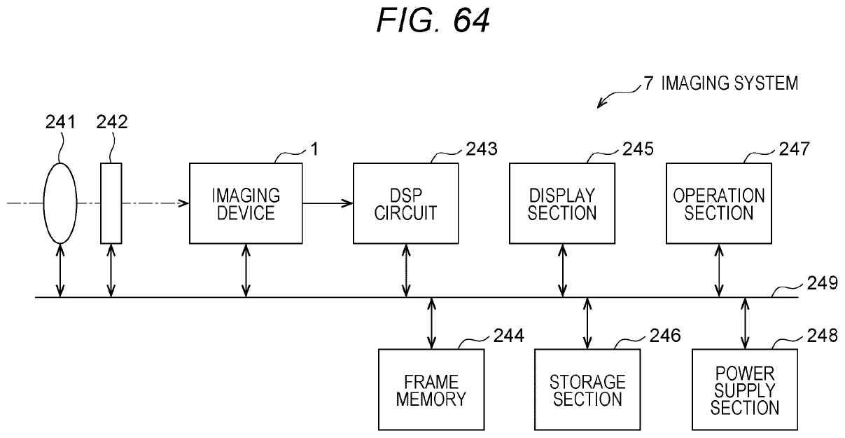

FIG. 64 illustrates an example of a schematic configuration of an imaging system 7 including the imaging device 1 according to the above embodiments and the modifications thereof.

The imaging system 7 is, for example, an electronic apparatus such as an imaging apparatus such as a digital still camera or a video camera, or a portable terminal apparatus such as a smartphone or a tablet terminal. The imaging system 7 includes, for example, the imaging device 1, a DSP circuit 243, a frame memory 244, a display section 245, a storage section 246, an operation section 247, and a power supply section 248 according to the above-described embodiments and the modifications thereof. In the imaging system 7, the imaging device 1, the DSP circuit 243, the frame memory 244, the display section 245, the storage section 246, the operation section 247, and the power supply section 248 according to the above-described embodiments and the modifications thereof are connected to each other via a bus line 249.

The imaging device 1 according to the above-described embodiments and the modification thereof outputs image data according to incident light. The DSP circuit 243 is a signal processing circuit that processes a signal (image data) output from the imaging device 1 according to the above-described embodiments and the modifications thereof. The frame memory 244 temporarily retains the image data processed by the DSP circuit 243 in units of frames. The display section 245 includes, for example, a panel-type display apparatus such as a liquid crystal panel or an organic electro luminescence (EL) panel, and displays a moving image or a still image captured by the imaging device 1 according to the above-described embodiments and the modifications thereof. The storage section 246 records image data of a moving image or a still image captured by the imaging device 1 according to the above-described embodiments and the modifications thereof in a recording medium such as a semiconductor memory or a hard disk. The operation section 247 issues operation commands for various functions of the imaging system 7 in accordance with an operation by the user. The power supply section 248 appropriately supplies various power supplies serving as operation power supplies of the imaging device 1, the DSP circuit 243, the frame memory 244, the display section 245, the storage section 246, and the operation section 247 according to the above-described embodiments and the modifications thereof to these supply targets.

Next, an imaging procedure in the imaging system 7 will be described.

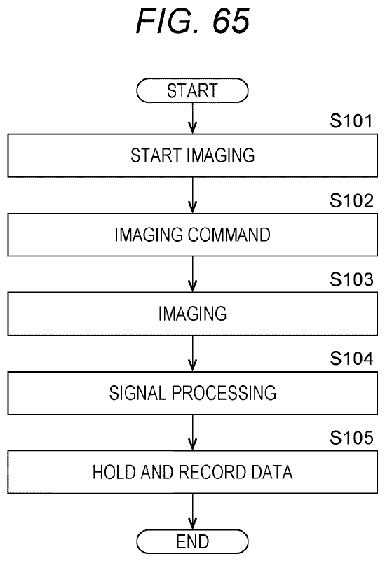

FIG. 65 illustrates an example of a flowchart of an imaging operation in the imaging system 7. The user instructs start of imaging by operating the operation section 247 (step S101). Then, the operation section 247 transmits an imaging command to the imaging device 1 (step S102). When receiving the imaging command, the imaging device 1 (specifically, the system control circuit 36) executes imaging by a predetermined imaging scheme (step S103).

The imaging device 1 outputs image data obtained by imaging to the DSP circuit 243. Here, the image data is data for all the pixels of the pixel signal generated on the basis of the charge temporarily retained in the floating diffusion FD. The DSP circuit 243 performs predetermined signal processing (for example, noise reduction processing or the like) on the basis of the image data input from the imaging device 1 (step S104). The DSP circuit 243 causes the frame memory 244 to hold the image data subjected to predetermined signal processing, and the frame memory 244 causes the storage section 246 to store the image data (step S105). In this manner, imaging in the imaging system 7 is performed.

In the present application example, the imaging device 1 according to the above-described embodiments and the modifications thereof is applied to the imaging system 7. As a result, since the imaging device 1 can be downsized or high definition, it is possible to provide the small or high definition imaging system 7.

### Second Application Example

The technology according to the present disclosure (present technology) can be applied to various products. For example, the technology of the present disclosure may be achieved in the form of a device to be mounted on a moving body of any kind, such as an automobile, an electric vehicle, a hybrid electric vehicle, a motorcycle, a bicycle, a personal mobility, an airplane, a drone, a vessel, or a robot.

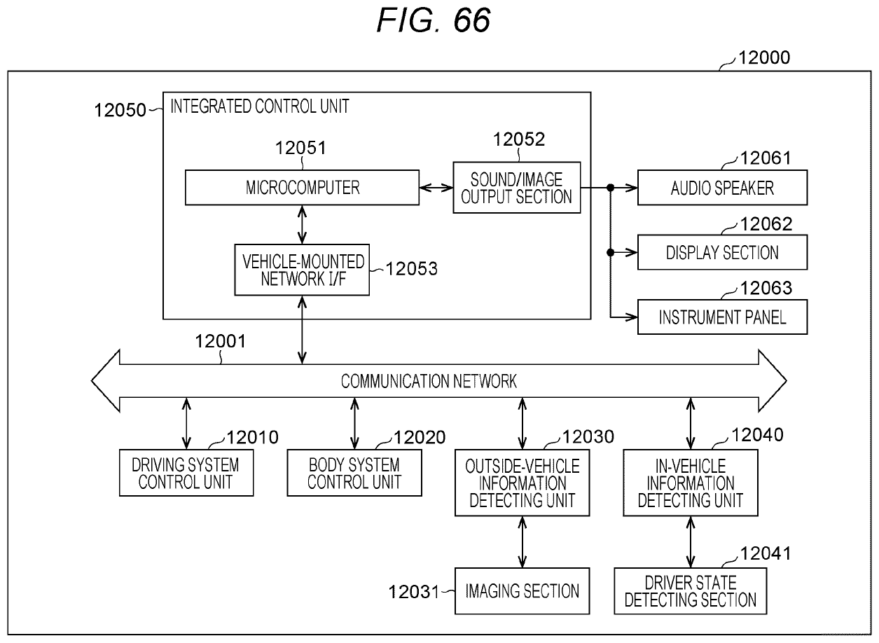

FIG. 66 is a block diagram illustrating an example of schematic configuration of a vehicle control system as an example of a mobile body control system to which the technology according to an embodiment of the present disclosure can be applied.

The vehicle control system 12000 includes a plurality of electronic control units connected via a communication network 12001. In the example illustrated in FIG. 66, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control apparatus of a keyless entry system, a smart key system, a power window apparatus, or various lamps such as a headlamp, a backup lamp, a brake lamp, a turn signal, or a fog lamp. In this case, radio waves transmitted from a portable device that substitutes for a key or signals of various switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. For example, a driver state detecting section 12041 that detects a state of a driver is connected to the in-vehicle information detecting unit 12040. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound or an image to an output apparatus capable of visually or auditorily notifying a passenger of the vehicle or the outside of the vehicle of information. In the example of FIG. 57, an audio speaker 12061, a display section 12062, and an instrument panel 12063 are illustrated as the output device. The display section 12062 may include, for example, at least one of an on-board display or a head-up display.

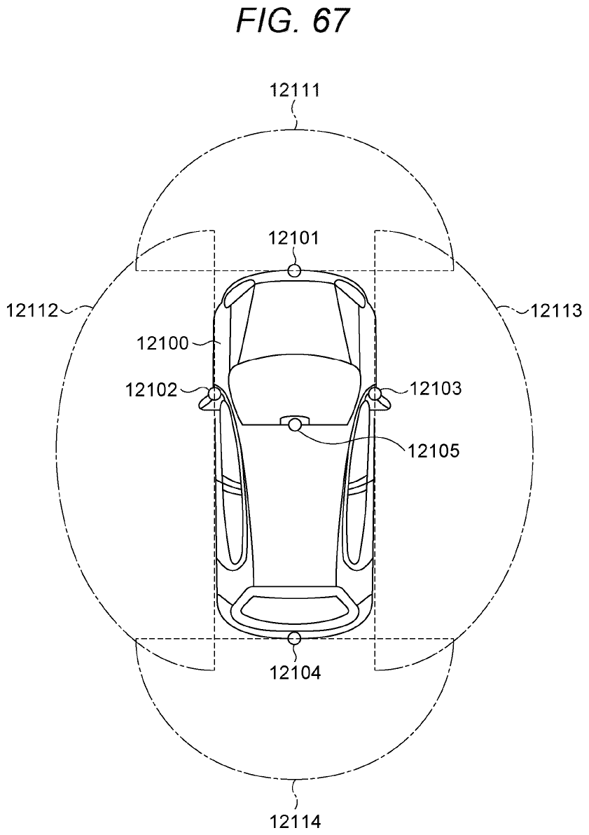

FIG. 67 is a diagram illustrating an example of the installation position of the imaging section 12031.

In FIG. 67, a vehicle 12100 includes imaging sections 12101, 12102, 12103, 12104, and 12105, as the imaging section 12031.

The imaging sections 12101, 12102, 12103, 12104, 12105 are provided, for example, at positions such as a front nose, a sideview mirror, a rear bumper, a back door, and an upper portion of a windshield in the interior of a vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 67 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or greater than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting feature points in the imaged images of the imaging sections 12101 to 12104 as infrared cameras and a procedure of determining whether or not it is the pedestrian by performing pattern matching processing on a series of feature points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the mobile body control system to which the technology according to the present disclosure can be applied has been described above. The technology according to the present disclosure can be applied to the imaging section 12031 among the configurations described above. Specifically, the imaging device 1 according to the above-described embodiments and the modifications thereof can be applied to the imaging section 12031. By applying the technology according to the present disclosure to the imaging section 12031, it is possible to obtain a high-definition captured image with little noise, and thus, it is possible to perform high-accuracy control using the captured image in the moving body control system.

### Third Application Example

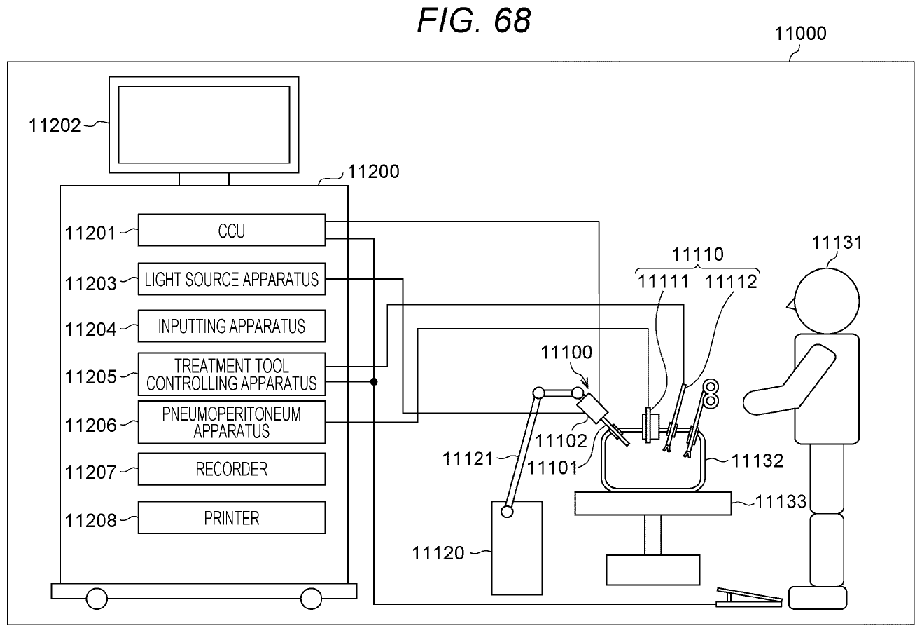

FIG. 68 is a diagram illustrating an example of a schematic configuration of an endoscopic surgery system to which the technology according to the present disclosure (the present technology) can be applied.

FIG. 68 shows a state where an operator (doctor) 11131 performs surgery on a patient 11132 on a patient bed 11133, by using an endoscopic surgery system 11000. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as a light emitting diode (LED), for example, and supplies irradiation light for imaging a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

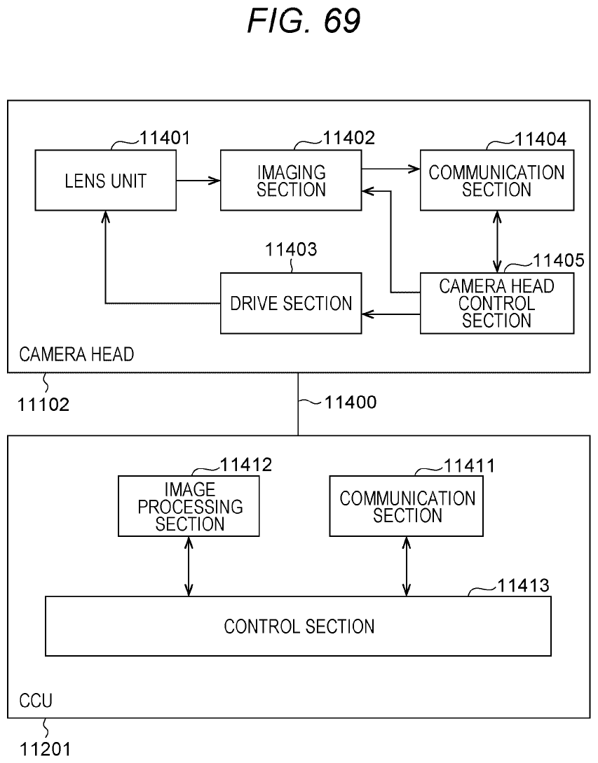

FIG. 69 is a block diagram illustrating an example of a functional configuration of the camera head 11102 and the CCU 11201 depicted in FIG. 68.

The camera head 11102 includes a lens unit 11401, an imaging section 11402, a drive section 11403, a communication section 11404, and a camera head control section 11405. The CCU 11201 includes a communication section 11411, an image processing section 11412, and a control section 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The imaging section 11402 includes an imaging element. The number of image pickup elements which is included by the imaging section 11402 may be one (single-plate type) or a plural number (multi-plate type). Where the imaging section 11402 is configured as that of the multi-plate type, for example, image signals corresponding to respective R, G and B are generated by the image pickup elements, and the image signals may be synthesized to obtain a color image. Alternatively, the imaging section 11402 may include a pair of imaging elements for acquiring right-eye and left-eye image signals corresponding to three-dimensional (3D) display. If 3D display is performed, then the depth of a living body tissue in a surgical region can be comprehended more accurately by the surgeon 11131. It is to be noted that, where the imaging section 11402 is configured as that of stereoscopic type, a plurality of systems of lens units 11401 are provided corresponding to the individual image pickup elements.

Further, the imaging section 11402 may not necessarily be provided on the camera head 11102. For example, the imaging section 11402 may be provided immediately behind the objective lens in the inside of the lens barrel 11101.

The drive section 11403 includes an actuator and moves the zoom lens and the focusing lens of the lens unit 11401 by a predetermined distance along an optical axis under the control of the camera head control section 11405. Consequently, the magnification and the focal point of a picked up image by the imaging section 11402 can be adjusted suitably.

The communication section 11404 includes a communication device for transmitting and receiving various types of information to and from the CCU 11201. The communication section 11404 transmits an image signal acquired from the imaging section 11402 as RAW data to the CCU 11201 via the transmission cable 11400.

Furthermore, the communication section 11404 receives a control signal for controlling driving of the camera head 11102 from the CCU 11201 and supplies the control signal to the camera head control section 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head control section 11405 controls driving of the camera head 11102 on the basis of a control signal from the CCU 11201 received via the communication section 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing section 11412 performs various types of image processing for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Furthermore, the control section 11413 controls, on the basis of an image signal for which image process has been performed by the image processing section 11412, the display apparatus 11202 to display a captured image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be suitably applied to the imaging section 11402 provided in the camera head 11102 of the endoscope 11100 among the above-described configurations. By applying the technology according to the present disclosure to the imaging section 11402, the imaging section 11402 can be downsized or high definition, so that the endoscope 11100 having a small size or high definition can be provided.

Although the present disclosure has been described with reference to the embodiments, the modifications, application examples, and applied examples thereof above, the present disclosure is not limited to the embodiments and the like, and various modifications can be made. Note that the effects described in the present specification are merely examples. The effects of the present disclosure are not limited to the effects described herein. The present disclosure may have effects other than those described herein.

Note that the present technology may have the following configurations.

(1)

A photodetection device including
a plurality of pixels that performs exposure at the same timing, in which
each of the plurality of pixels includes:
a photoelectric conversion element that stores charge corresponding to a light amount of incident light;
a first retention unit that retains the charge stored in the photoelectric conversion element;
a charge-voltage conversion unit that converts the charge retained in the first retention unit into a voltage;
a second retention unit that retains charge overflowing from the photoelectric conversion element;
a first transfer path that transfers charge from the photoelectric conversion element to the first retention unit;
a second transfer path that transfers charge from the photoelectric conversion element to the second retention unit; and
a first transistor that switches whether or not to supply the charge retained in the second retention unit to the charge-voltage conversion unit together with the charge retained in the first retention unit.
   (2)

The photodetection device according to (1), in which
the first transistor is switched so as to read the charge retained in the second retention unit when the incident light amount is equal to or greater than a first light amount, and not to read the charge retained in the second retention unit when the incident light amount is less than the first light amount.
   (3)

The photodetection device according to (1) or (2), further including
a semiconductor region in which the plurality of pixels is arranged, in which
the photoelectric conversion element and the first retention unit are arranged at different depth positions in the semiconductor region.
   (4)

The photodetection device according to (3), in which
the second transfer path includes a first diffusion region in which an impurity concentration changes continuously or stepwise in a depth direction of the semiconductor region from the photoelectric conversion element.
   (5)

The photodetection device according to (3) or (4), further including
a charge capturing portion arranged between the photoelectric conversion element and the first retention unit on the semiconductor region, the charge capturing portion capturing charge from the photoelectric conversion element and guiding the charge to the second transfer path.
   (6)

The photodetection device according to (5), in which
the charge capturing portion is arranged so as to cover the entire region of the first retention unit in plan view of the semiconductor region.
   (7)

The photodetection device according to (6), in which
the charge capturing portion includes a second diffusion region in which an impurity concentration changes continuously or stepwise from the photoelectric conversion element to the first retention unit.
   (8)

The photodetection device according to any one of (3) to (7), in which
the second transfer path includes a second transistor extending in a depth direction of the semiconductor region from the photoelectric conversion element to the second retention unit, and
a gate of the second transistor is set to a predetermined potential.
   (9)

The photodetection device according to any one of (1) to (8), further including
a third transistor that switches whether or not to discard the charge stored in the photoelectric conversion element, in which
the second transfer path transfers the charge stored in the photoelectric conversion element to the second retention unit without passing through the third transistor.
   (10)

The photodetection device according to any one of (1) to (8), further including
a third transistor that switches whether or not to discard the charge stored in the photoelectric conversion element, in which
the second transfer path transfers the charge overflowing from the photoelectric conversion element to the second retention unit through the third transistor.
   (11)

The photodetection device according to any one of (1) to (10), further including
a first substrate on which the photoelectric conversion element, the first retention unit, and the second retention unit are arranged, and
a second substrate laminated on the first substrate and provided with a pixel circuit that generates a pixel signal on the basis of charge retained in the first retention unit and the second retention unit.
   (12)

The photodetection device according to any one of (1) to (10), further including
a first substrate on which the photoelectric conversion element and the first retention unit are arranged, and
a second substrate laminated on the first substrate and provided with the second retention unit and a pixel circuit that generates a pixel signal on the basis of charge retained in the first retention unit and the second retention unit.
   (13)

The photodetection device according to any one of (1) to (12), in which
each of the plurality of pixels includes
a third retention unit that retains the charge stored in the photoelectric conversion element, and
a fourth transistor that switches whether or not to read the charge retained in the third retention unit.
   (14)

The photodetection device according to (13), in which
a capacitance of the third retention unit is smaller than a capacitance of the second retention unit.
   (15)

The photodetection device according to (13) or (14), in which
the first transistor and the fourth transistor are,
when the amount of incident light on the photoelectric conversion element is equal to or less than a second light amount, switched such that the charge retained in the first retention unit is supplied to the charge-voltage conversion unit without using the second retention unit and the third retention unit,
when the amount of incident light on the photoelectric conversion element is greater than the second light amount and equal to or less than a third light amount, switched such that a pixel signal is generated on the basis of the charge retained in the first retention unit and the third retention unit without using the second retention unit, and
when the amount of incident light on the photoelectric conversion element is greater than the third light amount, switched such that the charge retained in the first retention unit, the second retention unit, and the third retention unit is supplied to the charge-voltage conversion unit.
   (16)

The photodetection device according to any one of (1) to (15), in which
the second retention unit is configured using a diffusion layer and a wiring layer.
   (17)

The photodetection device according to any one of (1) to (15), in which
the second retention unit is configured using a diffusion layer, a wiring layer, and a metal-oxide semiconductor (MOS) capacitor.
   (18)

The photodetection device according to any one of (1) to (15), in which
the second retention unit is configured using a diffusion layer, a wiring layer, and a metal-insulator-metal (MIM) capacitor.
   (19)

The photodetection device according to any one of (1) to (18), further including
a semiconductor layer arranged on a semiconductor region in which the plurality of pixels is arranged, the semiconductor layer having an impurity concentration changing in a depth direction of the semiconductor region, and
a light shielding member partially arranged inside the semiconductor layer, in which
the photoelectric conversion element included in each of the plurality of pixels is arranged in the semiconductor layer, and
the first retention unit is arranged so as to at least partially overlap the light shielding member in plan view of the semiconductor region.
   (20)

An electronic apparatus including
a photodetection device, and
a processing unit that processes image data output from the photodetection device, in which
the photodetection device includes a plurality of pixels that performs exposure at the same timing, and
each of the plurality of pixels includes:
a photoelectric conversion element that stores charge corresponding to a light amount of incident light;
a first retention unit that retains the charge stored in the photoelectric conversion element;
a charge-voltage conversion unit that converts the charge retained in the first retention unit into a voltage;
a second retention unit that retains charge overflowing from the photoelectric conversion element;
a first transfer path that transfers charge from the photoelectric conversion element to the first retention unit;
a second transfer path that transfers charge from the photoelectric conversion element to the second retention unit; and
a first transistor that switches whether or not to supply the charge retained in the second retention unit to the charge-voltage conversion unit together with the charge retained in the first retention unit.

Modes of the present disclosure are not limited to the individual embodiments described above, but include various modifications that may be conceived by those skilled in the art, and the effects of the present disclosure are not limited to the contents described above. That is, various additions, modifications, and partial deletions may be made without departing from the conceptual idea and spirit of the present disclosure derived from the matters defined in the claims and equivalents thereof.

### REFERENCE SIGNS LIST

2 Photodetection device
3 Processing unit
4 Control unit
5 Recording unit
11 Imaging lens
12 Transmission line
13 Control line
20 Pixel array unit
21 Row drive unit
22 Timing control unit
23 Column signal processing unit
30, 30a, 30b, 30c, 30d, 30e, 30f, 30g, 90, 91 Pixel
31, 31a, 31b Pixel circuit
32 Bonding portion
33 Photoelectric conversion element
34 GS memory
35, 93 OF memory
36 Current source
37 Output node
41 First pixel chip
42 Second pixel chip
43 Logic chip
51 Lens portion
52 Color filter
53 Semiconductor layer
54, 55, 56 Light shielding portion 60 Charge capturing portion
61 Connection portion
62, 73, 74 Charge retention unit
71 Diffusion layer
72 Wiring capacitance
92 Light shielding film

What is claimed is:

1. A photodetection device, comprising
a plurality of pixels that performs exposure at the same timing, wherein
each of the plurality of pixels includes:
a photoelectric conversion element that stores charge corresponding to a light amount of incident light;
a first retention unit that retains the charge stored in the photoelectric conversion element;
a charge-voltage conversion unit that converts the charge retained in the first retention unit into a voltage;
a second retention unit that retains charge overflowing from the photoelectric conversion element;
a first transfer path that transfers charge from the photoelectric conversion element to the first retention unit;
a second transfer path that transfers charge from the photoelectric conversion element to the second retention unit; and
a first transistor that switches whether or not to supply the charge retained in the second retention unit to the charge-voltage conversion unit together with the charge retained in the first retention unit.

2. The photodetection device according to claim 1, wherein
the first transistor is switched so as to read the charge retained in the second retention unit when the incident light amount is equal to or greater than a first light amount, and not to read the charge retained in the second retention unit when the incident light amount is less than the first light amount.

3. The photodetection device according to claim 1, further comprising
a semiconductor region in which the plurality of pixels is arranged, wherein
the photoelectric conversion element and the first retention unit are arranged at different depth positions in the semiconductor region.

4. The photodetection device according to claim 3, wherein
the second transfer path includes a first diffusion region in which an impurity concentration changes continuously or stepwise in a depth direction of the semiconductor region from the photoelectric conversion element.

5. The photodetection device according to claim 3, further comprising
a charge capturing portion arranged between the photoelectric conversion element and the first retention unit on the semiconductor region, the charge capturing portion capturing charge from the photoelectric conversion element and guiding the charge to the second transfer path.

6. The photodetection device according to claim 5, wherein
the charge capturing portion is arranged so as to cover the entire region of the first retention unit in plan view of the semiconductor region.

7. The photodetection device according to claim 6, wherein
the charge capturing portion includes a second diffusion region in which an impurity concentration changes continuously or stepwise from the photoelectric conversion element to the first retention unit.

8. The photodetection device according to claim 3, wherein
the second transfer path includes a second transistor extending in a depth direction of the semiconductor region from the photoelectric conversion element to the second retention unit, and
a gate of the second transistor is set to a predetermined potential.

9. The photodetection device according to claim 1, further comprising
a third transistor that switches whether or not to discard the charge stored in the photoelectric conversion element, wherein
the second transfer path transfers the charge stored in the photoelectric conversion element to the second retention unit without passing through the third transistor.

10. The photodetection device according to claim 1, further comprising
a third transistor that switches whether or not to discard the charge stored in the photoelectric conversion element, wherein
the second transfer path transfers the charge overflowing from the photoelectric conversion element to the second retention unit through the third transistor.

11. The photodetection device according to claim 1, further comprising
a first substrate on which the photoelectric conversion element, the first retention unit, and the second retention unit are arranged, and
a second substrate laminated on the first substrate and provided with a pixel circuit that generates a pixel signal on the basis of charge retained in the first retention unit and the second retention unit.

12. The photodetection device according to claim 1, further comprising
a first substrate on which the photoelectric conversion element and the first retention unit are arranged, and
a second substrate laminated on the first substrate and provided with the second retention unit and a pixel circuit that generates a pixel signal on the basis of charge retained in the first retention unit and the second retention unit.

13. The photodetection device according to claim 1, wherein
each of the plurality of pixels includes
a third retention unit that retains the charge stored in the photoelectric conversion element, and
a fourth transistor that switches whether or not to read the charge retained in the third retention unit.

14. The photodetection device according to claim 13, wherein
a capacitance of the third retention unit is smaller than a capacitance of the second retention unit.

15. The photodetection device according to claim 13, wherein
the first transistor and the fourth transistor are,
when the amount of incident light on the photoelectric conversion element is equal to or less than a second light amount, switched such that the charge retained in the first retention unit is supplied to the charge-voltage conversion unit without using the second retention unit and the third retention unit,
when the amount of incident light on the photoelectric conversion element is greater than the second light amount and equal to or less than a third light amount, switched such that a pixel signal is generated on the basis of the charge retained in the first retention unit and the third retention unit without using the second retention unit, and
when the amount of incident light on the photoelectric conversion element is greater than the third light amount, switched such that the charge retained in the first retention unit, the second retention unit, and the third retention unit is supplied to the charge-voltage conversion unit.

16. The photodetection device according to claim 1, wherein
the second retention unit is configured using a diffusion layer and a wiring layer.

17. The photodetection device according to claim 1, wherein
the second retention unit is configured using a diffusion layer, a wiring layer, and a metal-oxide semiconductor (MOS) capacitor.

18. The photodetection device according to claim 1, wherein
the second retention unit is configured using a diffusion layer, a wiring layer, and a metal-insulator-metal (MIM) capacitor.

19. The photodetection device according to claim 1, further comprising
a semiconductor layer arranged on a semiconductor region in which the plurality of pixels is arranged, the semiconductor layer having an impurity concentration changing in a depth direction of the semiconductor region, and
a light shielding member partially arranged inside the semiconductor layer, wherein
the photoelectric conversion element included in each of the plurality of pixels is arranged in the semiconductor layer, and
the first retention unit is arranged so as to at least partially overlap the light shielding member in plan view of the semiconductor region.

20. An electronic apparatus, comprising
a photodetection device, and
a processing unit that processes image data output from the photodetection device, wherein
the photodetection device includes a plurality of pixels that performs exposure at the same timing, and
each of the plurality of pixels includes:
a photoelectric conversion element that stores charge corresponding to a light amount of incident light;
a first retention unit that retains the charge stored in the photoelectric conversion element;
a charge-voltage conversion unit that converts the charge retained in the first retention unit into a voltage;
a second retention unit that retains charge overflowing from the photoelectric conversion element;
a first transfer path that transfers charge from the photoelectric conversion element to the first retention unit;
a second transfer path that transfers charge from the photoelectric conversion element to the second retention unit; and
a first transistor that switches whether or not to supply the charge retained in the second retention unit to the charge-voltage conversion unit together with the charge retained in the first retention unit.
